(19) United States
(12) Patent Application Publication
(10) Pub. No.: US 2007/0069235 A1
(43) Pub. Date: Mar. 29, 2007

(54) Light-emitting element

(75) Inventors: Iwao Ueno, Kyoto (JP); Junichi Kato, Osaka (JP); Seiji Nishiyama, Osaka (JP); Naoki Noda, Osaka (JP)

Correspondence Address: HAMRE, SCHUMANN, MUELLER & LARSON P.C., P.O. BOX 2902-0902, MINNEAPOLIS, MN, 55402, US

(73) Assignee: Matsushita Electric Industrial Co., Ltd., Osaka (JP)

(21) Appl. No.: 10/572,761

(22) PCT Filed: Oct. 21, 2004
(86) PCT No.: PCT/JP04/15614

§ 371 Date: Mar. 21, 2006

(30) Foreign Application Priority Data
Oct. 27, 2003 (JP) 2003-366508
Nov. 13, 2003 (JP) 2003-383907
Feb. 3, 2004 (JP) 2004-027204
Jun. 18, 2004 (JP) 2004-181442
Oct. 18, 2004 (JP) 2004-303178

(51) Int. Cl. H01L 31/111

(52) U.S. Cl. 257/109

(57) ABSTRACT

A light-emitting element (1) includes a light-emitting layer (2) including a phosphor, and at least two electrodes (6, 7). The light-emitting element (1) includes at least two kinds of electrically insulating layers (2, 9) with different dielectric constants. One of the electrically insulating layers (2, 9) is the light-emitting layer (2), and one of the two electrodes (6, 7) is formed in contact with one of the insulating layers. Therefore, it is possible to provide a light-emitting element that can emit light by using surface discharge, is manufactured at low cost, exhibits favorable luminous efficiency, and is to be driven with low power consumption when being applied to a large-screen display.

### TECHNICAL FIELD

The present invention relates to a light-emitting element. In particular, the invention relates to a light-emitting element as a constituent of a unit pixel of a large-screen display that is configured and manufactured easily and achieves low power consumption.

### BACKGROUND ART

In recent years, liquid crystal displays and plasma displays have been used widely as large-screen flat displays, and further development is being carried out for displays with higher image quality and efficiency. Examples of such displays include an electroluminescence display (ELD) and a field emission display (FED). ELDs are described in Non-patent document 1 generally as follows. That is, an ELD has a basic structure in which an electric field is applied to a phosphor serving as a light-emitting layer via an insulating layer, and is classified into a distribution type and a thin film type. The former has a structure in which particles of ZnS to which impurities such as Cu are added are distributed in an organic binder, which is then sandwiched between upper and lower electrodes via an insulating layer. The impurities form a pn junction in the phosphor particles. When an electric field is applied, electrons emitted by a high electric field generated on the junction surface are accelerated, and then are recombined with positive holes, resulting in light emission. The latter has a structure in which an electrode is provided at a phosphor thin film of Mn doped ZnS or the like serving as a light-emitting layer via an insulating layer. The presence of the insulating layer allows a high electric field to be applied to the light-emitting layer, and emitted electrons accelerated by the electric field excite the luminescence center, resulting in light emission. On the other hand, a FED has a structure in which an electron-emitting element and a phosphor opposed thereto are contained in a vacuum vessel. Electrons emitted from the electron-emitting element in vacuum are accelerated and irradiated to the phosphor layer, whereby light is emitted.

In either device, light emission is induced by electron emission, and accordingly a technique for emitting electrons at a low voltage with high efficiency is important. As such a technique, electron emission by polarization reversal of a ferroelectric is receiving attention. For example, Non-patent document 2 proposes the following as shown in FIG. 20. A PZT ceramic 31 having a flat electrode 32 on one surface and a lattice electrode 33 on the other surface is provided in a vacuum vessel 36 so as to be opposed to a platinum electrode 34 with a grid electrode 35 interposed therebetween. When a pulse voltage is applied between the electrodes, electrons are emitted. Reference numeral 37 denotes an air outlet. This proposal describes that the pressure in the vessel is 1.33 Pa (10⁻² Torr), and that no discharge occurs under atmospheric pressure.

Patent documents 1 and 2 also describe the technique for allowing a light-emitting layer to emit light by accelerating electrons emitted by polarization reversal of a ferroelectric in a vacuum vessel, or a display using this light emission technique. A basic configuration thereof is as follows: an

electrode having a phosphor layer is provided instead of the platinum electrode in Non-patent document 2, thereby allowing the phosphor layer to emit light.

On the other hand, patent document 3 discloses an electric light emitting surface light source element as an example of a light-emitting element achieved by using electrons emitted by polarization reversal of a ferroelectric in non-vacuum. As shown in FIG. 21, this element includes a lower electrode 42, a ferroelectric thin film 41, an upper electrode 43, a carrier intensifying layer 48, a light-emitting layer 44, and a transparent electrode 46, which are formed on a substrate 45 in this order. The upper electrode has an opening portion 47. By reversing a voltage pulse applied between the lower and upper electrodes, electrons are emitted from the opening portion of the upper electrode toward the carrier intensifying layer, are accelerated by a positive voltage applied to the transparent electrode, and reach the light-emitting layer while being intensified, whereby light is emitted. It is described that the carrier intensifying layer is formed of a semiconductor that is relatively low in dielectric constant and has a band gap that does not allow light of a wavelength emitted from the light-emitting layer to be absorbed. This element can be regarded as a kind of ELD. Further, patent document 4 discloses a configuration in which a light-emitting layer made of a phosphor formed by sputtering is sandwiched between insulating layers, to which a pulse electric field is applied. The insulator on one side of the light-emitting layer is formed of a ferroelectric thin film.

Patent document 1: JP 7(1995)-64490A

Patent document 2: U.S. Pat. No. 5,453,661

Patent document 3: JP 6(1994)-283269 A

Patent document 4: JP 8(1996)-083686 A

Non-patent document 1: “Electronic Display” written and edited by Shoichi MATSUMOTO, published by Ohmsha, Dec. 25, 1984, p. 147-151.

Non-patent document 2: Jun-ichi ASANO et al., “Field-Excited Electron Emission from Ferroelectric Ceramic in Vacuum”, Japanese Journal of Applied Physics, Vol. 31, Part 1, p. 3098-3101, September 1992

In the above prior art, the light-emitting elements that need a vacuum state have a complicated structure, and it is rather difficult to achieve a large-screen display therewith. For example, a field emission display (FED), which is expected to achieve high luminous efficiency, needs a vacuum vessel in which a high degree of vacuum is maintained for emission of electron beams. This makes the structure of the display complicated, and it is considered to be difficult to realize a large-screen structure. No FED is yet commercially available.

Plasma displays need no vacuum vessel. A plasma display utilizes light emission caused by converting discharge energy into ultraviolet light energy once, so that the ultraviolet light excites phosphors. In the course of exiting the phosphors, a large amount of the ultraviolet light is absorbed by members other than the phosphors. For this reason, it is difficult to increase the luminous efficiency, and a large amount of power will be consumed by a large-screen plasma display.

Also, EL displays need no vacuum vessel. However, an inorganic EL display has a problem in luminous efficiency and color reproduction, and an organic EL display requires large-scale facilities for a thin film formation process for manufacturing a liquid crystal display and the like. Further, it is difficult to realize a large-screen EL display, and thus no such display is yet commercially available.

### DISCLOSURE OF INVENTION

A light-emitting element of the present invention includes a light-emitting layer including a phosphor, and at least two electrodes. The light-emitting element includes at least two kinds of electrically insulating layers with different dielectric constants, one of the electrically insulating layers is the light-emitting layer, and one of the two electrodes is formed in contact with one of the insulating layers.

The light emission principle of the present invention is as follows. That is, dielectric breakdown is caused between at least two electrodes to generate primary electrons (e−). The primary electrons (e−) collide with phosphor particles of a light-emitting layer to cause surface discharge, and a large number of secondary electrons (e−) are generated. Electrons and ultraviolet rays generated thereby in an avalanche manner collide with the luminescence center of the phosphor, so that the phosphor particles are excited to emit light.

### BRIEF DESCRIPTION OF DRAWINGS

FIG. 1 is a cross-sectional view of a light-emitting element according to Embodiment 1 of the present invention.

FIG. 2 is a view for explaining a manufacturing process of the light-emitting element according to Embodiment 1 of the present invention.

FIG. 3 is a view for explaining a manufacturing process of the light-emitting element according to Embodiment 1 of the present invention.

FIG. 4 is a view for explaining a manufacturing process of the light-emitting element according to Embodiment 1 of the present invention.

FIG. 5 is a view for explaining a manufacturing process of the light-emitting element according to Embodiment 1 of the present invention.

FIG. 6 is a schematic enlarged cross-sectional view of a porous light-emitting layer according to Embodiment 1 of the present invention.

FIG. 7 is a cross-sectional view of a light-emitting element according to Embodiment 2 of the present invention.

FIG. 8 is a cross-sectional view of a light-emitting element according to Embodiment 3 of the present invention.

FIG. 9 is a cross-sectional view of a light-emitting element according to Embodiment 4 of the present invention.

FIG. 10 is a view for explaining a manufacturing process of the light-emitting element according to Embodiment 4 of the present invention.

FIG. 11 is a view for explaining a manufacturing process of the light-emitting element according to Embodiment 4 of the present invention.

FIG. 12 is a view for explaining a manufacturing process of the light-emitting element according to Embodiment 4 of the present invention.

FIG. 13 is a view for explaining a manufacturing process of the light-emitting element according to Embodiment 4 of the present invention.

FIG. 14 is a schematic enlarged cross-sectional view of a porous light-emitting layer according to Embodiment 5 of the present invention.

FIG. 15 is a schematic enlarged cross-sectional view of a porous light-emitting layer according to Embodiment 5 of the present invention.

FIG. 16 is an exploded perspective view of a light-emitting element according to Embodiment 6 of the present invention.

FIG. 17 is a view for explaining effects of light emission according to Embodiment 1 of the present invention.

FIG. 18 is a cross-sectional view of a light-emitting element according to Embodiment 7 of the present invention.

FIG. 19 is a cross-sectional view of a light-emitting element according to Embodiment 8 of the present invention.

FIG. 20 is a cross-sectional view of a conventional light-emitting element in Non-patent document 2.

FIG. 21 is a cross-sectional view of a conventional light-emitting element in patent document 3.

FIG. 22 is a cross-sectional view of a light-emitting element according to Embodiment 9 of the present invention.

FIG. 23 is a cross-sectional view of a light-emitting element according to Embodiment 10 of the present invention.

FIG. 24 is a cross-sectional view of a light-emitting element according to Embodiment 11 of the present invention.

FIG. 25 is a cross-sectional view of a light-emitting element according to Embodiment 12 of the present invention.

FIG. 26 is a cross-sectional view of a light-emitting element according to Embodiment 13 of the present invention.

FIG. 27 is a cross-sectional view of a light-emitting element according to Embodiment 14 of the present invention.

FIG. 28 is a cross-sectional view of a light-emitting element according to Embodiment 15 of the present invention.

FIG. 29 is a cross-sectional view of a light-emitting element according to Embodiment 16 of the present invention.

FIGS. 30A to 30F are cross-sectional views for explaining processes of a manufacturing method of the light-emitting element shown in FIG. 29.

FIG. 31 is a cross-sectional view of a light-emitting element according to Embodiment 17 of the present invention.

FIGS. 32A to 32G are cross-sectional views for explaining processes of a manufacturing method of the light-emitting element shown in FIG. 31.

FIG. 33 is a cross-sectional view of a light-emitting element according to Embodiment 18 of the present invention.

FIGS. 34A to 34C are cross-sectional views for explaining processes of a manufacturing method of the light-emitting element shown in FIG. 33.

FIG. 35 is a cross-sectional view of a light-emitting element according to Embodiment 19 of the present invention.

FIGS. 36A to 36D are cross-sectional views for explaining processes of a manufacturing method of the light-emitting element shown in FIG. 35.

FIGS. 37A to 37C are cross-sectional views for explaining processes of a manufacturing method of an electron-emitting body according to Embodiment 20 of the present invention.

FIG. 38 is a cross-sectional view of a porous light-emitting body constituting a light-emitting element according to Embodiment 21 of the present invention.

FIG. 39 is a cross-sectional view of a porous light-emitting body constituting the light-emitting element according to Embodiment 21 of the present invention.

FIG. 40 is a cross-sectional view of a porous light-emitting body constituting the light-emitting element according to Embodiment 21 of the present invention.

FIG. 41 is a schematic cross-sectional view of a porous light-emitting body constituting the light-emitting element according to Embodiment 21 of the present invention.

FIG. 42 is a schematic cross-sectional view of a porous light-emitting body constituting the light-emitting element according to Embodiment 21 of the present invention.

FIG. 43 is an exploded perspective view of main portions of a field emission display according to Embodiment 22 of the present invention.

FIG. 44 is a cross-sectional view of a light-emitting element array according to Embodiment 22 of the present invention.

FIGS. 45A to 45C are cross-sectional views of a light-emitting element array according to Embodiment 23 of the present invention.

### DESCRIPTION OF THE INVENTION

A light-emitting element of the present invention includes, from a back surface side, at least a first electrode, a dielectric layer, a porous light-emitting layer, and a second electrode, and has a gap between the porous light-emitting layer and the electrode. Therefore, when an AC electric field is applied between the first electrode and the second electrode, gas breakdown is caused in the gap to accelerate the generation of primary electrons. By the primary electrons, surface discharge occurs in the porous light-emitting layer between the electrodes, so that secondary electrons and ultraviolet rays are emitted. The emitted secondary electrons and ultraviolet rays excite the luminescence center of the porous light-emitting layer, so that the porous light-emitting layer emits light.

The gap may be provided to have an arbitrary width, but the width is preferably in a range of not less than 1 μm to not more than 300 μm. When the width is less than 1 μm, it tends to be difficult to control the gap. When the width is more than 300 μm, dielectric breakdown is less likely to occur. In general, it is necessary to apply an electric field of 300 V or more (at intervals of 100 μm) at 3 kV/mm to cause dielectric breakdown of air in the atmosphere. Under a reduced pressure, although dielectric breakdown occurs at 300 V or less, the application of a high voltage causes damage to various parts of a cell structure. On this account, in order to apply a voltage that does not cause damage, the width of the gap is preferably in the above-mentioned range. More preferably, the width of the gap is in a range of not less than 10 μm to not more than 100 μm.

The light-emitting element of the present invention emits light by surface discharge in the porous light-emitting layer. There is no need to use a thin film formation process, a vacuum system, a carrier intensifying layer, and the like for forming the porous light-emitting layer. Therefore, the light-emitting element has a simple structure and is manufactured easily. Further, the light-emitting element exhibits favorable luminous efficiency and is to be driven with relatively low power consumption when being applied to a large-screen display. Further, in the light-emitting element of the present invention, discharge separation means may be provided between the porous light-emitting layers, whereby crosstalk during light emission can be avoided. Crosstalk herein refers to a phenomenon in which light emission from a pixel interacts with that from adjacent pixels to deteriorate the luminous efficiency.

It is preferable that the discharge separation means of the present invention is formed in particular of a partition wall and/or a space or the like. The partition wall for separating the porous light-emitting layers is preferably an electrical insulator with a thickness of 80 to 300 μm.

In the case of a partition wall, it preferably is made of an inorganic material. As an inorganic material, glass, ceramic, a dielectric, or the like can be used. As a dielectric, Y₂O₃, Li₂O, MgO, CaO, BaO, SrO, Al₂O₃, SiO₂, MgTiO₃, CaTiO₃, BaTiO₃, SrTiO₃, ZrO₂, TiO₂, B₂O₃, PbTiO₃, PbZrO₃, PbZrTiO₃ (PZT), or the like may be used.

In the case where the discharge separation means is formed of a space, the space preferably has a width of 80 to 300 μm.

The gap between the porous light-emitting layer and the second electrode may be partitioned by a rib in a thickness direction. As a result, electrons are generated easily by dielectric breakdown from a wall surface of the rib. A preferable material of the rib may be selected from the materials for the partition wall. It is preferable that the rib and the partition wall have a surface that is as smooth as possible. A smooth surface facilitates hopping of generated electrons on the rib, resulting in increased luminous efficiency of the porous light-emitting layer.

It is preferable that an atmosphere in the light-emitting element is at least one selected from atmospheric air, oxygen, nitrogen, and a rare gas.

It is preferable that the light-emitting element is in an atmosphere under a reduced pressure including at least one selected from the above-mentioned gases.

It is preferable that the porous light-emitting layer emits light of at least red (R), green (G), or blue (B).

It is preferable that the porous light-emitting layer is formed of a phosphor particle with an insulating layer on its surface.

It is preferable that the porous light-emitting layer is formed of a phosphor particle and an insulative fiber.

It is preferable that the porous light-emitting layer is formed of a phosphor particle with an insulating layer on its surface and an insulative fiber.

It is preferable that the porous light-emitting layer has an apparent porosity in a range of not less than 10% to less than 100%. In order to allow hopping of electrons in the porous light-emitting layer (an assembly of phosphor particles and spaces), it is necessary that a space among individual phosphor particles is smaller than a mean free path of electrons. When the apparent porosity is within the above range, hopping of electrons is not inhibited.

It is preferable that the first or second electrode is an address electrode or a display electrode.

It is preferable that the second electrode is a transparent electrode arranged on an observation side.

The light-emitting element of the present invention includes a dielectric layer, a porous light-emitting layer, a pair of electrodes, and another electrode. The porous light-emitting layer includes an inorganic phosphor particle, a pair of the electrodes are arranged so that an electric field is applied to at least a part of the dielectric layer, and the other electrode is arranged so that an electric field is applied to at least a part of the porous light-emitting layer between the other electrode and at least one of a pair of the electrodes. Specifically, this light-emitting element is a multi-terminal light-emitting element such as a three-terminal light-emitting element, for example. With this configuration, when an electric field is applied between a pair of the electrodes so that polarization reversal is performed, primary electrons are emitted initially from the dielectric layer due to polarization reversal. Thereafter, when an alternating electric field is applied between the other electrode and at least one of a pair of the electrodes, the emitted primary electrons cause surface discharge in an avalanche manner in the porous light-emitting layer, and secondary electrons are generated. Finally, a large number of the generated secondary electrons excite the luminescence center, so that the porous light-emitting layer emits light.

A pair of the electrodes may be arranged on the dielectric layer. One of a pair of the electrodes may be arranged at a boundary between the dielectric layer and the porous light-emitting layer, and the other may be arranged on the dielectric layer. Further, the other electrode may be arranged on the porous light-emitting layer. A pair of the electrodes may be formed so as to sandwich the boundary between the dielectric layer and the porous light-emitting layer therebetween. A pair of the electrodes may be both formed at the boundary between the dielectric layer and the porous light-emitting layer. One of a pair of the electrodes may be formed at the boundary between the dielectric layer and the porous light-emitting layer, and the other may be formed on the dielectric layer.

The porous light-emitting layer may be formed of a fine pore connected to a surface of the porous light-emitting layer, a gas filled in the fine pore, and a phosphor particle. The gas filled in the fine pore can be at least one gas selected from at least one of atmospheric air, oxygen, nitrogen, and an inert gas, and a gas under a reduced pressure.

The dielectric layer may be formed of a sintered dielectric. The dielectric layer may be formed of a dielectric particle and a binder. The dielectric layer may be formed of a thin film. Further, the porous light-emitting layer may be formed of a phosphor particle and an insulating layer on a surface of the phosphor particle. The porous light-emitting layer may be formed of a phosphor particle and an insulative fiber. The porous light-emitting layer may be formed of a phosphor particle, an insulating layer on a surface of the phosphor particle, and an insulative fiber.

It is preferable that when an electric field is applied between a pair of the electrodes so that polarization reversal is performed, primary electrons are emitted from the dielectric layer to cause surface discharge in an avalanche manner in the porous light-emitting layer, then secondary electrons are generated, and a large number of the secondary electrons generated due to surface discharge collide with phosphor particles, so that the porous light-emitting layer emits light. The porous light-emitting layer may emit light in at least one gas atmosphere selected from an atmosphere of atmospheric air, oxygen, nitrogen, and an inert gas, and a gas atmosphere under a reduced pressure. It is also preferable that an alternating electric field is applied between the other electrode and at least one electrode of a pair of the electrodes after the application of an electric field between a pair of the electrodes for polarization reversal.

The light-emitting element of the present invention includes a porous light-emitting body. The porous light-emitting body includes an insulative phosphor particle, and a predetermined electric field or higher is applied to the porous light-emitting body, so that electric charge transfer is carried out.

The light-emitting element of the present invention includes an electron-emitting body, a porous light-emitting body, and a pair of electrodes. The porous light-emitting body includes an inorganic phosphor particle and is arranged adjacent to the electron-emitting body so as to be irradiated with electrons generated from the electron-emitting body, and a pair of the electrodes are arranged so that an electric field is applied to at least a part of the porous light-emitting body.

With the above-described configuration, electrons are emitted from the electron-emitting body, and when an alternating electric field is applied between a pair of the electrodes, the emitted electrons cause surface discharge in an avalanche manner in the porous light-emitting layer. As a result, the emitted electrons excite the luminescence center, so that the porous light-emitting body emits light. Further, a direct electric field may be applied instead of the alternating electric field.

Hereinafter, embodiments of the present invention will be described with reference to the drawings.

### Embodiment 1

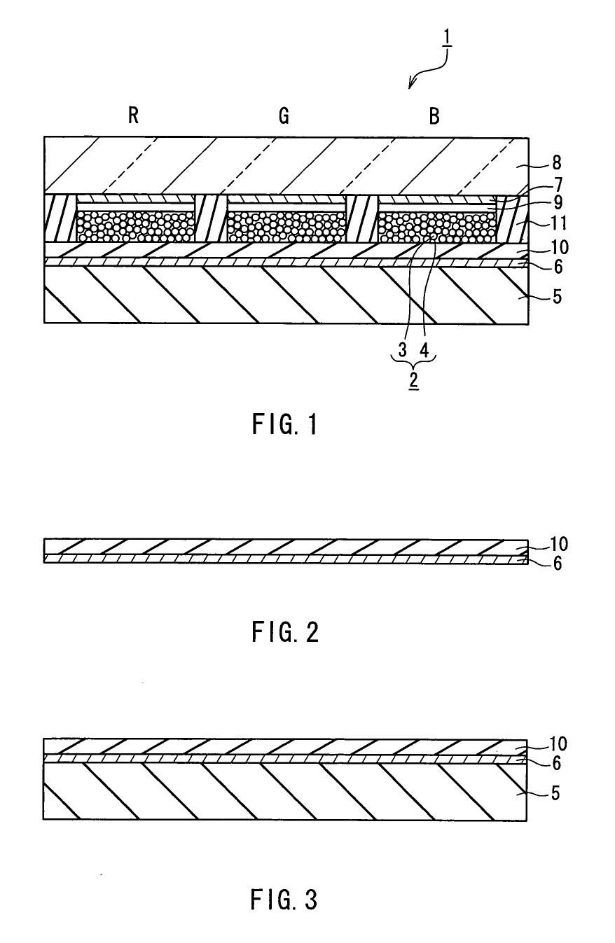

The present embodiment will be described with reference to FIGS. 1 to 6. In this example, a light-emitting element is formed of an assembly of a plurality of porous light-emitting layers, each having a dielectric layer and a first electrode on one surface and a second electrode on the other surface where the dielectric layer and the first electrode are not formed, and includes discharge separation means between the plurality of porous light-emitting layers. In particular, the dielectric layer is shared by part of the plurality of porous light-emitting layers, and the discharge separation means is formed of a partition wall.

FIG. 1 is a cross-sectional view of the light-emitting element of the present embodiment. FIGS. 2 to 6 are views for explaining manufacturing processes of the light-emitting element of the present embodiment. In these figures, reference numeral 1 denotes a light-emitting element, 2 denotes a porous light-emitting layer, 3 denotes a phosphor particle, 4 denotes an insulating layer, 5 denotes a substrate, 6 denotes a first electrode (back side electrode), 7 denotes a second electrode (observation side electrode), 8 denotes a transparent substrate, 9 denotes a gap (gas layer), 10 denotes a dielectric layer, and 11 denotes a partition wall.

As shown in FIG. 2, on one side of the sintered dielectric 10 with a thickness of 0.3 to 1.0 mm, an Ag paste is baked to a thickness of 30 μm to form the first electrode 6 into a predetermined shape. Then, as shown in FIG. 3, the dielectric layer with the electrode shown in FIG. 2 is adhered onto the substrate 5 made of glass or ceramic.

In the present embodiment, BaTiO₃ is used as the dielectric. However, SrTiO₃, CaTiO₃, MgTiO₃, PZT(PbZrTiO₃), PbTiO₃, or the like also may be used as the dielectric to achieve the same effect. Further, Al₂O₃, MgO, ZrO₂, or the like also may be used as the dielectric to achieve the same effect. In this case, however, the luminescence decreases as compared with the above-mentioned dielectrics having a higher relative dielectric constant. This can be improved by reducing the thickness of the dielectric layer.

Further, the dielectric layer may be formed by a molecule deposition method such as sputtering, CVD, and deposition or with a thin film formation process such as a sol-gel process. When the dielectric layer is formed of a sintered body, this can be used also as the substrate 5. The thickness of the dielectric layer varies considerably depending on how the dielectric layer is formed, e.g., the case where a sintered body is used or the case where a thick film process is used. Practically, however, the thickness is adjusted relative to the dielectric constant since a certain capacitance property is required.

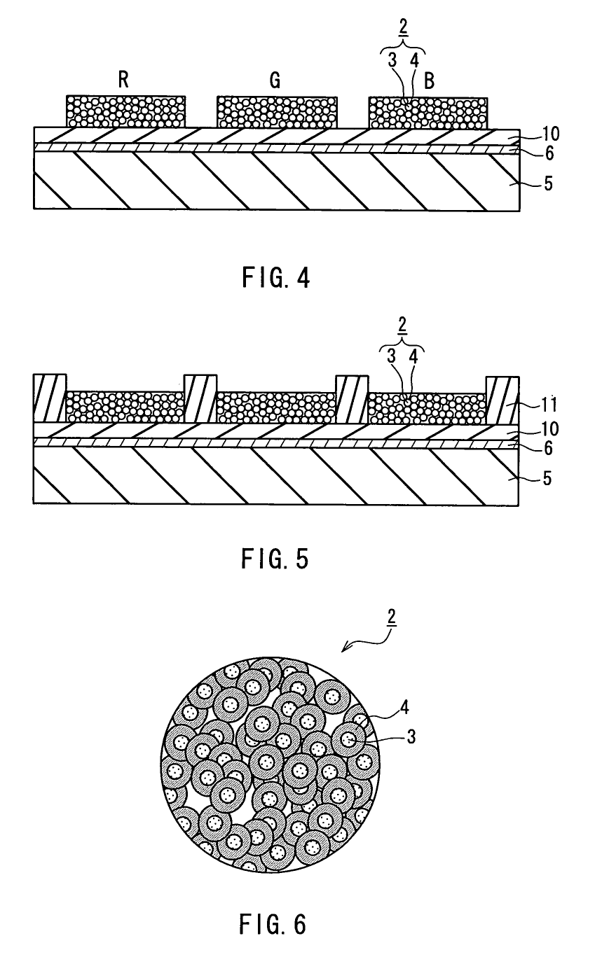

Then, as shown in FIG. 4, the plurality of porous light-emitting layers 2 are formed on the dielectric layer 10 into a predetermined shape by screen printing.

As shown in FIG. 6, the phosphor particles 3, each being coated with the insulating layer 4 made of a metal oxide such as MgO, are prepared for the porous light-emitting layer 2 as follows.

As the phosphor particle 3, an inorganic compound, such as BaMgAl₁₀O₁₇:Eu²⁺ (blue), Zn₂SiO₄:Mn²⁺ (green), and YBO₃:Eu³⁺ (red), with an average particle diameter of 2 to 3 μm can be used. The insulating layer 4 of MgO is formed on a surface of each phosphor particle in a common manner. Specifically, the phosphor particle 3 is added to an Mg precursor complex solution, stirred for a long time, and then taken out from the solution, followed by drying. After that, the phosphor particle 3 is subjected to heat treatment at 400° C. to 600° C. in the atmosphere, whereby a uniform coating layer of MgO, i.e., the insulating layer 4, is formed on the surface of the phosphor particle 3.

In the present embodiment, a kneaded paste containing 45 mass % of terpineol (α-terpineol) and 5 mass % of ethyl cellulose with respect to 50 mass % of the phosphor particle coated with the insulating layer 4 is prepared for each phosphor. As shown in FIG. 4, the porous light-emitting layer 2 is screen-printed into a predetermined shape by using this paste, followed by drying. This operation is repeated a plurality of times, so that the thickness of the printed porous light-emitting layer is adjusted to be 80 to 100 μm.

As shown in FIG. 4, in order for the porous light-emitting layers to emit red (R), green (G), and blue (B) light, respectively, the porous light-emitting layers, in general, are formed so as to be arranged regularly by being printed in order in a predetermined pattern (e.g., a strip shape) for the respective luminescent colors. However, it is also possible to form a light-emitting layer that emits white light, which then is separated into desired luminescent colors by a color filter.

The substrate 5 on which the porous light-emitting layers are printed as described above is placed finally in an N₂ atmosphere, and subjected to heat treatment at 400° C. to 600° C. for 2 to 5 hours, whereby the assembly of the porous light-emitting layers 2 with a thickness of about 50 to 80 μm is formed.

The paste is obtained by adding the organic binder and the organic solvent to the phosphor particle. However, the same effect is achieved by using a paste obtained by adding a colloidal silica solution to the phosphor particle.

FIG. 6 is an enlarged schematic cross-sectional view of the porous light-emitting layer 2 of the present embodiment. The figure shows a state in which the phosphor particles 3, each being coated uniformly with the insulating layer 4 of MgO, are in contact with each other as a result of being subjected to the heat treatment to form the porous light-emitting layer.

In the present embodiment, since the heat treatment temperature is set to be relatively low, the porosity of the porous light-emitting layer is increased. The apparent porosity is in a range of not less than 10% to less than 100%. It is not preferable that the porosity is increased extremely to 100%, so that pores are opened widely, because such a porous light-emitting layer causes a decrease in luminous efficiency and air discharge to occur therein. On the other hand, when the porosity is less than 10%, the generation of surface discharge is inhibited. (Surface discharge occurs at an interface between gas (in this case, an air gap) and an insulator solid (phosphor particle). When the apparent porosity is decreased, the air gaps disappear, resulting in difficulty in generating surface discharge. On the other hand, when the apparent porosity is increased, the air gaps become larger than a mean free path of electrons as mentioned above, resulting in difficulty in generating surface discharge.) When the apparent porosity is in a range of not less than 10% to less than 100%, it is assumed that the phosphor particles are in approximate point contact so as to be adjacent three-dimensionally to each other.

Then, in the assembly of the porous light-emitting layers 2, a glass paste is screen-printed at boundaries between the porous light-emitting layers, followed by drying. This operation is repeated a plurality of times, and the assembly is subjected to heat treatment at 600° C. As a result, the partition wall 11 with a thickness of about 80 to 300 μm is formed as shown in FIG. 5. In the present embodiment, although the partition wall 11 is formed after the formation of the porous light-emitting layer, the partition wall may be formed in advance. Further, the partition wall 11 may be formed of a glass paste or a resin containing ceramic particles. Specifically, in the former case, a kneaded paste containing 50 mass % of α-terpineol with respect to 50 mass % of mixed particles of ceramic and glass (1:1 by weight) is screen-printed in a predetermined pattern, followed by drying. This operation is repeated so that the thickness of the printed paste is adjusted to be about 100 to 350 μm. The thus obtained assembly is subjected to heat treatment at 400° C. to 600° C. for 2 to 5 hours in an N₂ atmosphere, whereby the partition wall 11 with a thickness of about 80 to 300 μm can be formed. In the latter case, the partition wall is formed of a thermosetting resin, such as an epoxy resin, a phenol resin, and a cyanate resin. One of these resins is screen-printed in the air gap between the porous light-emitting layers to form the partition wall.

After the formation of the partition wall 11 in the above-mentioned manner, the assembly of the porous light-emitting layers is covered entirely with the transparent substrate 8 such as a glass plate on which the second electrode 7 made of ITO (indium-tin oxide alloy) is formed beforehand so as to be opposed to the porous light-emitting layer, whereby the light-emitting element 1 of the present embodiment as shown in FIG. 1 is obtained. At this time, the transparent substrate 8 is attached to the partition wall 11 by using colloidal silica, water glass, a resin, or the like, so that the slight gap is provided between the porous light-emitting layer 2 and the second electrode 7. The gap 9 between the porous light-emitting layer 2 and the second electrode 7 preferably has a vertical width in a range of 30 to 250 μm, and in particular in a range of 40 to 220 μm. When the width is beyond this range, a high voltage is required to be applied for the generation of primary electrons due to gas breakdown, which is not preferable for the reasons of economical efficiency and reliability. Although the width of the gap may be smaller than the above range, it is desirable that the gap has such a width as to prevent the porous light-emitting layer from being in contact with the second electrode so as to allow the porous light-emitting layer to emit light uniformly and thoroughly.

Instead of the transparent substrate 8 with the second electrode of ITO, a transparent substrate on which copper wiring is provided can be used. Copper wiring is formed in a microporous mesh shape and has an open area ratio (ratio of a portion where no wiring is provided to the entire substrate) of 90%, and accordingly this substrate allows light to pass therethrough approximately as favorably as the transparent substrate with the ITO film. Further, copper is favorable since it has a much lower resistance than ITO and greatly contributes to increased luminous efficiency. As a metal for the wiring of microporous mesh shape, gold, silver, platinum, or aluminum can be used instead of copper. However, in the case of using copper and aluminum that are likely to be oxidized, a treatment for providing resistance to oxidization is necessary.

As described above, in the present embodiment, it is possible to manufacture the light-emitting element that is formed of an assembly of the plurality of porous light-emitting layers, each having the dielectric layer and the first electrode on one surface and the second electrode on the other surface where the dielectric layer and the first electrode are not formed, and includes the discharge separation means between the plurality of porous light-emitting layers. In particular, the partition wall is formed as the discharge separation means between the plurality of porous light-emitting layers, and the dielectric layer is formed on part of the plurality of porous light-emitting layers so that the dielectric layer is shared by the part of the plurality of porous light-emitting layers.

In the present embodiment, the phosphor particle 3 is coated with the insulating layer 4 of MgO. Since MgO has a high specific resistance (10⁹Ω·cm or more), surface discharge can occur efficiently. An insulating layer with a low specific resistance is not preferable since surface discharge is less likely to occur, and a short circuit may occur in some cases. For these reasons, it is desirable to coat the phosphor particle with an insulating metal oxide with a high specific resistance. It should be appreciated that when the phosphor particle itself to be used has a high specific resistance, surface discharge occurs easily without the coating of an insulating metal oxide. As the insulating layer, at least one selected from Y₂O₃, Li₂O, CaO, BaO, SrO, Al₂O₃, SiO₂, and ZrO₂ can be used as well as MgO. These oxides are stable substances with an extremely low standard free energy of formation AGfo (e.g., −100 kcal/mol or less at room temperature). Further, the insulating layer of these substances is favorable since it has a high specific resistance and allows discharge to occur easily, and is less likely to be reduced. Thus, this layer also serves as an excellent protective coating for suppressing reduction and deterioration due to ultraviolet rays of the phosphor particle during discharge, resulting in increased durability of the phosphor.

Further, instead of the above-mentioned sol-gel method, the insulating layer can be formed by chemisorption or physical adsorption using a CVD method, a sputtering method, a deposition method, a laser method, a shearing stress method, and the like. It is desirable for the insulating layer to be homogeneous and uniform so as not to be peeled off. To this end, it is important, in forming the insulating layer, to immerse the phosphor particle in a weak acid solution of acetic acid, oxalic acid, citric acid, or the like so as to wash impurities attached to a surface of the phosphor particle.

Further, it is desirable that the phosphor particle is subjected to a pretreatment in a nitrogen atmosphere at 200° C. to 500° C. for about 1 to 5 hours before the formation of the insulating layer. The reason for this is as follows. A usual phosphor particle contains a large amount of adsorbed water and water of crystallization, and the formation of the insulating layer on the phosphor particle in such a state exerts an undesirable effect on the lifetime property, such as a deterioration in brightness and a shift in emission spectrum. When the phosphor particle is washed with a weak acid solution, it is rinsed thoroughly in water before performing the pretreatment.

The points to note during the heat treatment process for forming the porous light-emitting layer include heat treatment temperature and atmosphere. In the present embodiment, since the heat treatment is performed in a nitrogen atmosphere at a temperature in a range of 450° C. to 1200° C., a valence of the doped rare earth element in the phosphor is not changed. When the treatment is performed at temperatures higher than this temperature range, however, the valence of the doped rare earth element may be changed or a solid solution of the insulating layer and the phosphor may be formed, and therefore care should be taken to avoid this.

Also, care should be given to the phenomenon in which the apparent porosity of the porous light-emitting layer decreases with increasing heat treatment temperature. Considering the facts as above, the optimum heat treatment temperature is preferably in a range of 450° C. to 1200° C. As for the heat treatment atmosphere, it is preferable to perform the heat treatment in a nitrogen atmosphere so as to avoid an effect on the valence of the doped rare earth element in the phosphor particle.

In the present embodiment, the thickness of the insulating layer is set to about 0.1 to 2.0 μm. However, the thickness may be determined in view of an average particle diameter of the phosphor particle and efficiency of surface discharge occurrence. Preferably, the phosphor with an average particle diameter on a submicron order has a relatively thin coating. A large thickness of the insulating layer is not preferable since it may result in a shift in emission spectrum, a deterioration in brightness, and the like. On the contrary, it is assumed that a small thickness of the insulating layer makes it somewhat difficult to cause surface discharge. Therefore, the relationship between the average particle diameter of the phosphor particle and the thickness of the insulating layer is desirably in the proportion of 1 part to 1/10 to 1/500.

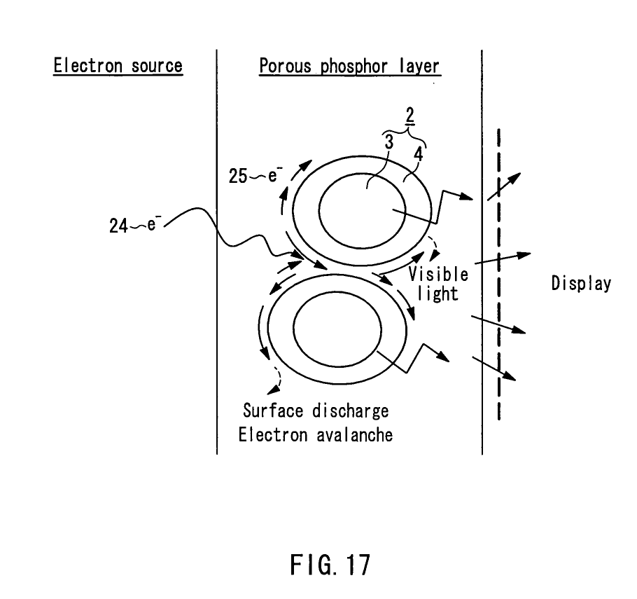

Next, the light emitting action of the light-emitting element 1 will be described with reference to FIGS. 1 and 17.

In order to drive the light-emitting element 1 as shown in FIG. 1, an AC electric field is applied between the first electrode 6 and the second electrode 7. The dielectric layer 10, the porous light-emitting layer 2, and the gap (gas layer) 9 are present in series in a thickness direction between the electrodes 6 and 7. Thus, the applied electric field is focused on the gap 9 in inverse proportion to the capacitance of each of the portions. As a result, gas breakdown is caused in the gap 9, and primary electrons (e−) 24 shown in FIG. 17 are generated. The primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the AC electric field to be applied has its waveform changed from a sine wave or a sawtooth wave to a rectangular wave or has its frequency increased by several tens to thousands of Hz, first electrons, secondary electrons, and ultraviolet rays are emitted very vigorously, resulting in increased emission brightness. Further, as the voltage of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the present embodiment, an electric field (frequency: 1 kHz) of about 0.72 to 1.5 kV/mm is applied in a thickness direction of the porous light-emitting layer to allow the phosphor particles 3 to emit light. Thereafter, an alternating electric field (frequency: 1 kHz) of about 0.5 to 1.0 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element of the present embodiment emits light by surface discharge in the porous light-emitting layer. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, it is possible to provide a light-emitting element that exhibits favorable luminous efficiency and is to be driven with relatively low power consumption when being applied to a large-screen display. In the present embodiment, the partition wall is provided as the discharge separation means at a boundary between the porous light-emitting layers, whereby crosstalk during light emission can be avoided in a relatively simple manner.

### Embodiment 2

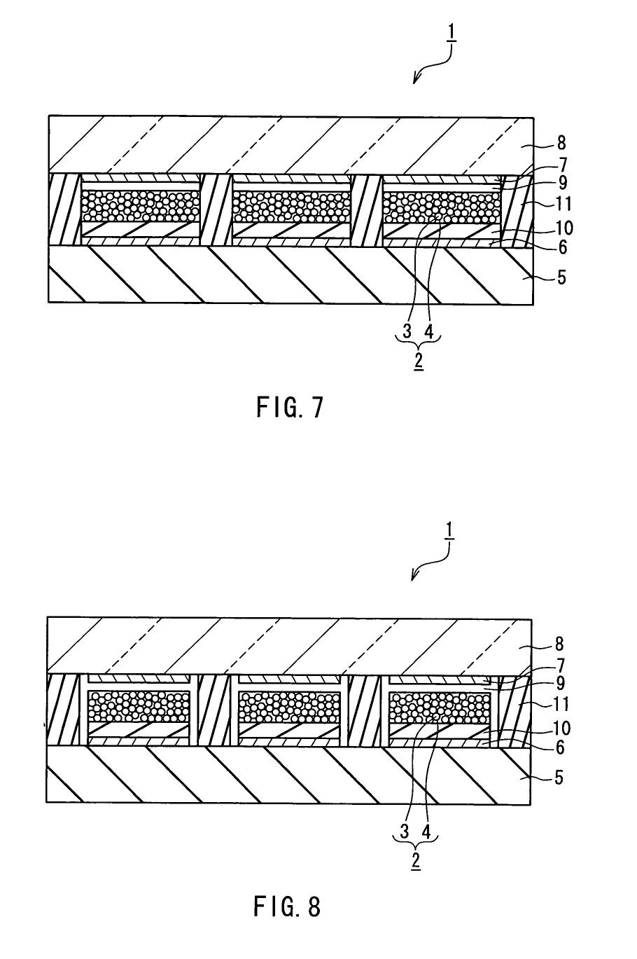

The present embodiment will be described with reference to FIG. 7. In this example, a light-emitting element is formed of an assembly of a plurality of porous light-emitting layers, each having a dielectric layer and a first electrode on one surface and a second electrode on the other surface where the dielectric layer and the first electrode are not formed, and includes discharge separation means between the plurality of porous light-emitting layers. In particular, the discharge separation means is formed of a partition wall. FIG. 7 is a cross-sectional view of the light-emitting element of the present embodiment. Reference numeral 1 denotes a light-emitting element, 2 denotes a porous light-emitting layer, 3 denotes a phosphor particle, 4 denotes an insulating layer, 5 denotes a substrate, 6 denotes a first electrode (back side electrode), 7 denotes a second electrode (observation side electrode), 8 denotes a transparent substrate, 9 denotes a gap (gas layer), 10 denotes a dielectric layer, and 11 denotes a partition wall.

In Embodiment 1, as shown in FIG. 1, the dielectric layer 10 and the first electrode 6 formed under the porous light-emitting layers are shared by the plurality of porous light-emitting layers. However, the dielectric layer and the first electrode may be formed with respect to each of the plurality of porous light-emitting layers. The light-emitting element of the present embodiment has such a configuration, and a cross section thereof is shown in FIG. 7.

The light-emitting element of the present embodiment can be manufactured in the same manner as in Embodiment 1. Practically, an Ag paste is baked initially to form the first electrode 6 at a place where the porous light-emitting layer is to be formed in a predetermined pattern and to be arranged. On the first electrode 6, the dielectric layer is formed by a thick film process or the like, and then the porous light-emitting layer is formed by screen printing. After that, as in Embodiment 1, the partition wall is formed, and finally the transparent substrate 8 with the second electrode is arranged, whereby the light-emitting element of the present embodiment as shown in FIG. 7 can be manufactured.

Next, the light emitting action of the light-emitting element 1 will be described with reference to FIG. 7. In order to drive the light-emitting element 1 as shown in FIG. 7, an AC electric field is applied between the first electrode 6 and the second electrode 7. By the application of an AC electric field, gas breakdown is caused in the gap 9, and accordingly electrons are generated. As a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the AC electric field to be applied has its waveform changed from a sine wave or a sawtooth wave to a rectangular wave or has its frequency increased by several tens to thousands of Hz, electrons and ultraviolet rays are emitted very vigorously by surface discharge, resulting in increased emission brightness. Further, as the voltage of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the present embodiment, an electric field of about 0.72 to 1.5 kV/mm is applied in a thickness direction of the porous light-emitting layer to allow the phosphor particles 3 to emit light. Thereafter, an alternating electric field of about 0.5 to 1.0 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element of the present embodiment emits light by surface discharge in the porous light-emitting layer. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, it is possible to provide a light-emitting layer that exhibits favorable luminous efficiency and is to be driven with relatively low power consumption when being applied to a large-screen display. In the present embodiment, the partition wall is provided as the discharge separation means at a boundary between the porous light-emitting layers, whereby crosstalk during light emission can be avoided in a relatively simple manner.

### Embodiment 3

With reference to FIG. 8, a description will be given of a light-emitting element that is formed of an assembly of a plurality of porous light-emitting layers, each having a dielectric layer and a first electrode on one surface and a second electrode on the other surface where the dielectric layer and the first electrode are not formed, and includes discharge separation means between the plurality of porous light-emitting layers. The discharge separation means is formed of a conductive partition wall.

FIG. 8 is a cross-sectional view of the light-emitting element of the present embodiment. In the figure, reference numeral 1 denotes a light-emitting element, 2 denotes a porous light-emitting layer, 3 denotes a phosphor particle, 4 denotes an insulating layer, 5 denotes a substrate, 6 denotes a first electrode (back side electrode), 7 denotes a second electrode (observation side electrode), 8 denotes a transparent substrate, 9 denotes a gap (gas layer), 10 denotes a dielectric layer, and 11 denotes a partition wall.

As mentioned above, the conductive partition wall 11 that has a static-shielding effect and is effective in extending surface discharge is used as the discharge separation means. Such a conductive partition wall can be formed of a deposited metal of various kinds. A description will be given of a method for forming the conductive partition wall by using electroless nickel plating, for example.

The light-emitting element is manufactured specifically as follows. Initially, on a surface of the substrate 5 made of ceramic, a resist film is screen-printed at places other than a place where the partition wall is to be formed. Then, the substrate 5 is immersed in a solution of tin chloride and palladium chloride. This treatment is referred to as a catalyzing/sensitizing treatment, and the treatment including its pre-treatment and after-treatment can be performed easily with a commercially available treatment agent.

When the resist film is peeled off after the treatment, fine particles of palladium are attached only to the place where the partition wall is to be formed. The ceramic substrate 5 treated in this manner is immersed in a solution (pH 4 to 6) containing nickel sulfite and sodium hypophosphite as main components, and is subjected to a treatment at about 90° C. so that metal nickel is deposited to a thickness of 80 to 300 μm, whereby the partition wall 11 with a predetermined shape can be formed on the surface of the substrate 5. In this manner, the ceramic substrate 5 on which the conductive partition wall 1 is formed can be obtained.

After that, an Ag paste is baked on the substrate 5 to form the first electrode 6. At this time, the first electrode 6 is formed slightly apart from the conductive partition wall 11 so as to be kept from contact therewith. Following the formation of the first electrode 6, the dielectric layer 10 is formed on the first electrode 6 by a thick film process or the like. Then, a paste containing phosphor particles 3, each being coated uniformly with the insulating layer 4, is screen-printed, followed by firing, whereby the porous light-emitting layer 2 is formed in a predetermined pattern. Finally, an assembly of the porous light-emitting layers is covered entirely with the transparent substrate 8 made of glass on which an ITO film is provided as the second electrode 7, resulting in the light-emitting element 1 as shown in FIG. 8. At this time, the second electrode of ITO is spaced slightly apart from the conductive partition wall so as to be kept from contact therewith, whereby the application of a voltage for driving the light-emitting element is not hindered.

In the present embodiment, in the above-mentioned manner, it is possible to obtain the light-emitting element that is formed of an assembly of the plurality of porous light-emitting layers, each having the dielectric layer and the first electrode on one surface and the second electrode on the other surface where the dielectric layer and the first electrode are not formed, and includes the discharge separation means between the plurality of porous light-emitting layers. In particular, the discharge separation means is formed of the conductive partition wall.

Next, the light emitting action of the light-emitting element 1 will be described with reference to FIG. 8. In order to drive the light-emitting element 1 in FIG. 8, an AC electric field is applied between the first electrode 6 and the second electrode 7. By the application of an AC electric field, gas breakdown is caused in the gap 9, and accordingly electrons are generated. As a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the AC electric field to be applied has its waveform changed from a sine wave or a sawtooth wave to a rectangular wave or has its frequency increased by several tens to thousands of Hz, electrons and ultraviolet rays are emitted very vigorously by surface discharge, resulting in increased emission brightness. Further, as a voltage value of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In particular, when the conductive partition wall is formed as in the present embodiment, surface discharge occurs easily, which contributes to a decrease in the driving voltage. More specifically, an electric field of about 0.58 to 1.2 kV/mm is applied in a thickness direction of the porous light-emitting layer to allow the phosphor particles 3 to emit light. Thereafter, an alternating electric field of about 0.4 to 0.8 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

The light-emitting layer of the present embodiment emits light by surface discharge in the porous light-emitting layer. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, it is possible to provide a light-emitting layer that exhibits favorable luminous efficiency and is to be driven with relatively low power consumption when being applied to a large-screen display. In the present embodiment, the partition wall is provided as the discharge separation means at a boundary between the porous light-emitting layers, whereby crosstalk during light emission can be avoided in a relatively simple manner.

### Embodiment 4

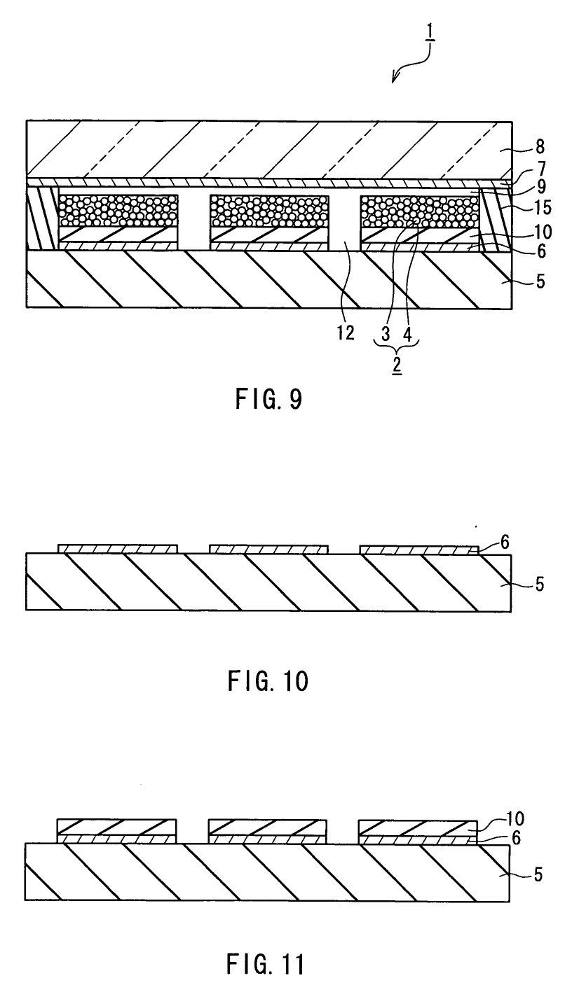

With reference to FIGS. 9 to 13, a description will be given of a light-emitting element that is formed of an assembly of a plurality of porous light-emitting layers, each having a dielectric layer and a first electrode on one surface and a second electrode on the other surface where the dielectric layer and the first electrode are not formed, and includes discharge separation means between the plurality of porous light-emitting layers. In particular, the plurality of porous light-emitting layers are arranged so as to share the second electrode, and the discharge separation means is formed of a gap.

FIG. 9 is a cross-sectional view of the light-emitting element of the present embodiment, and FIGS. 10 to 13 are views for explaining manufacturing processes of the light-emitting element of the present embodiment. In these figures, reference numeral 1 denotes a light-emitting element, 2 denotes a porous light-emitting layer, 3 denotes a phosphor particle, 4 denotes an insulating layer, 5 denotes a substrate, 6 denotes a first electrode (back side electrode), 7 denotes a second electrode (observation side electrode), 8 denotes a transparent substrate, 9 denotes a gap (gas layer), 10 denotes a dielectric layer, 12 denotes a space for separating the porous light-emitting layers, and 15 denotes a side wall.

As shown in FIG. 10, an Ag paste is baked on one side of the substrate 5 made of glass or ceramic to form the first electrode 6 into a predetermined shape. Then, as shown in FIG. 1, the dielectric layer 10 is formed on the first electrode 6 by a thick film process or the like.

After that, the porous light-emitting layer 2 is formed into a predetermined shape on the dielectric layer 10. At this time, the phosphor particles 3, each being coated with the insulating layer 4 made of a metal oxide such as MgO, are used as in Embodiment 1. As the phosphor particle 3, an inorganic compound, such as BaMgAl₁₀O₁₇:Eu²⁺ (blue), Zn₂SiO₄:Mn²⁺ (green), and YBO₃:Eu³⁺ (red), with an average particle diameter of 2 to 3 μm can be used.

In the present embodiment, a kneaded paste containing 45 mass % of α-terpineol and 5 mass % of ethyl cellulose with respect to 50 mass % of the phosphor particle coated with the insulating layer 4 is prepared for each phosphor. This paste is screen-printed on the dielectric layer 10, followed by drying. This operation is repeated a plurality of times, so that the thickness of the printed paste is adjusted to be 80 to 100 μm.

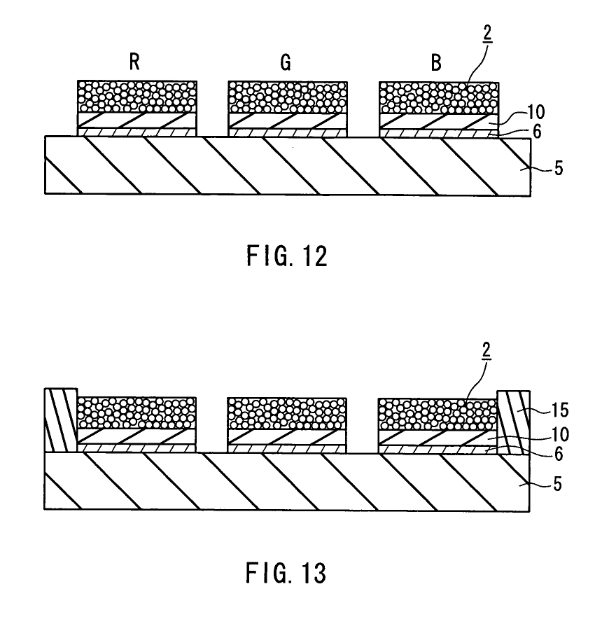

The substrate 5 on which the porous light emitting layer is printed in the above-mentioned manner is subjected to heat treatment at 400° C. to 600° C. for 2 to 5 hours in an N₂ atmosphere. As a result, as shown in FIG. 12, an assembly of the porous light-emitting layers 2 with a thickness of about 50 to 80 μm is formed on the substrate.

Then, in the present embodiment, the space 12 of about 80 to 300 μm is left, instead of providing a partition wall, at a boundary in the assembly of the porous light-emitting layers, and functions as an alternative to the partition wall. In the present embodiment, the side wall 15 is formed so as to surround the entire assembly of the porous light-emitting layers, thereby supporting the transparent substrate 8 as described later. The side wall 15 is formed by screen-printing of a glass paste, followed by drying. This operation is performed a plurality of times, and then the thus-obtained substrate is fired at 600° C. As a result, as shown in FIG. 13, the side wall 15 with a thickness of about 80 to 300 μm is formed.

The side wall 15 may be formed of a glass paste or a resin containing ceramic particles. Specifically, in the former case, a kneaded paste containing 50 mass % of α-terpineol with respect to 50 mass % of mixed particles of ceramic and glass (1:1 by weight) is screen-printed, followed by drying. This operation is repeated so that the thickness of the printed paste is adjusted to be about 100 to 350 μm. Then, the thus-obtained substrate is subjected to heat treatment at 400° C. to 600° C. for 2 to 5 hours in an N₂ atmosphere, whereby the side wall 15 with a thickness of about 80 to 300 μm can be formed. In the latter case, the side wall is formed of a thermosetting resin, such as an epoxy resin, a phenol resin, and a cyanate resin. One of these resins is selected and printed so as to surround the entire assembly of the porous light-emitting layers.

After the formation of the side wall 15 in the above-mentioned manner, the transparent substrate 8 such as a glass plate on which the second electrode 7 made of ITO (indium-tin oxide alloy) is formed is adhered to the side wall 15 so as to cover the assembly of the porous light-emitting layers entirely, whereby the light-emitting element 1 in the present embodiment as shown in FIG. 9 is obtained. At this time, as shown in the figure, the second electrode 7 is formed in a stripe shape, for example, so as to be opposed to the porous light-emitting layer, and is shared by the plurality of porous light-emitting layers. The slight gap is provided between the porous light-emitting layer 2 and the second electrode 7, and the width of the gap is preferably in a range of 30 to 250 μm, and in particular in a range of 40 to 220 μm.

Instead of the transparent substrate 8 with the second electrode of ITO, a substrate on which mesh-shaped fine wiring made of copper, gold, silver, platinum, aluminum, or the like is patterned can be used.

As described above, it is possible to manufacture the light-emitting element that is formed of an assembly of the plurality of porous light-emitting layers, each having a dielectric layer and the first electrode on one surface and the second electrode on the other surface where the dielectric layer and the first electrode are not formed, and includes the discharge separation means between the plurality of porous light-emitting layers. In particular the second electrode is arranged so as to be shared by the plurality of porous light-emitting layers, and the discharge separation means is formed of the space.

Next, the light emitting action of this light-emitting element 1 will be described with reference to FIG. 9. In order to drive the light-emitting element 1 as shown in FIG. 9, an AC electric field is applied between the first electrode 6 and the second electrode 7. By the application of an AC electric field, gas breakdown is caused in the gap 9, and accordingly electrons are generated. As a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the AC electric field to be applied has its waveform changed from a sine wave or a sawtooth wave to a rectangular wave or has its frequency increased by several tens to thousands of Hz, electrons and ultraviolet rays are emitted very vigorously by surface discharge, resulting in increased emission brightness. Further, as a voltage value of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the present embodiment, an electric field of about 0.85 to 1.8 kV/mm is applied in a thickness direction of the porous light-emitting layer to allow the phosphor particles 3 to emit light. Thereafter, an alternating electric field of about 0.6 to 1.2 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element of the present embodiment emits light by surface discharge in the porous light-emitting layer. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, it is possible to provide a light-emitting layer that exhibits favorable luminous efficiency and is to be driven with relatively low power consumption when being applied to a large-screen display. In the present embodiment, the space is provided as the discharge separation means at a boundary between the porous light-emitting layers, whereby crosstalk during light emission can be avoided in a relatively simple manner.

### Embodiment 5

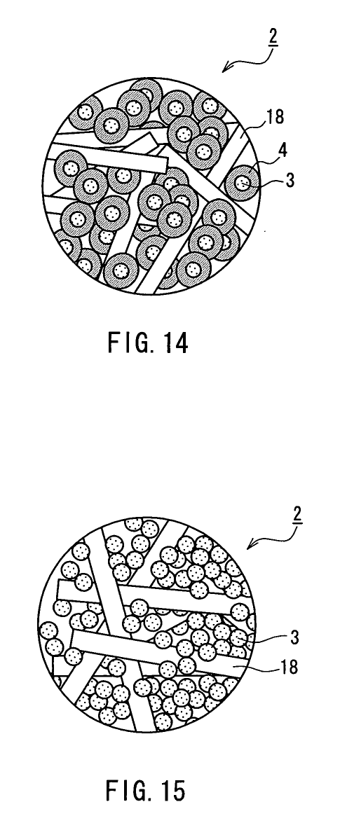

With reference to FIGS. 14 and 15, a description will be given of a light-emitting element that is formed of an assembly of a plurality of porous light-emitting layers, each having a dielectric layer and a first electrode on one surface and a second electrode on the other surface where the dielectric layer and the first electrode are not formed, and includes discharge separation means between the plurality of porous light-emitting layers. The following description is directed particularly to the porous light-emitting layer.

FIGS. 14 and 15 are schematic enlarged cross-sectional views of the porous light-emitting layer of the present embodiment. In these figures, reference numeral 2 denotes a porous light-emitting layer, 3 denotes a phosphor particle, 4 denotes an insulating layer, and 18 denotes an insulative fiber.

In the present embodiment, the porous light-emitting layer 2 is formed of the phosphor particles and the insulative fibers 18 of ceramic, glass, or the like, regardless of the presence/absence of the insulating layer on a surface of the phosphor particle.

An example of the insulative fiber 18 includes a SiO₂—Al₂O₃—CaO based fiber, which preferably has a diameter of 0.1 to 5 μm and a length of 0.5 to 20 μm. Preferably, 1 weight part of fiber having dimensions in the above range is used with respect to 2 weight parts of phosphor particle, whereby the porosity is increased relatively, and accordingly surface discharge occurs easily in the porous light-emitting layer. In the present embodiment, for the formation of the porous light-emitting layer, a kneaded paste containing 45 mass % of α-terpineol and 5 mass % of ethyl cellulose with respect to 50 mass % of a mixture of the phosphor particles and the insulative fibers is prepared. The paste is screen-printed in a pattern to form the porous light-emitting layer as in Embodiment 1. FIGS. 14 and 15 are schematic enlarged cross-sectional views of the thus-obtained porous light-emitting layer containing the insulative fibers 18. FIG. 15 shows the porous light-emitting layer 2 formed of the phosphor particles 3 and the insulative fibers 18. FIG. 14 shows the porous light-emitting layer formed of the phosphor particles 3, each being coated with the insulating layer 4, and the insulative fibers. The first electrode, the dielectric layer, the second electrode, and the partition wall are formed in the same manner as in Embodiment 1, and finally the same light-emitting element as in Embodiment 1 is manufactured (not shown).

The reason for selecting a SiO₂—Al₂O₃—CaO based fiber as the insulative fiber is as follows. That is, a SiO₂—Al₂O₃—CaO based fiber is thermally and chemically stable, has a specific resistance of 10⁹ Ω·cm or more, achieves easily a high apparent porosity in a range of not less than 10% to less than 100% in the porous light-emitting layer, and allows discharge to occur easily on a surface of the fiber, allowing surface discharge to occur in the entire porous light-emitting layer. Instead of the above-mentioned insulative fiber, an insulative fiber including a fiber of SiC base, ZnO base, TiO₂ base, MgO base, BN base, and Si₃N₄ base may be used to achieve substantially the same effect.

The light emitting action of this light-emitting element is the same as in Embodiment 1. In order to drive the light-emitting element, an AC electric field is applied between the first electrode and the second electrode. By the application of an AC electric field, gas breakdown is caused in the gap 9, and accordingly electrons are generated. As a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

In the present embodiment, an electric field of about 0.65 to 1.4 kV/mm is applied in a thickness direction of the porous light-emitting layer to allow the phosphor particles 3 to emit light. Thereafter, an alternating electric field of about 0.45 to 0.90 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element of the present embodiment emits light by surface discharge in the porous light-emitting layer. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, it is possible to provide a light-emitting layer that exhibits favorable luminous efficiency and is to be driven with relatively low power consumption when being applied to a large-screen display. In the present embodiment, the partition wall is provided as the discharge separation means at a boundary between the porous light-emitting layers, whereby crosstalk during light emission can be avoided in a relatively simple manner.

### Embodiment 6

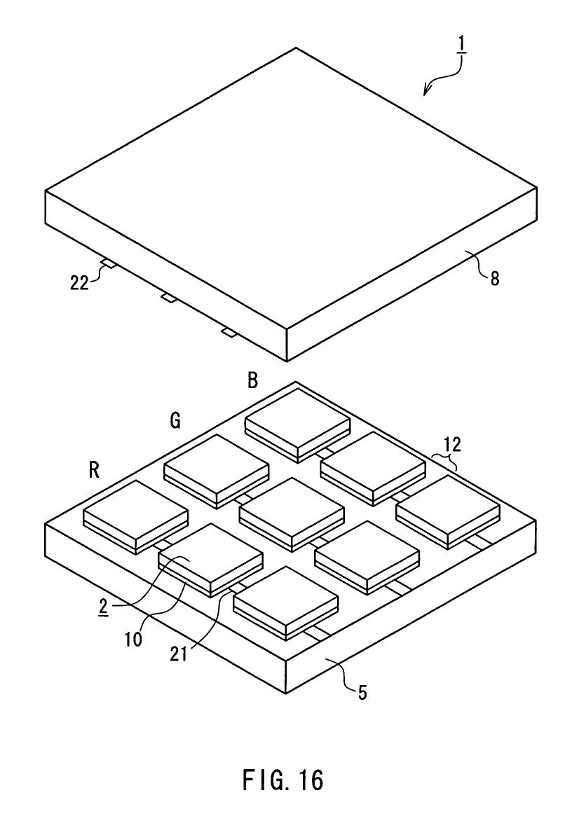

With reference to FIG. 16, a description will be given of an operation of a light-emitting element that is formed of an assembly of a plurality of porous light-emitting layers, each having a dielectric layer and an address electrode on one surface and a data electrode on the other surface where the dielectric layer and the address electrode are not formed, and includes discharge separation means between the plurality of porous light-emitting layers.

FIG. 16 is an exploded perspective view of the light-emitting element of the present embodiment. For the sake of clarity, the light-emitting element in which the discharge separation means is formed of a gap is shown. In the figure, reference numeral 1 denotes a light-emitting element, 2 denotes a porous light-emitting layer, 5 denotes a substrate, 8 denotes a transparent substrate, 10 denotes a dielectric layer, 12 denotes a gap, 21 denotes an address electrode, and 22 denotes a display electrode.

As shown in FIG. 16, in the light-emitting element 1 of the present embodiment, the address electrode 21 is formed on the substrate 5, and the plurality of porous light-emitting layers 2, each having the dielectric layer 10, are arranged regularly thereon, whereby an array of the porous light-emitting layers that emit light of three colors R, G, and B, respectively, is formed. The gap 12 is present between the porous light-emitting layers, and a side wall usually is provided (not shown) so as to surround the entire array of the porous light-emitting layers 2. On the transparent substrate 8, the display electrode 22 is formed so as to be opposed to the porous light-emitting layer 2 and to cross the address electrode 21. When this transparent substrate 8 is arranged on the array of the porous light-emitting layers, the light-emitting element 1 as shown in FIG. 16 is obtained finally. Although the address electrode and the display electrode in the present embodiment may correspond to the first electrode and the second electrode, respectively, in Embodiments 1 to 5, these electrodes may be provided additionally in some cases.

As described above, it is possible to obtain the light-emitting element that is formed of an assembly of the plurality of porous light-emitting layers, each having the dielectric layer and the address electrode on one surface and the data electrode on the other surface where the dielectric layer and the address electrode are not formed, and includes the discharge separation means between the plurality of porous light-emitting layers. In particular, the discharge separation means is formed of the gap.

In the thus-configured light-emitting layer 1 of the present embodiment, a two-dimensional image can be displayed on the porous light-emitting layer. Specifically, the light-emitting element 1 of the present embodiment can be driven in a so-called simple matrix. A pulse signal is transmitted sequentially to an X electrode, and ON/OFF information is input to a Y electrode at a timing of the signal transmission, whereby a pixel at a place where the address electrode and the display electrode cross each other is allowed to emit light in accordance with the ON/OFF information, so that one line is displayed. A two-dimensional image can be displayed by switching scan pulses sequentially. Further, when a transistor is provided for each pixel arranged in a matrix so as to turn ON/OFF the pixel, the light-emitting element 1 can be driven more actively. In the present embodiment, since the gap 12 is provided between the porous light-emitting layers, little crosstalk occurs during light emission. However, when a partition wall is provided between the unit light-emitting elements as in Embodiment 1, crosstalk during light emission can be avoided almost completely.

### Embodiment 7

FIG. 18 shows a cross section of a display device of the present embodiment. The present embodiment is the same as Embodiment 1 shown in FIG. 1 except for ribs 23a and 23b provided between the partition walls 11. The partition wall 11 has a horizontal thickness of 150 μm and a height of 270 μm. The ribs 23a and 23b have a thickness of 50 μm and a height of 250 μm. The width of one pixel is 100 μm. The porous light-emitting layer has a thickness of 230 μm. The gap (gas layer) 9 has a width of a distance of 20 μm. The dielectric layer 10 made of BaTiO₃ has a thickness of 250 μm. A distance between the first electrode 6 and the second electrode 7 is 500 μm.

In the present embodiment, an electric field (frequency: 1 kHz) of about 0.72 to 1.5 kV/mm is applied in a thickness direction of the porous light-emitting layer to allow the phosphor particles 3 to emit light. Thereafter, an alternating electric field (frequency: 1 kHz) of about 0.4 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

### Embodiment 8

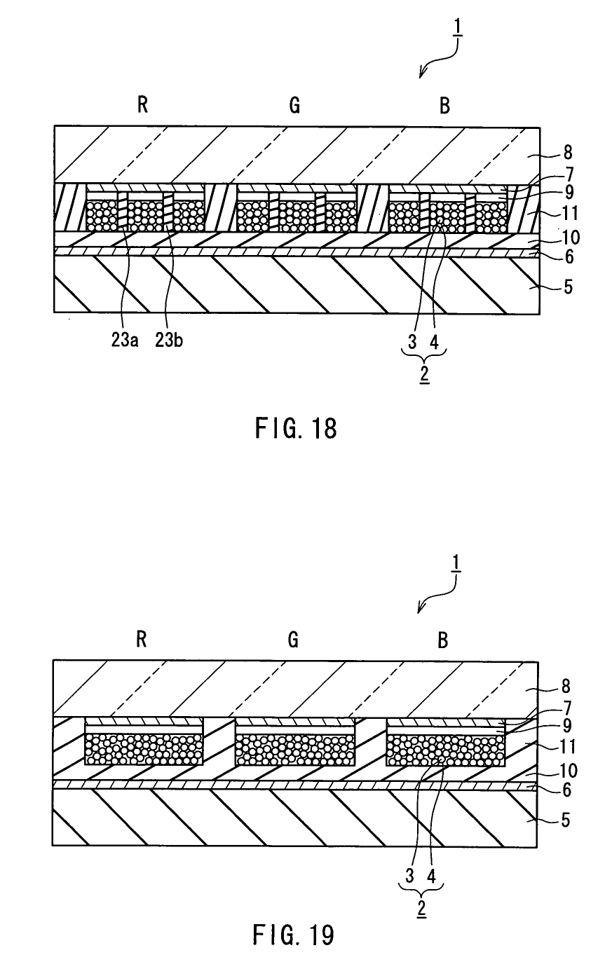

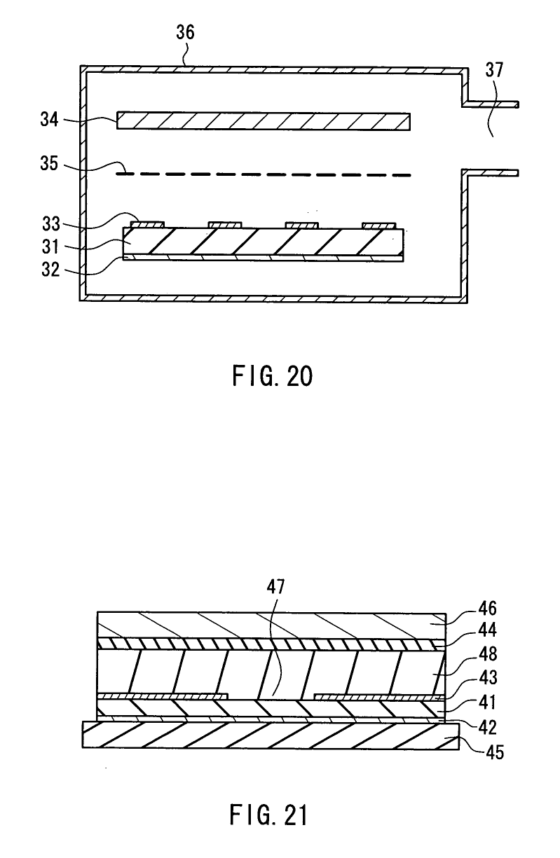

FIG. 19 shows a cross section of a display device of the present embodiment. The present embodiment is the same as Embodiment 1 shown in FIG. 1 except that the partition wall 11 is formed by cutting the dielectric layer 10 made of BaTiO₃. The partition wall 11 has a horizontal thickness of 150 μm and a height of 270 μm. The width of one pixel is 250 μm. The porous light-emitting layer has a thickness of 230 μm. The gap 9 has a width of 20 μm. The dielectric layer made of BaTiO₃ has a thickness of 520 μm. A distance between the first and second electrodes is 500 μm.

In the present embodiment, an electric field (frequency: 1 kHz) of about 0.72 to 1.5 kV/mm is applied in a thickness direction of the porous light-emitting layer to allow the phosphor particles 3 to emit light. Thereafter, an alternating electric field (frequency: 1 kHz) of about 0.4 kV/mm is applied, so that surface discharge occurs continuously to sustain the light emission of the phosphor particles 3. When a higher electric field is applied, the generation of electrons and ultraviolet rays is accelerated, and when a lower electric field is applied, the generation thereof is insufficient.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of each of the three colors.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

### COMPARATIVE EXAMPLE 1

As Comparative Example 1, silicone oil was impregnated as in a dielectric breakdown test of a multilayer chip capacitor. Specifically, in a multilayer chip capacitor, a true dielectric breakdown voltage value cannot be measured since surface discharge occurs frequently. To solve this problem, silicone oil was impregnated into fine pore portions of an element, and a true dielectric breakdown voltage value was obtained in a state in which no surface discharge occurred. Based on this method, gas in fine pores in the porous light-emitting layer 2 of the light-emitting element 1 in FIG. 1 was substituted by silicone oil. The fine pores were impregnated with the silicone oil for several minutes, followed by wiping the silicone oil off a surface of the light-emitting element, and an alternating electric field as in Embodiment 1 was applied.

It was confirmed that when a higher voltage was applied, a burst wave was generated and primary electrons were emitted from the gap. However, no surface discharge occurred in the porous light-emitting layer 2, or surface discharge, if any, occurred in an uppermost surface portion and not in the light-emitting layer 2, and thus no light emission was confirmed. Further, when a further higher voltage was applied, dielectric breakdown occurred instantly in the porous light-emitting layer 2, and the light-emitting element 1 was cracked and destroyed.

It was confirmed that when the light-emitting element 1 impregnated with the silicone oil was washed with an organic solvent such as acetone, and the fine pore portions were refilled with gas, light emission was recovered easily. Light emission was observed also when the fine pore portions were evacuated.

Further, when the fine pore portions were impregnated with a conductive solution such as an acetic acid aqueous solution, short circuit occurred, and no light emission was observed.

From the above, in order to achieve a light-emitting element with the configuration of the present invention, it is necessary that the light-emitting layer 2 has fine pores connected to its surface, and that the fine pores are filled with gas or evacuated. When externally emitted electrons rush into the light-emitting layer 4, the electrons are accelerated while causing surface discharge repeatedly in an avalanche manner along the fine pore portions. Then, the accelerated electrons collide with the luminescence center of the phosphor particles, so that the phosphor particles are excited to emit light. In a state in which the fine pore portions are filled with silicon oil or a conductive solution, it is difficult for electrons to move, or short circuit occurs, so that no surface discharge occurs, and accordingly no light is emitted.

In the present embodiments, the fine pore portion has a size of several hundreds μm or less. However, care should be taken when the size of the fine pore portion is several mm or more, since air discharge may occur to destroy the element. Empirically, the phosphor particles 3 are packed so as to be in point contact with each other. Ideally, it is desirable that the light-emitting layer is porous with an apparent porosity in a range of not less than 10% to less than 100%.

As in the above embodiments, the insulating layer 4 is provided for the following reasons:

a. To increase the surface resistance of the phosphor particle 3 to cause surface discharge easily;

b. To protect the phosphor particle from dielectric breakdown and ultraviolet rays; and

c. To allow more electrons to be emitted by secondary electron emitting action of MgO or the like so as to cause surface discharge more easily.

The thickness of the porous light-emitting layer 2 is not particularly limited. However, light emission was observed when the thickness was in a range of 10 μm to 3 mm caused. It should be appreciated that without the occurrence of short circuit, light is emitted even when the thickness is as small as several μm.

### Embodiment 9

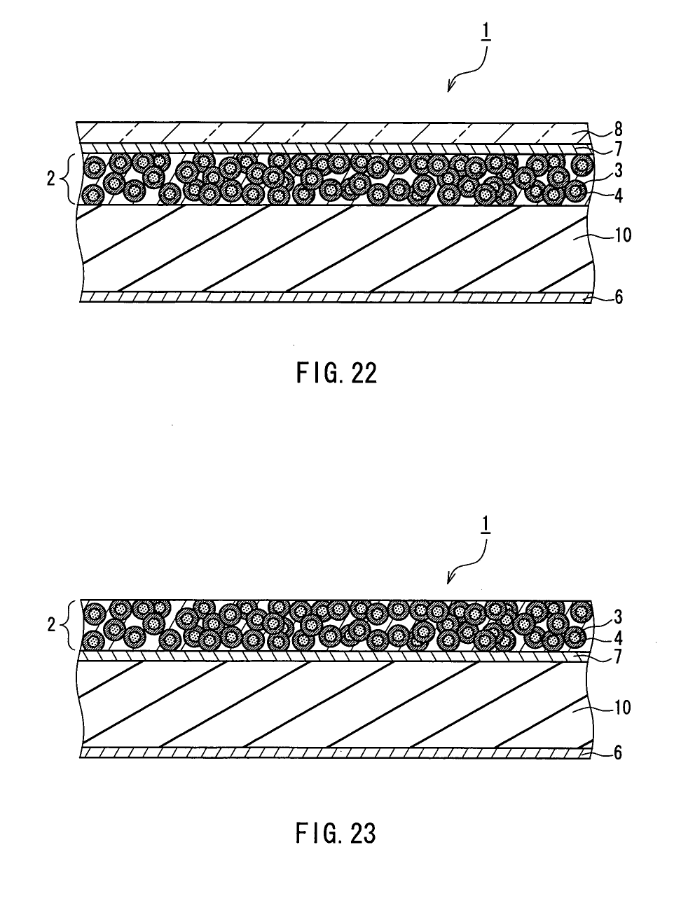

In Embodiment 9, with reference to FIG. 22, a description will be given of the case where the first electrode 6 and the second electrode 7 are formed so as to sandwich the dielectric layer 10 and the porous light-emitting layer 2 therebetween. FIG. 22 is a cross-sectional view of the light-emitting element 1 of the present embodiment. Reference numeral 6 denotes a first electrode, 7 denotes a second electrode, 3 denotes a phosphor particle, 4 denotes an electrically insulating layer, 2 denotes a porous light-emitting layer, and 10 denotes a dielectric layer. As shown in FIG. 6, the porous light-emitting layer 2 is formed of the phosphor particles 3 as a main component, and each of the phosphor particles 3 is coated with the insulating layer 4.

In order to achieve desired light emission, three inorganic compounds of BaMgAl₁₀O₁₇:Eu²⁺ (blue), Zn₂SiO₄:Mn²⁺ (green), and YBO₃:Eu³⁺ (red), each having an average particle diameter of 2 to 3 μm, can be used as the phosphor particle 3 singly or in a mixture.

In the present embodiment, the blue phosphor particle 3 coated with the insulating layer 4 of an insulative inorganic substance of MgO is used. The phosphor particles are added to an Mg precursor complex solution, stirred, and taken out from the solution, followed by drying. After that, the phosphor particle is subjected to heat treatment at 400° C. to 600° C. in the atmosphere, whereby a uniform coating layer of MgO shown in FIG. 6 is formed on a surface of the phosphor.

First, a method for manufacturing the light-emitting element of the present embodiment as shown in FIG. 22 will be described. 50 mass % of the phosphor particle powder 3 coated with the insulating layer 4 and 50 mass % of a colloidal silica solution are mixed to form a slurry. Then, the slurry is applied to one surface of the dielectric layer 10 (i.e., a plate-shaped sintered body containing BaTiO₃ as a main component, on a back surface of which an Ag electrode paste is baked to a thickness of about 50 μm to form the first electrode 6) with a diameter of 15 mmΦ and a thickness of 1 mm, on the other surface of which the first electrode 6 is formed, and drying is carried out with a dryer at 100° C. to 150° C. for 10 to 30 minutes. As a result, the porous light-emitting layer 2 with a thickness of about 100 μm is laminated on the dielectric layer 10. Further, on a top surface of the porous light-emitting layer 2, the transparent substrate (glass plate) 8 to which the transparent second electrode (indium-tin oxide alloy (ITO), thickness: about 0.1 μm) 7 is applied is laminated. Consequently, the light-emitting element 1 in which a pair of the electrodes 6 and 7 are formed so as to sandwich the dielectric layer 10 and the porous light-emitting layer 2 therebetween is obtained.

Next, the light emitting action of the light-emitting element 1 will be described with reference to FIGS. 22 and 17. In order to drive the light-emitting element 1 as shown in FIG. 22, an AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. The primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the AC electric field to be applied has its waveform changed from a sine wave or a sawtooth wave to a rectangular wave or has its frequency increased by several tens to thousands of Hz, electrons and ultraviolet rays are emitted very vigorously by surface discharge, resulting in increased emission brightness. Further, as the voltage of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the present embodiment, when a voltage of about 0.5 to 1.0 kV/mm is applied in a thickness direction of the dielectric layer 10 by using an AC power supply, the primary electrons (e−) 24 are emitted due to polarization reversal and the secondary electrons (e−) 25 are generated due to surface discharge, followed by light emission. A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. Further, it becomes possible to manufacture a light-emitting device with luminous efficiency of about 2 to 5 lm/w.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element 1 of the present embodiment has a structure similar to that of an inorganic EL display (ELD), but has a completely different configuration and mechanism. Regarding the configuration, a phosphor used in an inorganic EL display is a light-emitting body formed of a semiconductor such as ZnS:Mn²⁺ and GaP:N as described in the background art section. On the other hand, the phosphor particle in Embodiment 9 may be either an insulator or a semiconductor. More specifically, even when the phosphor particle is formed of a semiconductor with an extremely low resistance value, surface discharge occurs continuously without the occurrence of short circuit due to the uniform coating of the insulating layer 4 of an insulative inorganic substance, and the phosphor particle is allowed to emit light. In an inorganic EL display, a phosphor layer has a thickness of submicron to several μm. On the other hand, the phosphor layer in Embodiment 9 has a porous structure with a thickness of several μm to several hundreds μm. Further, in Embodiment 9, the light-emitting layer has a porous structure.

Regarding the porous structure, as a result of observation with an SEM (scanning electron microscope), the phosphor particles are packed so as to be in point contact with each other.

As the phosphor particle, powder that emits ultraviolet rays, which is used in current plasma display panels (PDPs), is used. However, it was confirmed that ZnS:Ag (blue), ZnS:Cu, Au,Al (green), and Y₂O₃ (red), which were used in cathode ray tubes (CRTs), also emitted light similarly. Since the phosphor for use in CRTs has a low resistance value, surface discharge is less likely to occur. However, the coating of the insulating layer 4 allows surface discharge to occur easily, and accordingly light is emitted easily.

The light-emitting element of the present invention emits light by surface discharge that occurs in an avalanche manner due to electrons emitted by polarization reversal in the dielectric. On this account, when a system having a new function, other than polarization reversal, of allowing electrons to collide is added to the porous light-emitting layer 2, the light-emitting element is expected to emit light easily.

In the present embodiment, a colloidal silica solution is used to form the slurry of the phosphor particles 3. However, it was confirmed that the same effect also was achieved by using an organic solvent. A kneaded slurry containing 45 mass % of α-terpineol and 5 mass % of ethyl cellulose with respect to 50 mass % of the phosphor particle is used and screen-printed on a surface of the dielectric layer 10. The thus-obtained substrate is subjected to heat treatment at 400° C. to 600° C. for 10 to 60 minutes in the atmosphere, whereby the porous light-emitting layer 2 with a thickness of several μm to several tens μm can be formed. In this case, controlling temperature and heat treatment atmosphere is important since the phosphor is likely to be deteriorated when the heat treatment temperature is increased excessively. Further, the organic slurry may contain inorganic fibers 18 to achieve the same effect.

In the present embodiment, BaTiO₃ is used as the dielectric. However, it was confirmed that the same effect also was achieved by using SrTiO₃, CaTiO₃, MgTiO₃, PZT(PbZrTiO₃), PbTiO₃, or the like as the dielectric. Further, the dielectric layer may be formed of a sintered body or may be formed by sputtering, CVD, deposition or with a thin film formation process such as a sol-gel process.

In the present embodiment, the dielectric layer is formed of a sintered body. However, light emission is also possible when the dielectric layer is formed of dielectric fine particles and a binder. More specifically, it is possible to use a dielectric layer of dielectric particles and a binder that is formed as follows. A slurry of fine particles in which 15 mass % of glass powder is mixed with respect to 40 mass % of BaTiO₃ powder, the fine particles being kneaded with 40 mass % of α-terpineol and 5 mass % of ethyl cellulose, is applied to an Al metal substrate, followed by drying. Then, the thus-obtained substrate is subjected to heat treatment at 400° C. to 600° C. in the atmosphere.

In the present embodiment, the blue phosphor particle is used. However, it was found that the same effect also was achieved by using a red or green phosphor particle. Further, mixed particles of blue, red, and green also achieve the same effect.

The light-emitting element of the present embodiment emits light by surface discharge. Thus, unlike a conventional light-emitting element, there is no need to use a thin film formation process for forming the phosphor layer, and neither a vacuum system nor a carrier intensifying layer is necessary. Therefore, the light-emitting element has a simple structure and is processed easily.

Further, ITO is used for the electrode 7. However, instead of ITO, copper wiring may be provided on the transparent substrate. Copper wiring is formed in a microporous mesh shape and has an open area ratio (ratio of a portion where no wiring is provided to the entire substrate) of 90%, and accordingly this substrate allows light to pass therethrough approximately as favorably as the transparent substrate with the ITO film. Further, copper is favorable since it has a much lower resistance than ITO and greatly contributes to increased luminous efficiency. As a metal for the wiring of microporous mesh shape, gold, silver, platinum, or aluminum can be used instead of copper.

### Embodiment 10

Next, a manufacturing method and a light emitting action according to Embodiment 10 will be described with reference to FIG. 23. Descriptions for the same reference numerals as in FIG. 22 may be omitted. A mesh-shaped (about 5 to 10 mesh) Ag paste is printed and baked on one surface of the dielectric 10 used in FIG. 22, on the other surface of which the first electrode 6 is formed, whereby the second electrode 7 is formed. Then, as stated above, a slurry of the phosphor particle powder 3 and a colloidal silica solution is applied to a top surface of the second electrode 7, and drying is carried out with a dryer at 100° C. to 150° C. for 10 to 30 minutes. As a result, the porous light-emitting layer 2 with a thickness of about 100 μm is laminated on a surface of the dielectric layer 10. Consequently, the light-emitting element 1 in which the second electrode 7 is formed between the dielectric layer 10 and the porous light-emitting layer 2 and the first electrode 6 is formed exteriorly so as to sandwich the dielectric layer 10 against the second electrode 7 is obtained. This light-emitting element emits light in the same manner as that in FIG. 22. That is, an AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. The primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

As in FIG. 22, when the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness. Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing peak voltage of the burst wave.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In the case of FIG. 23, when a voltage of about 0.7 to 1.2 kV/mm is applied in a thickness direction of the dielectric layer 10, the primary electrons (e−) 24 are emitted due to polarization reversal and the secondary electrons (e−) 25 are generated due to surface discharge as shown in FIG. 17, followed by light emission.

The difference in light emission between FIG. 22 and FIG. 23 is as follows: in the former case, surface discharge is likely to occur vigorously in the porous light-emitting layer 2; in the latter case, surface discharge occurs somewhat weakly, resulting in a slight decrease in brightness.

In FIG. 23, the second electrode 7 has a mesh shape so as to allow the primary electrons (e−) 24 generated by polarization reversal as shown in FIG. 17 to be emitted easily in the porous light-emitting layer 2. If the electrode 7 is formed to have a uniform thickness, the primary electrons (e−) 24 shown in FIG. 17 are less likely to be emitted in the porous light-emitting layer 2.

In the case of FIG. 23, although a coating of MgO or the like is not provided beforehand as the insulating layer 4, the colloidal silica used as a binder functions as the insulating layer 4.

### Embodiment 11

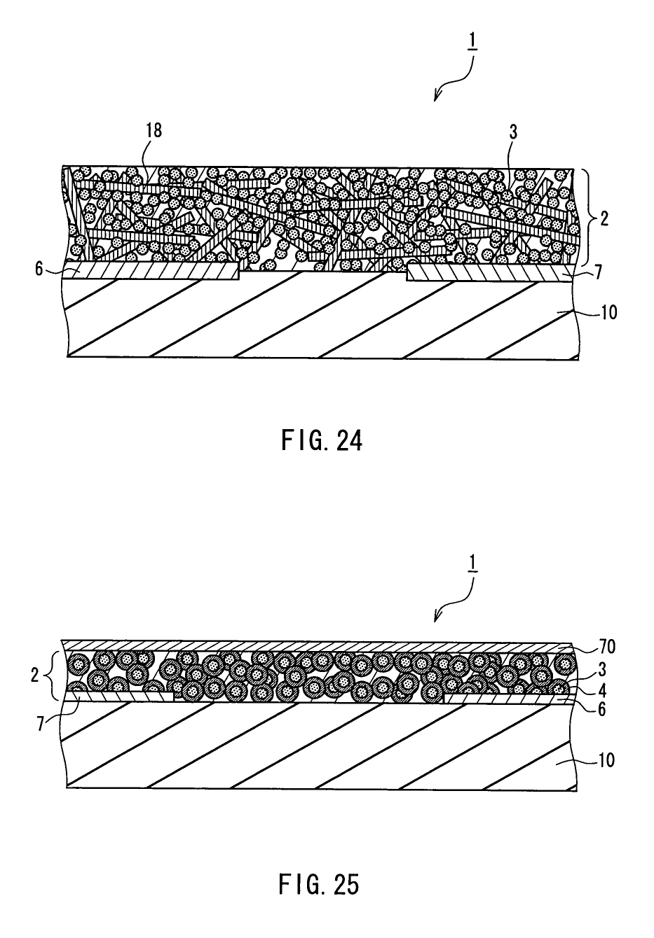

Next, with reference to FIG. 24, a description will be given of the case where a pair of the electrodes 6 and 7 both are formed at a boundary between the dielectric layer 10 and the porous light-emitting layer 2. FIG. 24 is a cross-sectional view of the light-emitting element 1 of Embodiment 11. Reference numeral 6 denotes a first electrode, 7 denotes a second electrode, 3 denotes a phosphor particle, 2 denotes a porous light-emitting layer, and 10 denotes a dielectric layer. The porous light-emitting layer 2 is formed of a material containing the phosphor particles 3 and ceramic fibers 18 as main components. In order to achieve desired light emission, three inorganic compounds of BaMgAl₁₀O₁₇:Eu²⁺ (blue), Zn₂SiO₄:Mn²⁺ (green), and YBO₃:Eu³⁺ (red), each having an average particle diameter of 2 to 3 μm, are used as the phosphor particle 3 singly or in a mixture.

Next, a manufacturing method and a light emitting action of the light-emitting element in FIG. 24 will be described. Initially, an Ag paste is applied to and baked on one surface of the sintered dielectric 10 used in FIG. 22, so that a pair of the electrodes 6 and 7 are formed. Then, a kneaded slurry containing 45 mass % of the phosphor particle, 10 mass % of inorganic fiber powder, 40 mass % of α-terpineol, and 5 mass % of ethyl cellulose is applied, followed by drying. After that, the thus-obtained dielectric 10 is subjected to heat treatment at 400° C. to 600° C., whereby the porous light-emitting layer 2 with a thickness of about 50 μm is laminated on the dielectric layer 10. Consequently, the light-emitting element 1 in which a pair of the electrodes 6 and 7 both are formed at the boundary between the dielectric layer 10 and the porous light-emitting layer 2 is obtained.

This light-emitting element emits light in the same manner as that in FIG. 22. That is, an AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. The primary electrons (e−) collide with the phosphor particles 3 and the ceramic fibers 18 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

When the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness. Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing peak voltage of the burst wave.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In the present embodiment, when a voltage of about 0.7 to 1.2 kV/mm is applied in a thickness direction of the dielectric by using an AC power supply, electrons are emitted due to polarization reversal and surface discharge occurs, followed by light emission. Further, FIG. 24 shows the case where a pair of electrodes both are formed at the boundary between the dielectric layer and the porous light-emitting layer.

### Embodiment 12

With reference to FIG. 25, Embodiment 12 of the present invention will be described. In the present embodiment, a pair of the electrodes 6 and 7 are arranged on a top surface of a dielectric layer, the porous light-emitting layer 2 is laminated on the dielectric layer via a pair of the electrodes, and another electrode 70 is arranged on a top surface of the porous light-emitting layer 2.

FIG. 25 is a cross-sectional view of the light-emitting element 1 of the present embodiment. Reference numerals 6 and 7 denote a first electrode and a second electrode, respectively, as a pair of electrodes. Reference numeral 3 denotes a phosphor particle, 4 denotes an electrically insulating layer, 2 denotes a porous light-emitting layer, 10 denotes a dielectric layer, and 70 denotes a third electrode. As shown in FIG. 6, the porous light-emitting layer is formed of the phosphor particles 3 or a material containing the phosphor particles 3 as a main component. In the present embodiment, the phosphor particle 3 coated with the insulating layer 4 is used.

In order to achieve desired light emission, three inorganic compounds of BaMgAl₁₀O₁₇:Eu²⁺ (blue), Zn₂SiO₄:Mn²⁺ (green), and YBO₃:Eu³⁺ (red), each having an average particle diameter of 2 to 3 μm, are used as the phosphor particle 3 singly or in a mixture.

In the present embodiment, the blue phosphor particle 3 coated with the insulating layer 4 of an insulative inorganic substance of MgO is used. The phosphor particles 3 are added to an Mg precursor complex solution, stirred for a long time, and taken out from the solution, followed by drying. After that, the phosphor particle is subjected to heat treatment at 400° C. to 600° C. in the atmosphere, whereby a uniform coating layer of MgO, i.e., the insulating layer 4, is formed on a surface of the phosphor particle 3.

First, a method for manufacturing the light-emitting element of Embodiment 12 as shown in FIG. 25 will be described. 50 mass % of the phosphor particle 3 coated with the insulating layer 4 and 50 mass % of a colloidal silica solution are mixed to form a slurry. Then, the slurry is applied to the dielectric layer 10 (i.e., a plate-shaped sintered body containing BaTiO₃ as a main component, on a top surface of which an Ag electrode paste is baked to a thickness of 30 μm to form the first electrode 6 and the second electrode 7) with a diameter of 15 mmΦ and a thickness of 1 mm, on which the first electrode 6 and the second electrode 7 are formed, via a pair of the electrodes, i.e., the first electrode 6 and the second electrode 7, and drying is carried out with a dryer at 100° C. to 150° C. for 10 to 30 minutes. As a result, the porous light-emitting layer 2 with a thickness of about 100 μm is laminated on the dielectric layer 10. Further, on a top surface of the porous light-emitting layer 2, a glass (not shown) to which the transparent electrode (indium-tin oxide alloy (ITO), thickness: 0.1 μm) 70 is applied is laminated. Consequently, the light-emitting element 1 as shown in FIG. 25 in which a pair of the electrodes 6 and 7 are formed at a boundary between the dielectric layer 10 and the porous light-emitting layer 2 and the third electrode 70 is formed on the top surface of the porous light-emitting layer is obtained. As described later, an inorganic fiber board supporting phosphor particle powder may be used as the porous light-emitting layer.

Next, the light emitting action of the light-emitting element 1 will be described. An AC electric field is applied between the first electrode 6 and the second electrode 7. By the application of a voltage, polarization reversal is performed in the dielectric layer 10, and accordingly primary electrons (e−) 24 as shown in FIG. 17 are emitted. At this time, ultraviolet rays and visible light are generated. Thereafter, an alternating electric field is applied between the other electrode, i.e., the electrode 70 and at least one of a pair of the electrodes. As a result, the primary electrons (e−) 24 as shown in FIG. 17 collide with the phosphor particles 3 and the insulating layers 4 of the porous light-emitting layer 2 to cause surface discharge, and a large number of secondary electrons (e−) 25 as shown in FIG. 17 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

At this time, when the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness.

Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing voltage of the burst wave. As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In the present embodiment, an electric field of about 0.65 to 1.3 kV/mm is applied in a thickness direction of the dielectric layer 10 for polarization reversal. Thereafter, an alternating electric field of about 0.5 to 1.0 kV/mm is applied in a thickness direction of the light-emitting element 1 by using an AC power supply. As a result, primary electrons are emitted and surface discharge occurs, followed by light emission. When a higher electric field is applied for polarization reversal, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. It becomes possible to manufacture a light-emitting device with luminous efficiency of 2 to 5 lm/W with respect to blue light.

In Embodiment 12, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element 1 of Embodiment 12 has a structure similar to that of an inorganic EL display (ELD), but has a completely different configuration and mechanism. Regarding the configuration, a phosphor used in an inorganic EL display is a light-emitting body formed of a semiconductor such as ZnS:Mn²⁺ and GaP:N as described in the background art section. On the other hand, the phosphor particle in Embodiment 12 may be either an insulator or a semiconductor. More specifically, even when the phosphor particle is formed of a semiconductor with an extremely low resistance value, surface discharge occurs continuously without the occurrence of short circuit since the phosphor particle 3 is coated uniformly with the insulating layer 4 of an insulative inorganic substance as described above, and the phosphor particle is allowed to emit light. In an inorganic EL display, a phosphor layer has a thickness of submicron to several μm. On the other hand, the phosphor layer in the present embodiment has a porous structure with a thickness of several μm to several hundreds μm. Further, in the present embodiment, the light-emitting layer has a porous structure.

Regarding the porous structure, as a result of observation with an SEM (scanning electron microscope), the phosphor particles are packed so as to be in point contact with each other.

As the phosphor particle, powder that emits ultraviolet rays, which is used in current plasma display panels (PDPs), is used. However, it was confirmed that ZnS:Ag (blue), ZnS:Cu, Au,Al (green), and Y₂O₃ (red), which were used in cathode ray tubes (CRTs), also emitted light similarly. Since the phosphor for use in CRTs has a low resistance value, surface discharge is less likely to occur. To solve this problem, it is desirable to coat the phosphor with the insulating layer 4 so as to facilitate the occurrence of surface discharge for light emission.

The light-emitting element of the present invention emits light by surface discharge that occurs in an avalanche manner due to primary electrons emitted by polarization reversal in the dielectric, followed by the generation of a large number of secondary electrons. On this account, when a system having a new function, other than polarization reversal, of allowing electrons to collide is added to the porous light-emitting layer 2, the light-emitting element is expected to emit light easily.

In the present embodiment, a colloidal silica solution is used to form the slurry of the phosphor particles 3. However, it was confirmed that the same effect also was achieved by using an organic solvent. A kneaded slurry containing 45 mass % of α-terpineol and 5 mass % of ethyl cellulose with respect to 50 mass % of the phosphor particle is used and screen-printed on a surface of the dielectric layer 10. The thus-obtained substrate is subjected to heat treatment at 400° C. to 600° C. for 10 to 60 minutes in the atmosphere, whereby the porous light-emitting layer 2 with a thickness of several μm to several tens μm can be formed. In this case, controlling temperature and heat treatment atmosphere is important since the phosphor is likely to be deteriorated when the heat treatment temperature is increased excessively. Further, the organic slurry may contain inorganic fibers 18 to achieve the same effect.

In the present embodiment, BaTiO₃ is used as the dielectric. However, it was confirmed that the same effect also was achieved by using SrTiO₃, CaTiO₃, MgTiO₃, PZT(PbZrTiO₃), PbTiO₃, or the like as the dielectric. Further, the dielectric layer may be formed of a sintered body or may be formed by sputtering, CVD, deposition or with a thin film formation process such as a sol-gel process.

In the present embodiment, the dielectric layer is formed of a sintered body. However, light emission is also possible when the dielectric layer is formed of dielectric fine particles and a binder. More specifically, it is possible to use a dielectric layer of dielectric particles and a binder that is formed as follows. A slurry of fine particles in which 15 mass % of glass powder is mixed with respect to 40 mass % of BaTiO₃ powder, the fine particles being kneaded with 40 mass % of α-terpineol and 5 mass % of ethyl cellulose, is applied to an Al metal substrate, followed by drying. Then, the thus-obtained substrate is subjected to heat treatment at 400° C. to 600° C. in the atmosphere.

In the present embodiment, the blue phosphor particle is used. However, it was found that the same effect also was achieved by using a red or green phosphor particle. Further, mixed particles of blue, red, and green also achieve the same effect. The light-emitting element of the present embodiment emits light by surface discharge. Thus, unlike a conventional light-emitting element, there is no need to use a thin film formation process for forming the phosphor layer, and neither a vacuum system nor a carrier intensifying layer is necessary. Therefore, the light-emitting element has a simple structure and is processed easily.

ITO is used for the electrode 70. However, instead of ITO, copper wiring may be provided on the transparent substrate. Copper wiring is formed in a microporous mesh shape and has an open area ratio (ratio of a portion where no wiring is provided to the entire substrate) of 90%, and accordingly this substrate allows light to pass therethrough approximately as favorably as the transparent substrate with the ITO film. Further, copper is favorable since it has a much lower resistance than ITO and greatly contributes to increased luminous efficiency. As a metal for the wiring of microporous mesh shape, gold, silver, platinum, or aluminum can be used instead of copper.

### Embodiment 13

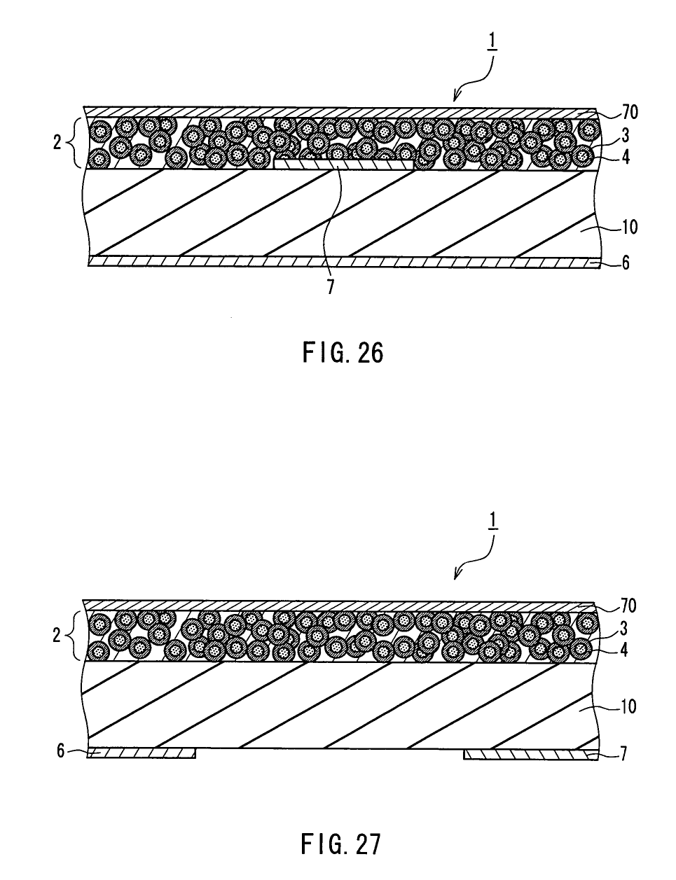

Next, a manufacturing method and a light emitting action according to Embodiment 13 will be described with reference to FIG. 26. In the present embodiment, the first electrode 6 and the second electrode 7 are formed on a bottom surface and a top surface, respectively, of the dielectric layer 10. Descriptions for the same reference numerals as in FIG. 1 may be omitted. With the use of the dielectric 10 as used in Embodiment 12, the second electrode 7 is formed in a central portion on the top surface, and the first electrode 6 is formed on the entire bottom surface by printing and baking an Ag paste as in Embodiment 12. Then, the slurry containing the phosphor particles 3 as used in Embodiment 12 is applied to a surface of the second electrode 7, and drying is carried out with a dryer at 100° C. to 150° C. for 10 to 30 minutes. As a result, the porous light-emitting layer 2 with a thickness of about 100 μm is laminated on the dielectric layer 10. After that, on a top surface of the porous light-emitting layer 2, a glass plate (not shown) to which the transparent electrode 70 (indium-tin oxide alloy (ITO), thickness: 0.1 μm) is applied is laminated as in Embodiment 12. Consequently, the light-emitting element 1 with a cross-sectional structure as shown in FIG. 26, in which a pair of the electrodes 6 and 7 are formed on both the surfaces of the dielectric layer 10, the porous light-emitting layer 2 is laminated on the top surface of the dielectric 10 via the second electrode 7, and the third electrode 70 is formed on the top surface of the porous light-emitting body, is obtained.

In order to drive the light-emitting element 1, an AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. Thereafter, an alternating electric field is applied between the third electrode 70 and at least one of a pair of the electrodes. As a result, the primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

In Embodiment 13, as described in Embodiment 12, when the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness. Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing peak voltage of the burst wave.

Once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In Embodiment 13, when a voltage of about 0.84 to 1.4 kV/mm is applied between the first electrode 6 and the second electrode 7 in a thickness direction of the dielectric layer 10, primary electrons are emitted due to polarization reversal. Thereafter, when an alternating electric field of about 0.7 to 1.2 kV/mm is applied between at least one of the first electrode 6 and the second electrode 7 and the electrode 70 in a thickness direction of the light-emitting element 1, surface discharge occurs and a large number of secondary electrons are generated, followed by light emission.

A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. It becomes possible to manufacture a light-emitting device with luminous efficiency of 2 to 5 lm/w with respect to blue light.

As shown in FIG. 26, in the light-emitting element of Embodiment 13, the second electrode 7 is formed not on the entire top surface of the dielectric layer 10 but in a certain portion on the top surface thereof. This prevents primary electrons emitted by polarization reversal from being blocked by the electrode itself and allows the primary electrons to be introduced into the porous light-emitting layer 2 efficiently. Instead of forming the electrode in a certain portion, the electrode may have any shape, such as a mesh shape, as long as electrons generated by polarization reversal are emitted to the porous light-emitting layer 2 smoothly.

In FIG. 26, there is little difference in brightness between the case where the alternating voltage is applied between the first electrode 6 and the third electrode 70 and the case where the alternating voltage is applied between the second electrode 7 an the third electrode 70.

### Embodiment 14

Next, Embodiment 14 will be described with reference to FIG. 27. In the present embodiment, a pair of the electrodes 6 and 7 are arranged on a bottom surface of the dielectric layer 10, the porous light-emitting layer 2 is laminated on a top surface thereof, and the third electrode 70 is arranged on a top surface of the porous light-emitting layer 2.

In the present embodiment, as in Embodiment 12, the phosphor particle is coated with the insulating layer 4. In other words, a uniform coating layer of MgO is formed on a surface of the phosphor particle.

A method for manufacturing the light-emitting element of the present embodiment will be described with reference to FIG. 27. 50 mass % of the phosphor particle 3 coated uniformly with the insulating layer 4 and 50 mass % of a colloidal silica solution are mixed to form a slurry. Then, the slurry is applied to a top surface of the dielectric layer 10 (i.e., a plate-shaped sintered body containing BaTiO₃ as a main component, on a bottom surface of which an Ag electrode paste is baked to a thickness of 30 μm to form the first electrode 6 and the second electrode 7) with a diameter of 15 mmΦ and a thickness of 1 mm, on which the first electrode 6 and the second electrode 7 are formed, and drying is carried out with a dryer at 100° C. to 150° C. for 10 to 30 minutes. As a result, the porous light-emitting layer 2 with a thickness of about 100 μm is laminated on the dielectric layer 10. Thereafter, on a top surface of the porous light-emitting layer 2, a glass (not shown) to which the transparent electrode (indium-tin oxide alloy (ITO), thickness: 0.1 μm) 70 is applied is laminated. Consequently, the light-emitting element 1 as shown in FIG. 27 in which a pair of the electrodes 6 and 7 are formed on the bottom surface of the dielectric layer 10, the porous light-emitting layer 2 is laminated on the top surface of the dielectric layer 10, and the third electrode 70 is formed on the top surface of the porous light-emitting layer 2 is obtained.

Next, the light emitting action of the light-emitting element 1 will be described. An AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. Thereafter, an alternating electric field is applied between the third electrode 70 and at least one of a pair of the electrodes 6 and 7. As a result, the primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

At this time, when the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness.

Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing voltage of the burst wave.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In Embodiment 14, an electric field of about 0.4 to 0.8 kV/mm is applied in a thickness direction of the dielectric layer 10 for polarization reversal. Thereafter, an alternating electric field of about 0.5 to 1.0 kV/mm is applied in a thickness direction of the light-emitting element 1 by using an AC power supply. As a result, primary electrons are emitted and surface discharge occurs, followed by light emission. When a higher electric field is applied for polarization reversal, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. It becomes possible to manufacture a light-emitting device with luminous efficiency of 2 to 5 lm/W with respect to blue light.

### Embodiment 15

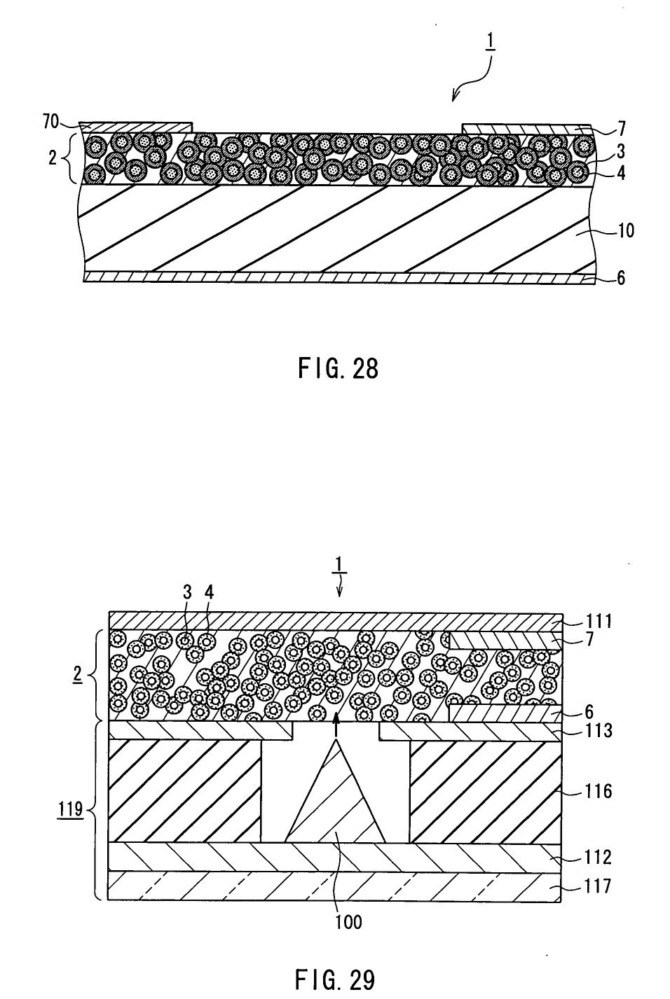

Embodiment 15 of the present invention will be described with reference to FIG. 28. In the present embodiment, the first electrode 6 is arranged on a bottom surface of the dielectric layer 10, the porous light-emitting layer 2 is laminated on a top surface of the dielectric layer 10, and the second electrode 7 and the third electrode 70 are arranged on a top surface of the porous light-emitting layer 2.

In Embodiment 15, as in Embodiment 12, the phosphor particle is coated with the insulating layer 4. In other words, a uniform coating layer of MgO is formed on a surface of a blue phosphor particle in the same manner as in Embodiment 12.

The light-emitting element of Embodiment 15 is manufactured as follows. Initially, 50 mass % of the phosphor particle 3 coated uniformly with the insulating layer 4 and 50 mass % of a colloidal silica solution are mixed to form a slurry. Then, the slurry is applied to a top surface of the dielectric layer 10 (i.e., a plate-shaped sintered body containing BaTiO₃ as a main component, on a bottom surface of which an Ag electrode paste is baked to a thickness of 30 μm to form the first electrode 6) with a diameter of 15 mmΦ and a thickness of 1 mm, on which the first electrode 6 is formed, and drying is carried out with a dryer at 100° C. to 150° C. for 10 to 30 minutes. As a result, the porous light-emitting layer 2 with a thickness of about 100 μm is laminated on the dielectric layer 10. Further, on a top surface of the porous light-emitting layer 2, an Ag electrode paste is baked to a thickness of 30 μm to form the second electrode 7 in a portion on the surface of the porous light-emitting layer 2, and then a glass plate (not shown) to which the transparent electrode (indium-tin oxide alloy (ITO), thickness: 0.1 μm) 70 is applied partially is laminated. Consequently, the light-emitting element 1 with a cross-sectional structure as shown in FIG. 28, in which the first electrode 6 of a pair of the electrodes is formed on the bottom surface of the dielectric layer 10, the porous light-emitting layer 2 is laminated on the top surface of the dielectric layer 10, and the second electrode 7 and the third electrode 70 are formed on the top surface of the porous light-emitting layer 2, is obtained.

Next, the light emitting action of the light-emitting element 1 will be described. An AC electric field is applied between the first electrode 6 and the second electrode 7. By the application of a voltage, polarization reversal is performed in the dielectric layer 10, and accordingly primary electrons (e−) 24 are emitted. At this time, ultraviolet rays and visible light are generated. Thereafter, an alternating electric field is applied between the other electrode, i.e., the electrode 70 and at least one of a pair of the electrodes. As a result, the primary electrons (e−) collide with the phosphor particles 3 and the insulating layers 4 of the porous light-emitting layer 2 to cause surface discharge, and a large number of secondary electrons (e−) 25 are generated. Electrons and ultraviolet rays generated thereby in an avalanche manner collide with the luminescence center of the phosphors, so that the phosphor particles 3 are excited to emit light. In addition, by the application of an AC electric field, polarization reversal is performed repeatedly in the dielectric layer. Accordingly, electrons are generated, and as a result of electric charge being injected into the porous light-emitting layer, surface discharge occurs. Surface discharge occurs continuously during the application of an electric field. Electrons and ultraviolet rays generated in an avalanche manner during the application of an electric field collide with the luminescence center of the phosphors, so that the phosphor particles 3 are excited to emit light.

At this time, when the alternating electric field to be applied has its waveform changed from a sine wave or a sawtooth wave to a rectangular wave or has its frequency increased by several tens to thousands of Hz, electrons are emitted by polarization reversal and surface discharge occurs more vigorously, resulting in increased emission brightness.

Further, as a voltage value of the alternating electric field is increased, a burst wave is generated. A burst wave, which is generated when polarization reversal is performed in the dielectric layer 10, is generated at a frequency immediately before the peak of the frequency in the case of a sine wave, and is generated at the peak of the frequency in the case of a sawtooth wave or a rectangular wave, and the emission brightness increases with increasing voltage of the burst wave. As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In the present embodiment, an electric field of about 0.5 to 1.0 kV/mm is applied in a thickness direction of the dielectric layer 10 for polarization reversal. Thereafter, an alternating electric field of about 0.5 to 1.0 kV/mm is applied in a thickness direction of the light-emitting element 1 by using an AC power supply. As a result, primary electrons are emitted, surface discharge occurs, and a large number of secondary electrons are generated, followed by light emission. When a higher electric field is applied for polarization reversal, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. It becomes possible to manufacture a light-emitting device with luminous efficiency of 2 to 5 lm/W with respect to blue light.

### Embodiment 16

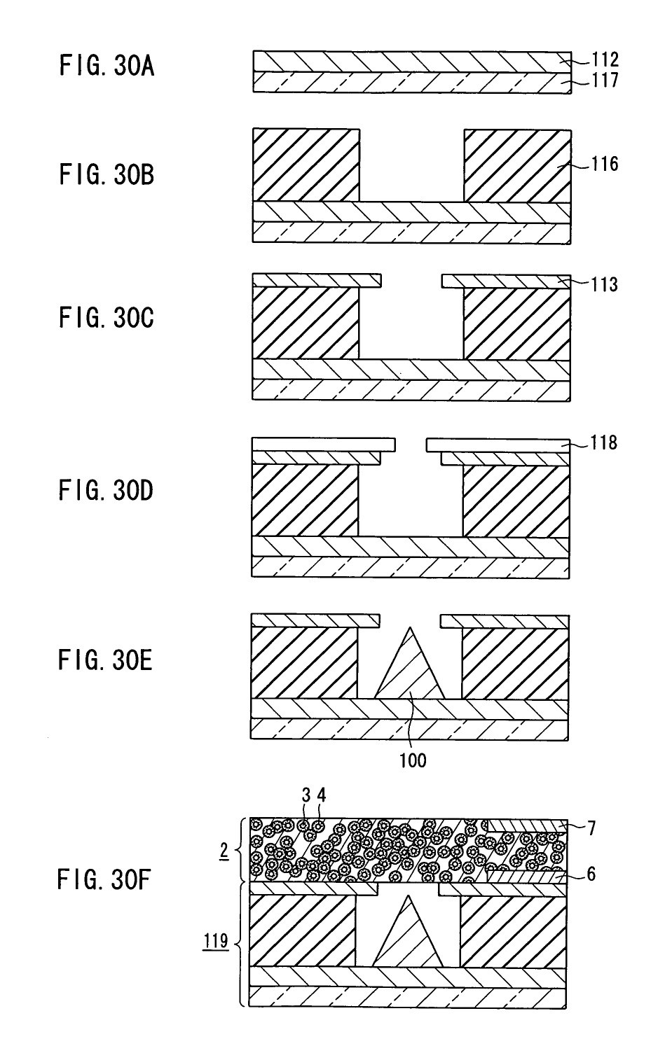

A light-emitting element including an electron-emitting body, a porous light-emitting body, and a pair of electrodes according to the present embodiment will be described with reference to FIGS. 29 and 30. In the light-emitting element of the present embodiment, the porous light-emitting body includes inorganic phosphor particles and is arranged adjacent to the electron-emitting body so as to be irradiated with electrons generated from the electron-emitting body, and a pair of the electrodes are arranged so that an electric field is applied to at least a part of the porous light-emitting body. In particular, the electron-emitting body includes a cathode electrode, a gate electrode, and a Spindt-type emitter interposed between the two electrodes, and electrons emitted from the Spindt-type emitter by the application of a gate voltage between the cathode electrode and the gate electrode are irradiated to the porous light-emitting body, whereby the porous light-emitting body is allowed to emit light.

FIG. 29 is a cross-sectional view of the light-emitting element of the present embodiment. Reference numeral 1 denotes a light-emitting element with an overall thickness of about 2 mm, 2 denotes a porous light-emitting layer with a thickness of about 30 μm, 3 denotes a phosphor particle with an average particle diameter of 2 μm, 4 denotes an insulating layer with a thickness of 0.5 μm provided on a surface of the phosphor particle, 100 denotes a triangular pyramid Spindt-type emitter with a bottom surface of 1 μm and a height of 1 μm, 6 denotes a first electrode with a thickness of 200 nm, 7 denotes a second electrode with a thickness of 200 nm, 111 denotes an anode electrode with a thickness of 150 nm, 112 denotes a cathode electrode with a thickness of 150 nm, 113 denotes a gate electrode with a thickness of 200 nm, 116 denotes an insulating layer with a thickness of 1 μm, 117 denotes a substrate with a thickness of 1.1 mm, and 119 denotes an electron-emitting body with a thickness of 1.1 mm.

First, a method for manufacturing the light-emitting element of the present embodiment will be described with reference to the figures. FIGS. 30A to 30F are views for explaining the manufacturing method of the light-emitting element shown in FIG. 29. As shown in FIG. 30A, Au is deposited on a surface of the substrate 117 made of glass to form the cathode electrode 112. For the cathode electrode 112, Ag, Al, or Ni may be deposited instead of Au. Further, the substrate 117 may be made of ceramic instead of glass.

Then, as shown in FIG. 30B, in order to form the insulating layer 116, a glass paste is printed on the cathode electrode 112 by a screen printing method, followed by drying and firing at 580° C. Instead of screen printing of a glass paste, the insulating layer 116 may be formed by using a so-called photolithography technique. That is, the cathode electrode is coated with SiO₂ by sputtering, the thus-obtained substrate is exposed to UV light using a photoresist and a photomask to be developed, and etching is performed, whereby the insulating layer 116 is formed selectively.

Then, as shown in FIG. 30C, Al is sputtered to form a film, and the gate electrode 113 of Al is formed on the insulating layer 116 by using a photolithography technique. As a metal for the gate electrode, Ni may be used instead of Al.

Thereafter, as shown in FIG. 30E, the Spindt-type emitter is formed in a recess between the gate electrode 113 by a two-step deposition method. Specifically, the substrate shown in FIG. 30C is placed in a deposition device while being tilted at an angle of about 20°, and Al₂O₃ as a sacrificial material is deposited while the substrate is rotated. As a result, as shown in FIG. 30D, Al₂O₃ is deposited so as to coat the gate electrode 113 and forms an Al₂O₃ layer 118 with a thickness of 200 nm, with no Al₂O₃ deposited on the cathode electrode 112. Then, Mo is deposited vertically as the emitter so as to get into the recess between the gate electrode 113 in a self-aligned manner, resulting in the triangular pyramid Spindt-type emitter of Mo. After that, the sacrificial layer and Mo on the gate electrode 113 are lifted off. Further, the emitter of Mo, which is subjected to oxidation during deposition, is fired at 550° C., whereby as shown in FIG. 30E, the glass substrate on which the Spindt-type emitter 100 of Mo is formed in the recess between the gate electrode 113 is obtained finally. As a material of the emitter, a metal such as Nb, Zr, Ni, and molybdenum steel may be used instead of Mo, and the emitter of these materials can be manufactured based on the above-mentioned method used for the emitter of Mo.

In the present embodiment, the porous light-emitting body 2 is formed of the phosphor particles 3 or a material containing the phosphor particles 3 as a main component, and the phosphor particle 3 coated with the insulating layer 4 is used.

In order to achieve desired light emission, three inorganic compounds of BaMgAl₁₀O₁₇:Eu²⁺ (blue), Zn₂SiO₄:Mn²⁺ (green), and YBO₃:Eu³⁺ (red), each having an average particle diameter of 2 to 3 μm, for example, can be used as the phosphor particle 3 singly or in a mixture.

In the present embodiment, the blue phosphor particle 3 is used, and the insulating layer 4 of an insulative inorganic substance of MgO is formed on its surface. Specifically, the phosphor particles 3 are added to an Mg precursor complex solution, stirred for a long time, and taken out from the solution, followed by drying. After that, the phosphor particle is subjected to heat treatment at 400° C. to 600° C. in the atmosphere, whereby a uniform coating layer of MgO, i.e., the insulating layer 4, is formed on the surface of the phosphor particle 3. 50 mass % of the phosphor particle 3 coated with the insulating layer 4 and 50 mass % of a colloidal silica solution are mixed to form a slurry.

Then, a ceramic board formed of inorganic fiber (an Al₂O₃—CaO—SiO₂ based ceramic fiber board with a thickness of about 1 mm and a void ratio of about 45%) is immersed in the slurry, followed by drying at 100° C. to 150° C. for 10 to 30 minutes. As a result, the ceramic board supports phosphor particle powder. Thereafter, on both sides of the ceramic board, an Ag electrode paste is baked to a thickness of 30 μm to form the first electrode 6 and the second electrode 7. As shown in FIG. 30F, the ceramic fiber board thus obtained is attached to the electron-emitting body 119 by using colloidal silica, water glass, or an epoxy resin. Then, on a top surface of the porous light-emitting body 2, a glass (not shown) to which the transparent anode electrode (indium-tin oxide alloy (ITO), thickness: 15 μm) 111 is applied is laminated. Consequently, the light-emitting element 1 as shown in FIG. 29 in which the porous light-emitting body 2 is formed on the electron-emitting body 119 and the electrodes are arranged at predetermined positions is obtained. Regarding the electrodes of the light-emitting element 1, the first electrode 6 and the second electrode 7 are inserted as auxiliary electrodes since the transparent electrode of ITO used as the anode electrode 111 has a high resistance value. Thus, it is possible to form the anode electrode 11 and the second electrode 7 as one electrode or the gate electrode 113 and the first electrode 6 as one electrode.

In order to prevent electrons emitted from the emitter from greatly leaving orbit, an Ag paste may be screen-printed on the gate electrode so as to form a focusing electrode.

Next, the light emitting action of the light-emitting element 1 of the present embodiment will be described.

In order to drive the light-emitting element 1, initially, a direct electric field of 800 V and 80 V is applied between the anode electrode 111 and the cathode electrode 112 and between the gate electrode 113 and the cathode electrode 112, respectively, in FIG. 29, so that primary electrons are emitted from the Spindt-type emitter 100 in the direction of an arrow in the figure. When a higher electric field is applied, the generation of electrons is accelerated, and when an excessively low electric field is applied, the emission of electrons is insufficient.

With primary electrons emitted as described above, an alternating electric field is applied between the first electrode 6 and the second electrode 7. Primary electrons emitted due to electric charge transfer are doubled in an avalanche manner, and cause surface discharge in the porous light-emitting body 2. Surface discharge occurs continuously in a chain reaction, so that electric charge transfer is carried out in the vicinity of the phosphor particles. Electrons accelerated further collide with the luminescence center, so that the porous light-emitting body 2 is excited to emit light. At this time, ultraviolet rays and visible light also are generated, and the porous light-emitting body 2 also is excited to emit light by the ultraviolet rays.

When the alternating electric field to be applied has its waveform changed from a sine wave or a sawtooth wave to a rectangular wave and has its frequency increased by several tens to thousands of Hz, electrons are emitted and surface discharge occurs more vigorously, resulting in increased emission brightness.

Once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

Specifically, when an alternating electric field of about 0.5 to 1.0 kV/mm is applied in a thickness direction of the porous light-emitting body 2 by using an AC power supply, electric charge transfer is carried out and surface discharge occurs, followed by light emission. When a higher electric field is applied, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially, and that a high brightness, a high contrast, a high recognition capability, and a high reliability were ensured in light emission. Consequently, it is possible to manufacture a light-emitting device with luminous efficiency of 2.0 lm/W, a brightness of 200 cd/m², and a contrast of 500:1 with respect to blue light.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

The light-emitting element 1 of the present embodiment has a structure similar to that of an inorganic EL display (ELD), but has a completely different configuration and mechanism. Regarding the configuration, a phosphor used in an inorganic EL display is a light-emitting body formed of a semiconductor such as ZnS:Mn²⁺ and GaP:N as described in the background art section. On the other hand, the phosphor particle in the embodiment may be either an insulator or a semiconductor, although an insulative phosphor particle is preferable. More specifically, even when the phosphor particle is formed of a semiconductor with an extremely low resistance value, surface discharge occurs continuously without the occurrence of short circuit since the phosphor particle is coated uniformly with the insulating layer of an insulative inorganic substance as described above, and the phosphor particle is allowed to emit light. In an inorganic EL display, a phosphor layer has a thickness of submicron to several μm. On the other hand, the phosphor layer in the present embodiment has a porous structure with a thickness of several μm to several hundreds μm. Further, in the present embodiment, the light-emitting body has a porous structure.

Regarding the porous structure, as a result of observation with an SEM (scanning electron microscope), the phosphor particles are packed so as to be in point contact with each other.

As the phosphor particle, powder that emits ultraviolet rays, which is used in current plasma display panels (PDPs), is used. However, it was confirmed that ZnS:Ag (blue), ZnS:Cu, Au,Al (green), and Y₂O₃ (red), which were used in cathode ray tubes (CRTs), also emitted light similarly.

The light-emitting element of the present invention emits light by surface discharge that occurs in an avalanche manner due to electrons emitted from the electron-emitting body 119. When a new electron-emitting body that irradiates electrons is combined with the porous light-emitting body 2 of the present invention, the light-emitting element is expected to emit light easily.

In the present embodiment, a colloidal silica solution is used to form the slurry of the phosphor particles 3. However, it was confirmed that the same effect also was achieved by using an organic solvent. It is possible that a kneaded slurry containing 45 mass % of α-terpineol and 5 mass % of ethyl cellulose with respect to 50 mass % of the phosphor particle is formed, and the above-mentioned ceramic fiber board is immersed in the slurry, followed by heat treatment for degreasing.

In the present embodiment, the blue phosphor particle is used. However, it was found that the same result also was obtained by using a red or green phosphor particle. Further, mixed particles of blue, red, and green also provide the same result. Further, in the present embodiment, although an alternating electric field is applied between the first electrode 6 and the second electrode 7, a direct electric field may be applied.

The light-emitting element of the present embodiment emits light by surface discharge. Thus, unlike a conventional light-emitting element, there is almost no need to use a thin film formation process for forming the phosphor layer, and neither a vacuum system nor a carrier intensifying layer is necessary. Therefore, the light-emitting element has a simple structure and is processed easily.

### Embodiment 17

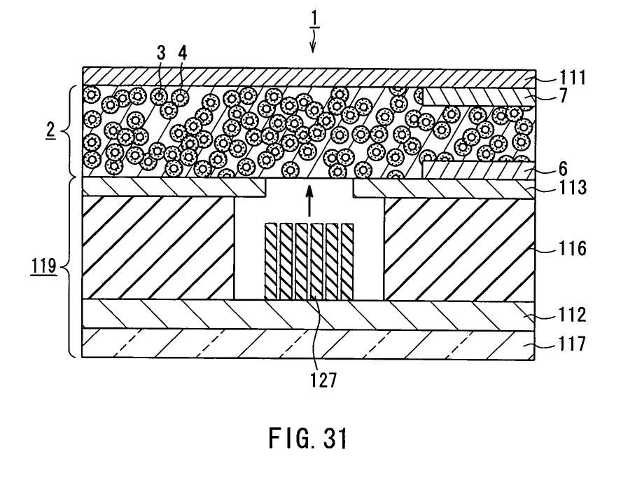

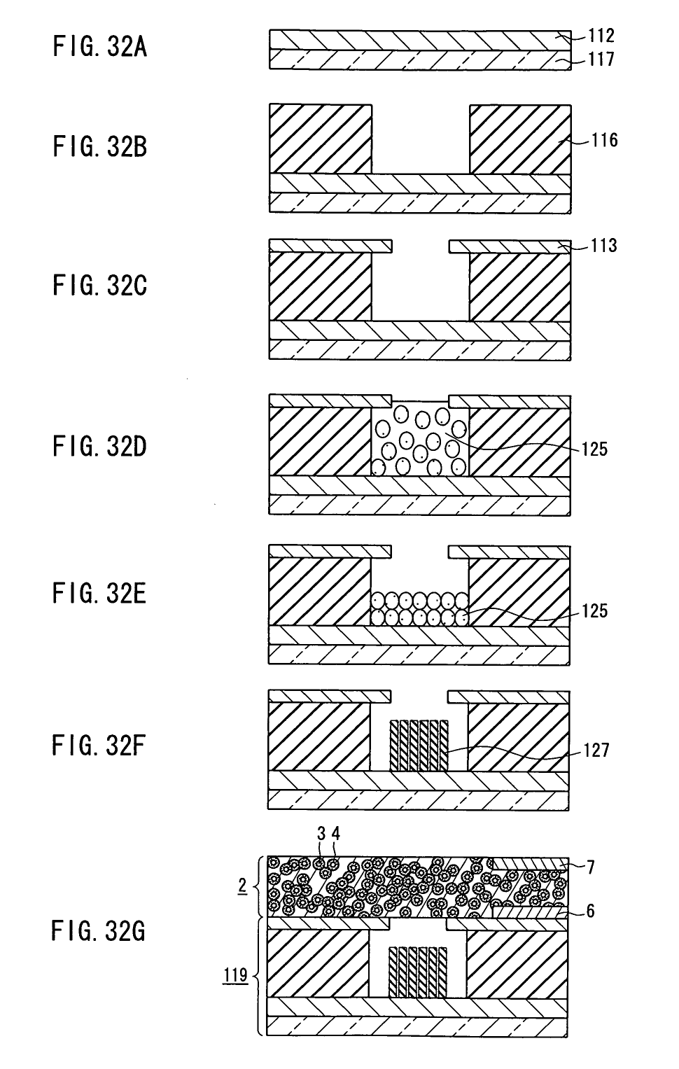

A light-emitting element including an electron-emitting body, a porous light-emitting body, and a pair of electrodes according to the present embodiment will be described with reference to FIGS. 31 and 32A to 32G. In the light-emitting element of the present embodiment, the porous light-emitting body includes inorganic phosphor particles and is arranged adjacent to the electron-emitting body so as to be irradiated with electrons generated from the electron-emitting body, and a pair of the electrodes are arranged so that an electric field is applied to at least a part of the porous light-emitting body. In particular, the electron-emitting body includes a cathode electrode, a gate electrode, and a carbon nanotube interposed between the two electrodes, and electrons emitted from the carbon nanotube by the application of a gate voltage between the cathode electrode and the gate electrode are irradiated to the porous light-emitting body, whereby the porous light-emitting body is allowed to emit light.

FIG. 31 is a cross-sectional view of the light-emitting element of the present embodiment. Reference numeral 1 denotes a light-emitting element, 2 denotes a porous light-emitting body, 3 denotes a phosphor particle, 4 denotes an insulating layer, 6 denotes a first electrode, 7 denotes a second electrode, 111 denotes an anode electrode, 112 denotes a cathode electrode, 113 denotes a gate electrode, 116 denotes an insulating layer, 117 denotes a substrate, and 127 denotes a carbon nanotube.

First, a method for manufacturing the light-emitting element of the present embodiment will be described with reference to the figures. FIGS. 32A to 32G are views for explaining the manufacturing method of the light-emitting element shown in FIG. 31. As shown in FIG. 32A, Au is deposited on a surface of the substrate 117 made of glass to form the cathode electrode 112 in the same manner as in Embodiment 16. The substrate in the present embodiment may be made of ceramic instead of glass. Then, as shown in FIG. 32B, the insulating layer 116 is formed on the cathode electrode 112, and as shown in FIG. 32C, the gate electrode 113 made of Al is formed on the insulating layer 116 in the same manner as in Embodiment 16.

Then, as shown in FIG. 32D, a kneaded paste containing 45 mass % of x-terpineol and 5 mass % of ethyl cellulose with respect to 50 mass % of carbon nanotube is dropped into a recess between the gate electrode 113 by screen printing, followed by drying. After that, the thus-obtained substrate is subjected to heat treatment at 400° C. in an N₂ atmosphere, whereby the carbon nanotube is deposited in the recess as shown in FIG. 32E. Thereafter, the carbon nanotube is subjected to orientation by adhering an adhesive film to a surface of the carbon nanotube and then peeling it off, whereby the vertically oriented carbon nanotube as shown in FIG. 32F, which is favorable as an electron-emitting body, is formed.

It is also possible that the substrate on which the gate electrode is formed is coated with a photosensitive carbon nanotube paste and is exposed to light using a photomask to be developed, whereby the carbon nanotube is patterned. Further, as a process for vertically orienting the carbon nanotube, a laser irradiation method may be used. Specifically, the paste containing carbon nanotube is used to form a carbon nanotube film, and then the film is irradiated with a laser, so that an organic resin contained in the carbon nanotube film is burned out, whereby the carbon nanotube can be exposed and raised on a surface of the film.

Then, as in Embodiment 16, a ceramic board formed of inorganic fiber (an Al₂O₃—CaO—SiO₂ based ceramic fiber board with a thickness of about 1 mm and a void ratio of about 45%) supports phosphor particle powder. On both sides of the ceramic board, an Ag electrode paste is baked to a thickness of 30 μm to form the first electrode 6 and the second electrode 7. As shown in FIG. 32G, the ceramic fiber board thus obtained is attached to the electron-emitting body 119 by using colloidal silica, water glass, or an epoxy resin. Then, on a top surface of the porous light-emitting body 2, a glass (not shown) to which the transparent anode electrode (indium-tin oxide alloy (ITO), thickness: 15 μm) 111 is applied is laminated. Consequently, the light-emitting element 1 of the present embodiment as shown in FIG. 31 in which the porous light-emitting body 2 is formed on the electron-emitting body 119 and the electrodes are arranged at predetermined positions is obtained.

Next, the light emitting action of the light-emitting element 1 will be described. In order to drive the light-emitting element 1, initially, a direct electric field of 750 V and 80 V is applied between the anode electrode 111 and the cathode electrode 112 and between the gate electrode 113 and the cathode electrode 112, respectively, in FIG. 31, so that electrons are emitted from the carbon nanotube in the direction of an arrow in the figure.

With electrons emitted as described above, an alternating electric field is applied between the first electrode 6 and the second electrode 7. Electrons emitted due to electric charge transfer are doubled in an avalanche manner, and cause surface discharge in the porous light-emitting body 2. Surface discharge occurs continuously in a chain reaction, so that electric charge transfer is carried out in the vicinity of the phosphor particles. Electrons accelerated further collide with the luminescence center, so that the porous light-emitting body 2 is excited to emit light. At this time, ultraviolet rays and visible light also are generated, and the porous light-emitting body 2 also is excited to emit light by the ultraviolet rays.

When the alternating electric field to be applied has its waveform changed from a sine wave or a sawtooth wave to a rectangular wave and has its frequency increased by several tens to thousands of Hz, electrons are emitted and surface discharge occurs more vigorously, resulting in increased emission brightness.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

Specifically, when an alternating electric field of about 0.5 to 1.0 kV/mm is applied in a thickness direction of the porous light-emitting body 2 by using an AC power supply, electric charge transfer is carried out and surface discharge occurs, followed by light emission. When a higher electric field is applied, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

In the present embodiment, the blue phosphor particle is used. However, it was found that the same result also was obtained by using a red or green phosphor particle. Further, mixed particles of blue, red, and green also provide the same result.

The light-emitting element of the present embodiment emits light by surface discharge. Thus, unlike a conventional light-emitting element, there is almost no need to use a thin film formation process for forming the phosphor layer, and neither a vacuum system nor a carrier intensifying layer is necessary. Therefore, the light-emitting element has a simple structure and is processed easily.

### Embodiment 18

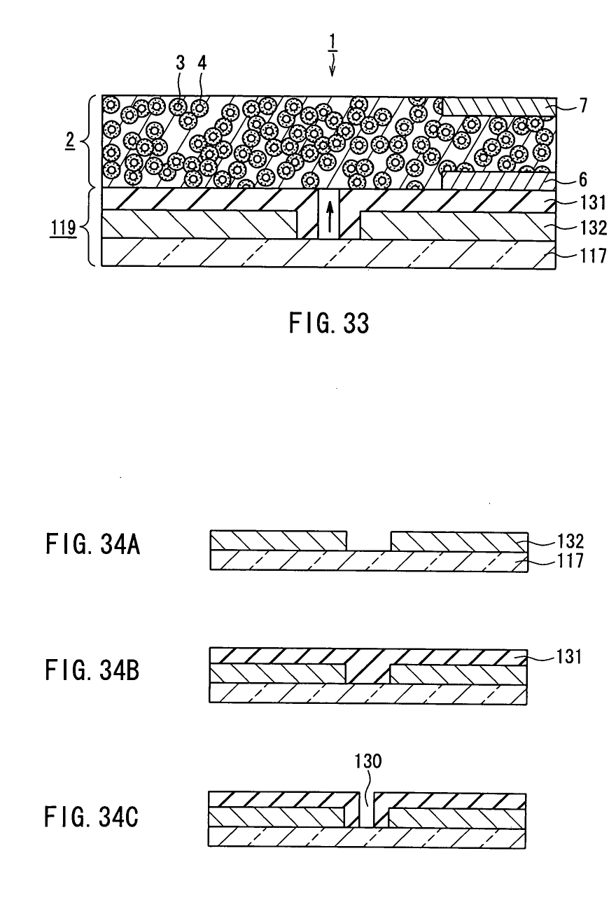

A light-emitting element including an electron-emitting body, a porous light-emitting body, and a pair of electrodes according to the present embodiment will be described with reference to FIGS. 33 and 34A to 34C. In the light-emitting element of the present embodiment, the porous light-emitting body includes inorganic phosphor particles and is arranged adjacent to the electron-emitting body so as to be irradiated with electrons generated from the electron-emitting body, and a pair of the electrodes are arranged so that an electric field is applied to at least a part of the porous light-emitting body. In particular, the electron-emitting body is a surface-conduction-type electron-emitting element, a minute gap is provided in a metal oxide film, and electrons generated from the gap by an electric field applied to the gap by the application of a voltage to an electrode provided on the metal oxide film beforehand are irradiated to the porous light-emitting body.

FIG. 33 is a cross-sectional view of the light-emitting element of the present embodiment. Reference numeral 1 denotes a light-emitting element, 2 denotes a porous light-emitting body, 3 denotes a phosphor particle, 4 denotes an insulating layer, 6 denotes a first electrode, 7 denotes a second electrode, 117 denotes a substrate, 130 denotes a gap, 131 denotes a PdO ultrafine particle film, and 132 denotes a Pt electrode.

First, a method for manufacturing the light-emitting element of the present embodiment will be described with reference to the figures. FIGS. 34A to 34C are views for explaining the manufacturing method of the light-emitting element of the present embodiment shown in FIG. 33. As shown in FIG. 34A, a Pt paste is subjected to patterning by screen printing on a surface of the ceramic substrate 117 so as to form the Pt electrode 132 with a small gap provided therebetween. Then, as shown in FIG. 34B, PdO ink coats the Pt electrode 132 so as to bridge between the Pt electrode 132 by ink-jet printing, followed by firing. As a result, the PdO ultrafine particle film 131 is formed on the Pt electrode 132. Subsequently, the thus-obtained substrate is subjected to an electrical treatment, so that as shown in FIG. 34C, the PdO ultrafine particle film 31 is cracked to form the minute gap 130 of about 10 nm. As described above, the electron-emitting body of the present embodiment is formed without using a photolithography process and with a relatively smaller number of processes, and thus it is very excellent in economical efficiency and in view of achieving a large-screen display.

Then, as in Embodiment 16, a ceramic board formed of inorganic fiber (an Al₂O₃—CaO—SiO₂ based ceramic fiber board with a thickness of about 1 mm and a void ratio of about 45%) supports phosphor particle powder. On both sides of the ceramic board, an Ag electrode paste is baked to a thickness of 30 μm to form the first electrode 6 and the second electrode 7, respectively. As shown in FIG. 33, the ceramic fiber board thus obtained is attached to the electron-emitting body 119 by using colloidal silica, water glass, or an epoxy resin.

Consequently, the light-emitting element 1 of the present embodiment as shown in FIG. 313 in which the porous light-emitting body 2 is provided on the electron-emitting body 119 and the electrodes are arranged at predetermined positions is obtained.

Next, the light emitting action of the light-emitting element 1 will be described. In order to drive the light-emitting element 1, initially, a DC voltage of 12 to 16 V is applied between the two Pt electrodes 132 shown in FIG. 33, so that electrons are emitted from one of the electrodes via the slit of 10 nm by a tunnel effect in the direction of an arrow in the figure and are irradiated to the porous light-emitting body 2.

With electrons emitted as described above, an alternating electric field is applied between the first electrode 6 and the second electrode 7. Electrons emitted due to electric charge transfer are doubled in an avalanche manner, and cause surface discharge in the porous light-emitting body 2. Surface discharge occurs continuously in a chain reaction, so that electric charge transfer is carried out in the vicinity of the phosphor particles. Electrons accelerated further collide with the luminescence center, so that the porous light-emitting body 2 is excited to emit light. At this time, ultraviolet rays and visible light also are generated, and the porous light-emitting body 2 also is excited to emit light by the ultraviolet rays.

When the alternating electric field to be applied has its waveform changed from a sine wave or a sawtooth wave to a rectangular wave and has its frequency increased by several tens to thousands of Hz, electrons are emitted and surface discharge occurs more vigorously, resulting in increased emission brightness.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

Specifically, when an alternating electric field of about 0.5 to 1.0 kV/mm is applied in a thickness direction of the porous light-emitting body 2 by using an AC power supply, electric charge transfer is carried out and surface discharge occurs, followed by light emission. When a higher electric field is applied, the generation of electrons is accelerated, and when an excessively low electric field is applied, the emission of electrons is insufficient.

A current value during discharge is 0.1 mA or less. It was confirmed that light emission once started was sustained even when the voltage was decreased to 50% to 80% of the voltage applied initially.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

As the phosphor particle, powder that emits ultraviolet rays, which is used in current plasma display panels (PDPs), is used. However, it was confirmed that ZnS:Ag (blue), ZnS:Cu, Au,Al (green), and Y₂O₃ (red), which were used in cathode ray tubes (CRTs), also emitted light similarly.

The light-emitting element of the present invention emits light by surface discharge that occurs in an avalanche manner due to electrons emitted from the electron-emitting body 119. When a device having a new function of irradiating electrons is added to the porous light-emitting body 2, the light-emitting element is expected to emit light easily.

In the present embodiment, the blue phosphor particle is used. However, it was found that the same result also was obtained by using a red or green phosphor particle. Further, mixed particles of blue, red, and green also provide the same result.

The light-emitting element of the present embodiment emits light by surface discharge. Thus, unlike a conventional light-emitting element, there is almost no need to use a thin film formation process for forming the phosphor layer, and neither a vacuum system nor a carrier intensifying layer is necessary. Therefore, the light-emitting element has a simple structure and is processed easily.

Instead of using the electron-emitting body as described in the present embodiment, it is also possible to use a similar electron-emitting body in which an insulating layer is sandwiched between two electrodes and electrons are emitted by the application of an electric field between the electrodes. Specifically, an upper electrode is formed of an Ir—Pt—Au alloy, a cathode electrode is formed of Al, and the insulating layer is formed of Al₂O₃. The insulating layer is sandwiched between the two electrodes, and electrons are emitted from the upper electrode when an electric field is applied between the electrodes. Such an electron-emitting body can be used to manufacture the light-emitting element to irradiate the porous light-emitting body with electrons.

### Embodiment 19

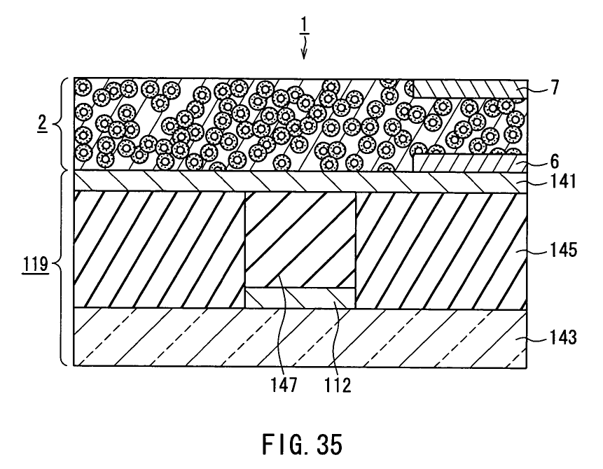

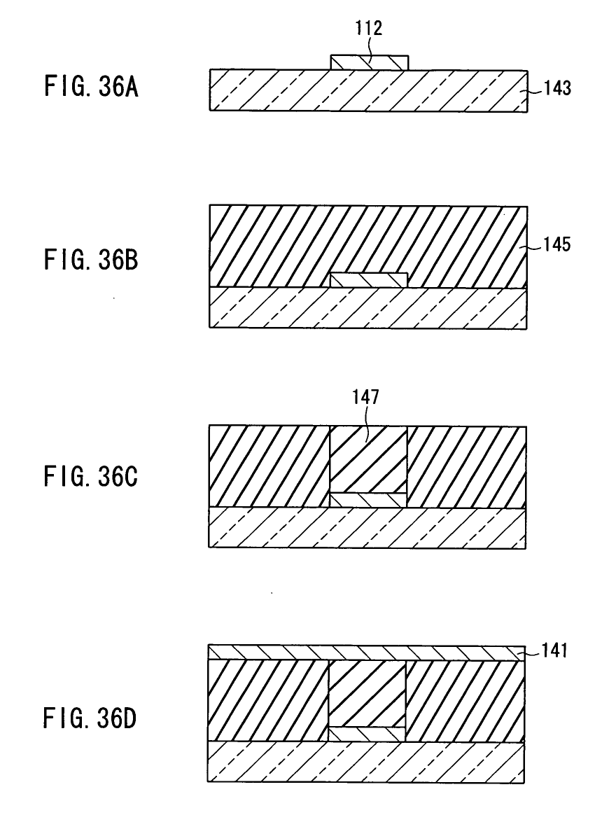

A light-emitting element including an electron-emitting body, a porous light-emitting body, and a pair of electrodes according to the present embodiment will be described with reference to FIGS. 35 and 36A to 36D. In the light-emitting element of the present embodiment, the porous light-emitting body includes inorganic phosphor particles and is arranged adjacent to the electron-emitting body so as to be irradiated with electrons generated from the electron-emitting body, and a pair of the electrodes are arranged so that an electric field is applied to at least a part of the porous light-emitting body. In particular, the electron-emitting body includes a polysilicon thin film, a silicon microcrystal, and an oxide film formed on a surface of the silicon microcrystal, and electrons emitted by the application of a voltage to the electron-emitting body are irradiated to the porous light-emitting body, whereby the porous light-emitting body is allowed to emit light.

FIG. 35 is a cross-sectional view of the light-emitting element of the present embodiment. Reference numeral 1 denotes a light-emitting element, 2 denotes a porous light-emitting body, 3 denotes a phosphor particle, 4 denotes an insulating layer, 6 denotes a first electrode, 7 denotes a second electrode, 112 denotes a cathode electrode, 119 denotes an electron-emitting body, 141 denotes a metal thin film electrode, 145 denotes polysilicon, and 147 denotes a silicon microcrystal. FIGS. 36A to 36D are views for explaining the manufacturing method of the light-emitting element shown in FIG. 35. As shown in FIG. 36A, Au is deposited on a surface of a substrate 143 made of glass to form the cathode electrode 112 by patterning using a photolithography technique. Subsequently, as shown in FIG. 36B, columnar polysilicon is formed by a plasma CVD method.

Then, as shown in FIG. 36C, the polysilicon 145 formed on the cathode electrode 112 is made porous to form the nanosilicon microcrystal 147. Specifically, the substrate is immersed in a mixed solution of hydrofluoric acid and ethyl alcohol, and a voltage is applied between the substrate as a positive electrode and, as a counter electrode, Pt as a negative electrode, whereby the silicon microcrystal is formed on the cathode electrode 112.

After that, the substrate 143 is washed and then is immersed in a sulphuric acid solution. A voltage is applied between the substrate as a positive electrode and Pt as a negative electrode as above, so that surfaces of both the polysilicon 145 and the silicon microcrystal are oxidized. Finally, as shown in FIG. 36D, the metal thin film electrode 141 formed of an Au alloy, an Ag alloy, or the like is provided by sputtering, followed by photoetching for patterning. As a result the electron-emitting body 119 is obtained. The manufacturing method of the electron-emitting body of the present embodiment requires a relatively small number of processes and can include a wet process, and therefore is excellent in economical efficiency.

Then, as in Embodiment 11, a ceramic board formed of inorganic fiber (an Al₂O₃—CaO—SiO₂ based ceramic fiber board with a thickness of about 1 mm and a void ratio of about 45%) supports phosphor particle powder. On both sides of the ceramic board, an Ag electrode paste is baked to a thickness of 30 μm to form the first electrode 6 and the second electrode 7, respectively. As shown in FIG. 35, the ceramic fiber board thus obtained is attached to the electron-emitting body 119 by using colloidal silica, water glass, or an epoxy resin.

The above-mentioned processes yield the light-emitting element 1 of the present embodiment as shown in FIG. 35 in which the porous light-emitting body 2 is provided on the electron-emitting body 119 and the electrodes are arranged at predetermined positions.

Next, the light emitting action of the light-emitting element 1 will be described. In order to drive the light-emitting element 1, initially, a direct electric field of 15 to 20 V is applied between the metal thin film electrode 141 and the cathode electrode 112 shown in FIG. 35, so that electrons from the cathode electrode tunnel through the silicon microcrystal, are accelerated by the oxide film on its surface, and are emitted into the porous light-emitting body.

With electrons emitted as described above, an alternating electric field is applied between the first electrode 6 and the second electrode 7. Electrons emitted due to electric charge transfer are doubled in an avalanche manner, and cause surface discharge in the porous light-emitting body 2. Surface discharge occurs continuously in a chain reaction, so that electric charge transfer is carried out in the vicinity of the phosphor particles. Electrons accelerated further collide with the luminescence center, so that the porous light-emitting body 2 is excited to emit light. At this time, ultraviolet rays and visible light also are generated, and the porous light-emitting body 2 also is excited to emit light by the ultraviolet rays.

When the alternating electric field to be applied has its waveform changed from a sine wave or a sawtooth wave to a rectangular wave and has its frequency increased by several tens to thousands of Hz, electrons are emitted and surface discharge occurs more vigorously, resulting in increased emission brightness.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

In the present embodiment, when an alternating electric field of about 0.5 to 1.0 kV/mm is applied in a thickness direction of the porous light-emitting body 2 by using an AC power supply, electric charge transfer is carried out and surface discharge occurs, followed by light emission. When a higher electric field is applied, the generation of electrons is accelerated, and when an excessively low electric field is applied, the generation of electrons is insufficient.

A current value during discharge is 0.1 mA or less. It was confirmed that light emission once started was sustained even when the voltage was decreased to 50% to 80% of the voltage applied initially.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

In the present embodiment, the blue phosphor particle is used. However, it was found that the same result also was obtained by using a red or green phosphor particle. Further, mixed particles of blue, red, and green also provide the same result.

The light-emitting element of the present embodiment emits light by surface discharge. Thus, unlike a conventional light-emitting element, there is almost no need to use a thin film formation process for forming the phosphor layer, and neither a vacuum system nor a carrier intensifying layer is necessary. Therefore, the light-emitting element has a simple structure and is processed easily.

### Embodiment 20

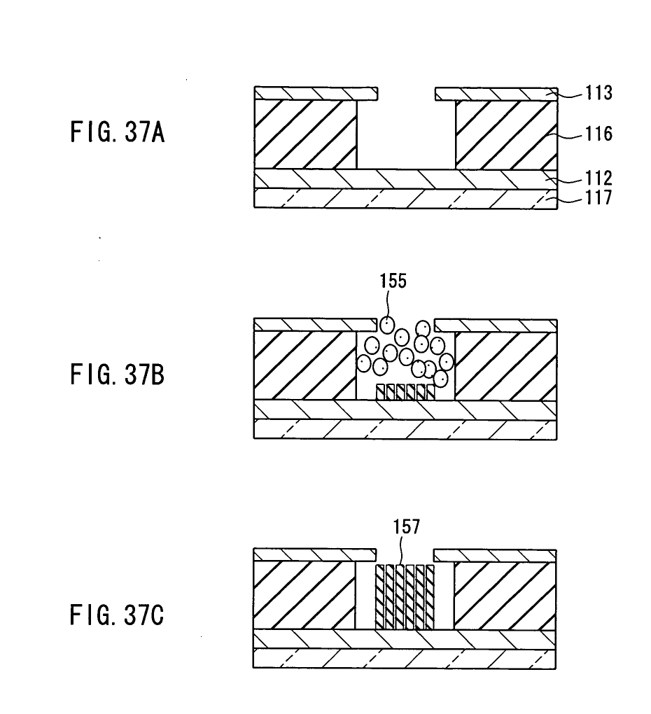

An electron-emitting body constituting a part of a light-emitting element of the present embodiment will be described with reference to FIGS. 37A to 37C. The electron-emitting body of the present embodiment is formed of a whisker emitter instead of the carbon nanotube as mentioned above.

FIGS. 37A to 37C are views for explaining the manufacturing method of the electron-emitting body of the present embodiment. Reference numeral 112 denotes a cathode electrode, 113 denotes a gate electrode, 116 denotes an insulating layer, 117 denotes a substrate, 155 denotes an organic metal complex gas, and 157 denotes a whisker emitter. As shown in FIG. 37A, Au is deposited on a surface of the substrate 117 formed of glass to form the cathode electrode 112, the insulating layer 116 is formed thereon, and the gate electrode 113 is formed on the insulating layer 116 in the same manner as in Embodiment 19. Then, as shown in FIG. 37B, the whisker emitter is formed by a CVD method. Specifically, a large amount of Al:Zn organic metal complex gas 155 is showered toward the cathode electrode. At this time, when a certain amount or more of gas is showered, a thermally-oxidized Al:ZnO film grows in a vertical direction. Further, as the source gas is increased, a front end of the film becomes sharp to a level of several nm. In this manner, the Al:ZnO whisker is patterned and oriented vertically in a self-aligned manner. The film is formed by paying attention to a source gas input, a film forming temperature, and a film formation time. As a result, the electron-emitting body having the Al:ZnO whisker emitter 157 as shown in FIG. 37C is obtained.

Then, as in Embodiment 11, the porous light-emitting body is manufactured by allowing a ceramic board formed of inorganic fiber (an Al₂O₃—CaO—SiO₂ based ceramic fiber board with a thickness of about 1 mm and a void ratio of about 45%) to support phosphor particle powder. Predetermined electrodes are arranged on the porous light-emitting body, and the thus-obtained porous light-emitting body is laminated on the above-mentioned electron-emitting body, whereby the light-emitting element (not shown) is obtained.

Next, the light emitting action of the light-emitting element 1 will be described. In order to drive the light-emitting element, initially, a direct electric field of 850 V and 80 V is applied between an anode electrode and the cathode electrode and between the gate electrode and the cathode electrode, respectively, so that electrons are emitted from the whisker emitter.

With electrons emitted as described above, an alternating electric field is applied between a first electrode and a second electrode. Electrons emitted due to electric charge transfer are doubled in an avalanche manner, and cause surface discharge in the porous light-emitting body. Surface discharge occurs continuously in a chain reaction, so that electric charge transfer is carried out in the vicinity of the phosphor particles. Electrons accelerated further collide with the luminescence center, so that the porous light-emitting body is excited to emit light. At this time, ultraviolet rays and visible light also are generated, and the porous light-emitting body 2 also is excited to emit light by the ultraviolet rays.

When the alternating electric field to be applied has its waveform changed from a sine wave or a sawtooth wave to a rectangular wave and has its frequency increased by several tens to thousands of Hz, electrons are emitted and surface discharge occurs more vigorously, resulting in increased emission brightness.

As described above, once surface discharge is started, discharge occurs repeatedly in a chain reaction, and ultraviolet rays and visible light are generated constantly. Thus, it is necessary to suppress deterioration of the phosphor particle 3 due to these rays of light. For this reason, it is preferable to decrease the voltage after light emission is started.

Specifically, when an alternating electric field of about 0.5 to 1.0 kV/mm is applied in a thickness direction of the porous light-emitting body by using an AC power supply, electric charge transfer is carried out and surface discharge occurs, followed by light emission. When a higher electric field is applied, the generation of electrons is accelerated, and when an excessively low electric field is applied, the emission of electrons is insufficient. A current value during discharge is 0.1 mA or less. It was confirmed that light emission once started was sustained even when the voltage was decreased to 50% to 80% of the voltage applied initially.

In the present embodiment, the light-emitting element is driven in the atmosphere. However, it was confirmed that even in an atmosphere of oxygen, nitrogen, and an inert gas or in a gas atmosphere under a reduced pressure, the light-emitting element emitted light similarly.

In the present embodiment, the blue phosphor particle is used. However, it was found that the same result also was obtained by using a red or green phosphor particle. Further, mixed particles of blue, red, and green also provide the same result.

The light-emitting element of the present embodiment emits light by surface discharge. Thus, unlike a conventional light-emitting element, there is almost no need to use a thin film formation process for forming the phosphor layer, and neither a vacuum system nor a carrier intensifying layer is necessary. Therefore, the light-emitting element has a simple structure and is processed easily.

In the electron-emitting body, silicon carbide or a diamond thin film may be used instead of the whisker emitter. When such a material is used, electrons can be emitted from the material by the application of a gate voltage between the cathode electrode and the gate electrode and irradiated to the porous light-emitting body.

### Embodiment 21

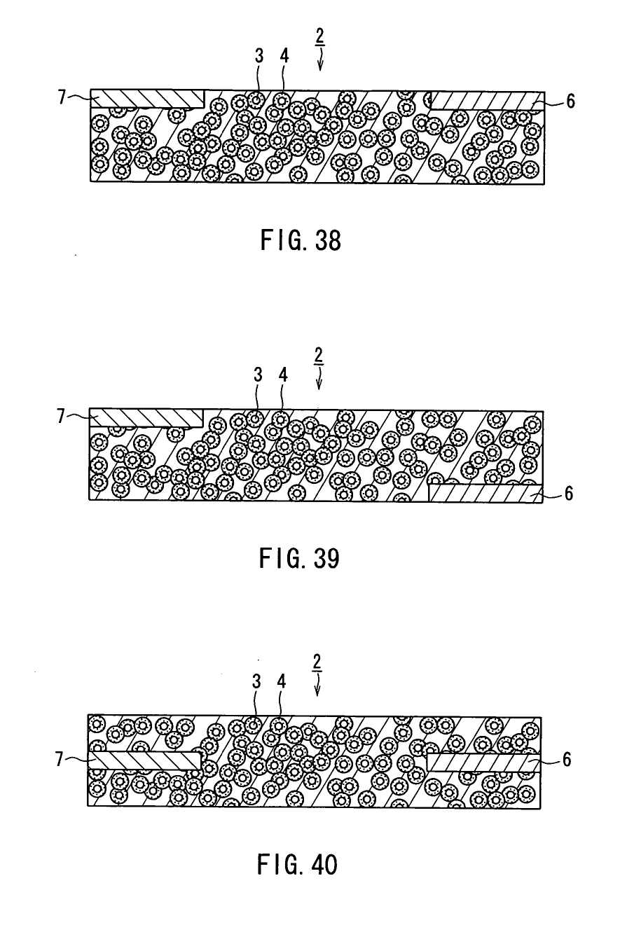

In the present embodiment, a light-emitting element including an electron-emitting body, a porous light-emitting body, and a pair of electrodes will be described with reference to FIGS. 38 to 40. In particular, the description is directed to the pair of electrodes provided to apply an electric field to the porous light-emitting body.

FIGS. 38 to 40 are cross-sectional views of the porous light-emitting body constituting a part of the light-emitting element. Reference numeral 2 denotes a porous light-emitting body, 3 denotes a phosphor particle, 4 denotes an insulating layer, 6 denotes a first electrode, and 7 denotes a second electrode. In the porous light-emitting body shown in FIG. 38, the blue phosphor particle 3 coated with the insulating layer 4 of an insulative inorganic substance of MgO is used as in Embodiment 16. Specifically, the phosphor particle is added to an Mg precursor complex solution, stirred for a long time, and then taken out from the solution, followed by drying. After that, the phosphor particle is subjected to heat treatment at 400° C. to 600° C. in the atmosphere, whereby a uniform coating layer of MgO, i.e., the insulating layer, is formed on a surface of the phosphor particle. 50 mass % of the phosphor particle 3 coated with the insulating layer 4 and 50 mass % of a colloidal silica solution are mixed to form a slurry.

Then, a ceramic board formed of inorganic fiber (an Al₂O₃—CaO—SiO₂ based ceramic fiber board with a thickness of about 1 mm and a void ratio of about 45%) is immersed in the slurry, followed by drying at 120° C. to 150° C. for 10 to 30 minutes. As a result, the ceramic board supports phosphor particle powder. Thereafter, as shown in FIG. 38, on a top surface of the ceramic board, an Ag electrode paste is baked to a thickness of 30 μm to form the first electrode 6 and the second electrode 7. The ceramic fiber board thus obtained is attached to the electron-emitting body by using colloidal silica, water glass, or an epoxy resin, whereby the light-emitting element (not shown) of the present invention is obtained.

In Embodiment 1, as shown in FIG. 1, the first electrode 6 and the second electrode 7 are formed on a top surface of the porous light-emitting body so as to be opposed to each other. However, as shown in FIG. 39, these electrodes may be formed on both the top surface and the bottom surface in a diagonally crossed manner.

Next, a description will be given of the case, as shown in FIG. 40, where both the first electrode 6 and the second electrode 7 are buried in the porous light-emitting body 2. The phosphor particle 3 coated with the insulating layer 4 of MgO is mixed with 5 mass % of polyvinyl alcohol to be granulated, and then the granules are molded in a plate shape under a pressure of about 50 MPa by using a molding die. Then, the thus-obtained molded granules are subjected to heat treatment at 450° C. to 1200° C. for 2 to 5 hours in a nitrogen atmosphere, whereby the plate-shaped porous light-emitting body 2 is manufactured. When the porous light-emitting body has an apparent porosity of less than 10%, surface discharge occurs only on a surface of the phosphor, resulting in decreased luminous efficiency. Therefore, it is desirable that the porous light-emitting body has a porous structure with an apparent porosity of not less than 10%. On the other hand, when the porosity is excessively high due to too large pores of the phosphors, it is expected that the luminous efficiency is decreased or that surface discharge is less likely to occur. On this account, ideally, the apparent porosity is preferably in a range of not less than 10% to less than 100%.

On a surface of the plate-shaped porous light-emitting body 2 thus obtained, an Ag electrode paste is baked to a thickness of 30 μm to form the first electrode 6 and the second electrode 7. Then, 50 mass % of the phosphor particle 3 coated with the insulating layer 4 and 50 mass % of a colloidal silica solution are mixed to form a slurry, and the slurry is applied to the surface of the porous light-emitting body on which the electrodes are formed, followed by drying at 120° C. to 150° C. for 10 to 30 minutes. As a result, as shown in FIG. 40, the porous light-emitting body in which both the first electrode 6 and the second electrode 7 are buried is obtained.

Further, the insulating layer of MgO may be formed on the surface of the phosphor particle in the following manner. Initially, Mg(OC₂H₅)₂ powder (1 molar ratio) as metal alkoxide is mixed well by stirring in a solution of CH₃COOH (10 molar ratio), H₂O (50 molar ratio), and C₂H₅OH (50 molar ratio) at room temperature, whereby a substantially transparent sol/gel solution is prepared. Phosphor particles (2 molar ratio), such as BaMgAl₁₀O₁₇:Eu²⁺ (blue), Zn₂SiO₄:Mn²⁺ (green), and YBO₃:Eu³⁺ (red), with an average particle diameter of 2 to 3 μm are mixed little by little by stirring into the sol/gel solution. This operation is performed continuously for 1 day, and then the mixed solution undergoes centrifugal separation so as to take powder therefrom to a tray made of ceramic, which is allowed to dry at 150° C. all day and night.

Then, the dried powder is calcined in the air at 400° C. to 600° C. for 2 to 5 hours, so that the uniform insulating layer of MgO is formed on the surface of the phosphor particle.

As a result of observing the phosphor particle with a transmission electron microscope (TEM), the thickness of the insulating layer is 0.1 to 2.0 μm. The coating of the insulating layer can be provided by immersing the phosphor particle in a metal alkoxide solution, by using a metal complex solution as mentioned above, or by deposition, sputtering, CVD, and the like.

As a metal oxide for use as the insulating layer, Y₂O₃, Li₂O, MgO, CaO, BaO, SrO, Al₂O₃, SiO₂, MgTiO₃, CaTiO₃, BaTiO₃, SrTiO₃, ZrO₂, TiO₂, B₂O₃, and the like are known. It is desirable to use at least one of these materials to form the insulating layer.

In particular, when the insulating layer is formed by a vapor phase method, it is desirable that the phosphor particle is subjected to a pretreatment in a nitrogen atmosphere at 200° C. to 500° C. for about 1 to 5 hours. In general, phosphor particles contain a large amount of absorbed water and water of crystallization, and it is not preferable to form the insulating layer on the phosphor particles in such a state because this has an effect on lifetime properties such as a deterioration of brightness and a shift in emission spectrum.

The thickness of the insulating layer is set to about 0.1 to 2.0 μm. However, the thickness may be determined in view of an average particle diameter of the phosphor particle and the occurrence of surface discharge. In the case of an average particle diameter on a submicron order, it is considered that a very thin coating layer is required to be formed.

A large thickness of the insulating layer is not preferable in terms of a shift in emission spectrum, a deterioration in brightness, and electron shielding. On the contrary, it is expected that a small thickness of the insulating layer makes it somewhat difficult to cause surface discharge continuously. Therefore, the relationship between the average particle diameter of the phosphor particle and the thickness of the insulating layer is preferably in the proportion of 1 part to 1/10 to 1/500.

It is preferable that each phosphor particle is coated with the insulating layer of a metal oxide. Practically, however, 2 or 3 phosphor particles are coated in a flocculated state. Even when the phosphor particles are coated in such a somewhat flocculated state, there is substantially no effect on light emission.

The light-emitting element of the present invention is manufactured by using the porous light-emitting body thus obtained. As a result, it was confirmed that the light-emitting element exhibited a high brightness, a high contrast, a high recognition capability, and a high reliability.

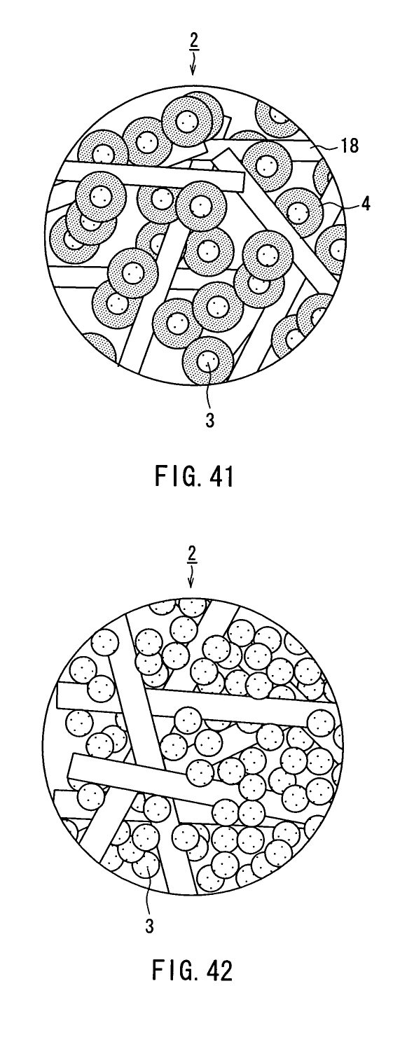

Further, in order to accelerate the occurrence of surface discharge, it is also possible to manufacture the porous light-emitting body 2 by mixing insulative fibers 18 when forming the phosphor particle 3 coated with the insulating layer 4. As the insulative fiber 18 for use in such a case, a SiO₂—Al₂O₃—CaO based electrically insulative fiber or the like is preferable. FIG. 41 shows a schematic cross-sectional view of the porous light-emitting body thus obtained. Further, instead of subjecting the phosphor particle 3 coated with the insulating layer 4 to heat treatment, a mixture of the phosphor particles 3 and the insulative fibers 18 may be used simply. FIG. 42 is a schematic cross-sectional view of the porous light-emitting body formed of the mixture of the phosphor particles 3 and the insulative fibers 18.

### Embodiment 22

In the present embodiment, a general description will be given, with reference to the figures, of a structure of a field emission display (FED) manufactured by combining the porous light-emitting body with the electron-emitting body including the Spindt-type emitter according to the present invention.

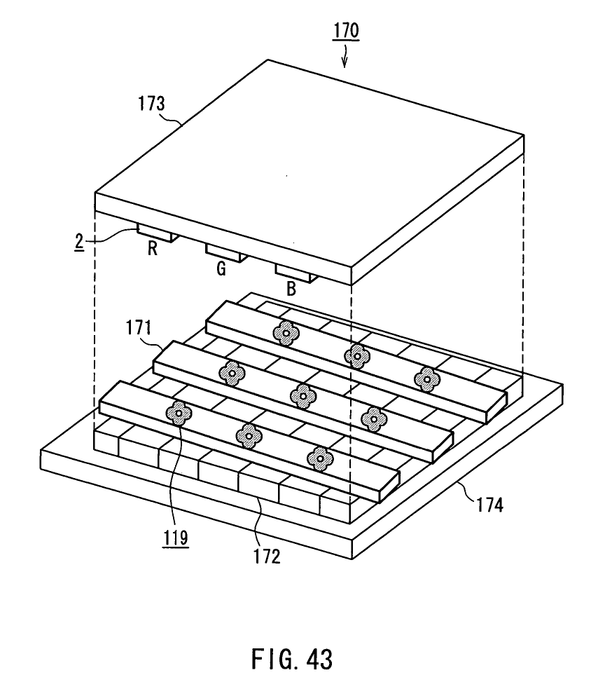

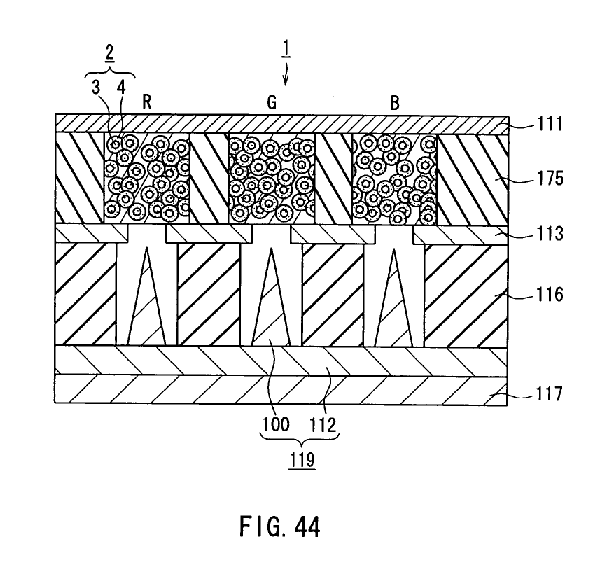

FIG. 43 is an exploded perspective view of main portions of the field emission display of the present embodiment. FIG. 44 is a cross-sectional view of an array of light-emitting elements using the Spindt-type emitter according to the present embodiment. In FIG. 43, reference numeral 2 denotes a porous light-emitting body, 119 denotes an electron-emitting body, 170 denotes a field emission display, 171 denotes a gate line, 172 denotes a cathode line, 173 denotes an anode substrate, and 174 denotes a cathode substrate. In FIG. 44, reference numeral 1 denotes a light-emitting element, 2 denotes a porous light-emitting body, 3 denotes a phosphor particle, 4 denotes an insulating layer, 100 denotes a Spindt-type emitter, 111 denotes an anode electrode, 112 denotes a cathode electrode, 113 denotes a gate electrode, 116 denotes an insulator, 117 denotes a substrate, and 175 denotes a spacer.

As shown in FIG. 43, in the field emission display 170 of the present embodiment, the anode substrate 173 with the porous light-emitting bodies 2 is laminated on the cathode substrate 174 mounted with the electron-emitting bodies 119 so as to be opposed thereto. On the cathode substrate 174, two-layer wirings of the gate lines 171 and the cathode lines 172 that are orthogonal to each other are formed, and the electron-emitting body 119 is formed at a point of intersection of these lines. This allows the field emission display 170 of the present embodiment to display a two-dimensional image on a phosphor screen without deflecting an electron beam as in a CRT.

As described in Embodiment 16, the electron-emitting body 119 using the Spindt-type emitter 100 includes the cone-shaped Spindt-type emitter 100 and the gate electrode 113 formed so as to surround the Spindt-type emitter 100 for the application of a voltage for drawing electrons.

In order to allow electrons to be emitted from the emitter, a positive potential is applied to the gate, and a negative potential is applied to the emitter. A high electric field is concentrated on a front end portion of the cone-shaped emitter, and electrons are emitted therefrom toward the porous light-emitting body 2. In the case of an Mo Spindt-type emitter, the application of a voltage of 15 to 80 V causes electrons to be emitted. In a practical display panel, a plurality of emitters are provided for each pixel, so that a high level of redundancy can be ensured with respect to an operating state of the emitters. Consequently, current fluctuations specific to this type of element are averaged statistically, and thus each pixel is allowed to emit light stably. Further, the field emission display can be driven in a so-called simple matrix. One line is displayed at a time by applying a negative data voltage to the emitter line 172 while applying a positive scan pulse to the gate line 171. By switching scan pulses sequentially, a two-dimensional image can be displayed. Further, when a transistor is provided for each pixel arranged in a matrix so as to turn ON/OFF the pixel, the field emission display can be driven more actively.

FIG. 44 shows a cross section of an exemplary light-emitting element in which a plurality of the Spindt-type emitters 100 are formed and the porous light-emitting bodies 2 are laminated so as to correspond to the respective emitters. In this case, as shown in the figure, it is desirable to form the spacer 175 between the porous light-emitting bodies 2 so as to avoid crosstalk during light emission. In the field emission display of the present embodiment, the Spindt-type emitter 100 is used as the electron-emitting body 119. However, the present invention is not necessarily limited thereto, and any devices having a function of emitting electrons may be combined with the porous light-emitting body of the present invention to manufacture the field emission display.

### Embodiment 23

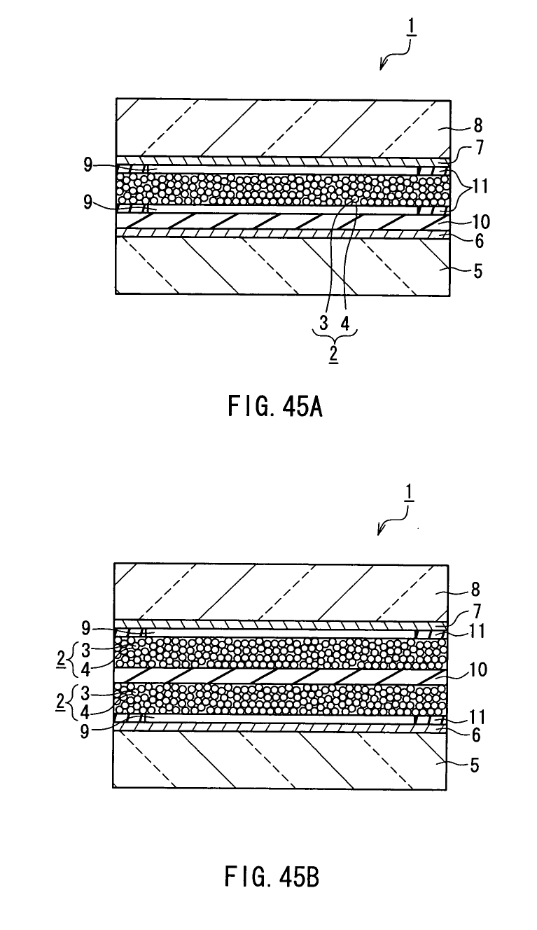

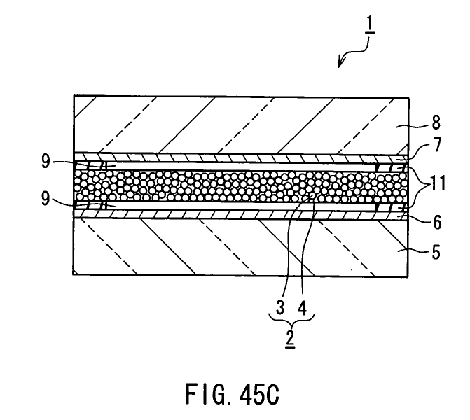

FIGS. 45A to 45C are cross-sectional views of a light-emitting element of the present embodiment. In these figures, reference numeral 1 denotes a light-emitting element, 2 denotes a porous light-emitting layer, 3 denotes a phosphor particle, 4 denotes an insulating layer, 5 denotes a substrate, 6 denotes a first electrode, 7 denotes a second electrode, 8 denotes a transparent substrate, 9 denotes a gas layer, 10 denotes a dielectric layer, and 11 denotes a partition wall.

The light-emitting element in FIG. 45A is manufactured as follows. Initially, on one side of the sintered dielectric 10 with a thickness of 0.3 to 1.0 mm, an Ag paste is baked to a thickness of 30 μm to form the first electrode 6 of a predetermined shape. Then, the side of the dielectric on which the first electrode is formed is adhered onto the substrate 5 made of glass or ceramic. The dielectrics as described in Embodiment 1 are available.

Then, as in Embodiment 1, the phosphor particles 3, each being coated with the insulating layer 4 made of a metal oxide such as MgO, are prepared. As the phosphor particle 3, an inorganic compound, such as BaMgAl₁₀O₁₇:Eu²⁺ (blue), Zn₂SiO₄:Mn²⁺ (green), and YBO₃:Eu³⁺ (red), with an average particle diameter of 2 to 3 μm can be used.

In the present embodiment, the phosphor particle 3 coated with the insulating layer 4 of MgO is mixed with 5 mass % of polyvinyl alcohol to be granulated, and then the granules are molded in a plate shape under a pressure of about 50 MPa by using a molding die. The thus-obtained molded granules are subjected to heat treatment at 450° C. to 1200° C. for 2 to 5 hours in a nitrogen atmosphere, whereby the plate-shaped porous light-emitting body 2 is manufactured.

When the porous light-emitting body has an apparent porosity of less than 10%, the luminous efficiency is decreased for the following reason. That is, when electrons collide with the porous light-emitting layer, although light is emitted on a surface of the porous light-emitting layer, electrons are not injected into the light-emitting layer, and thus substantially no light is emitted inside the layer. To avoid this, in order to allow electrons generated due to discharge to be injected smoothly into the porous light-emitting layer, it is desirable that the porous light-emitting body of the present embodiment has a porous structure with an apparent porosity of not less than 10%. On the other hand, when the porous light-emitting body has an excessively high apparent porosity, the luminous efficiency is decreased or surface discharge is less likely to occur inside the porous light-emitting layer. On this account, the apparent porosity is preferably in a range of not less than 10% to less than 100%, and in particular in a range of 50% to less than 100%.

The plate-shaped porous light-emitting body 2 thus obtained is attached to the dielectric layer 10 by using a glass paste. At this time, the glass paste is screen-printed on the porous light-emitting layer at its both ends, so that the porous light-emitting layer is adhered thereto, followed by heat treatment at 580° C. As a result, the porous light-emitting layer can be adhered to the dielectric layer 10 with the gas layer interposed therebetween.

After that, the porous light-emitting layer is covered with the transparent substrate 8 such as a glass plate on which the second electrode 7 made of ITO (indium-tin oxide alloy) is formed beforehand so as to be opposed to the porous light-emitting layer, whereby the light-emitting element 1 shown in FIG. 45A is obtained. At this time, the transparent substrate 8 is attached by heat treatment using a glass paste, colloidal silica, water glass, a resin, or the like, so that a slight gap for gas is provided between the porous light-emitting layer 2 and the second electrode 7. Consequently, as shown in FIG. 45A, the both end portions of the porous light-emitting layer are adhered by a glass paste or the like that functions as the partition wall 11 in a state where the gas layers are provided on and under the porous light-emitting layer.

The gas layers provided both on and under the porous light-emitting layer, i.e., the gas layer interposed between the porous light-emitting layer 2 and the dielectric layer 10 and the gas layer interposed between the porous light-emitting layer and the second electrode, which are a characteristic of the present embodiment, have a thickness preferably in a range of 20 to 250 μm, and most preferably in a range of 30 to 220 μm. When the thickness is larger than this range, a high voltage is required to be applied for the occurrence of discharge, which is not preferable for the reason of economical efficiency. The thickness of the gas layer may be smaller than the above range, and there is no practical problem as long as the thickness is not less than a mean free path of gas. However, when the gas layer has a very small thickness, it may be somewhat difficult to control the thickness in the process of manufacturing the light-emitting element.

It is not necessarily required that the gas layers provided on and under the porous light-emitting layer according to the present embodiment have the same thickness. However, in the case of providing the gas layers at two places on and under the light-emitting layer, it is preferable that the thickness of each of the gas layers is set to be slightly smaller than that of the gas layer provided only on one side of the light-emitting layer as in FIG. 1. When the thickness of the gas layers is larger, a relatively high voltage is required to be applied for the occurrence of discharge, which is not preferable for the reason of economical efficiency.

As described above, the present embodiment is characterized in that the gas layers are provided on and under the porous light-emitting layer. When an AC electric field is applied between a pair of the first electrode and the second electrode, discharge occurs simultaneously in both the gas layers, so that electrons are emitted from above and below the porous light-emitting layer to be injected into the light-emitting layer efficiently. More specifically, the AC electric field to be applied is increased gradually, and when a voltage not less than the dielectric breakdown voltage is applied to the gas layers, discharge occurs. Accordingly, electrons are doubled in the gas layers and collide with the porous light-emitting body to excite the luminescence center thereof, so that the porous light-emitting layer emits light. In this manner, the gas layers function as an electron supply source, and generated electrons are injected from above and below the porous light-emitting layer and pass through the light-emitting layer in an avalanche manner while causing surface discharge throughout the layer. Surface discharge occurs continuously during the application of an electric field. Electrons generated in an avalanche manner during the application of an electric field collide with the luminescence center of the phosphors, so that the phosphor particles 3 are excited to emit light. As described above, electrons are injected efficiently from above and below the porous light-emitting layer. Therefore, as compared with the light-emitting element in which electrons are injected from one side of the light-emitting layer as described in Embodiment 1, the light-emitting layer having a porous structure according to the present embodiment wholly emits light thoroughly, uniformly, and efficiently, resulting in a remarkably increased brightness.

As described above, in the present embodiment, it is possible to manufacture the light-emitting element including the gas layers, the porous light-emitting layer in contact with the gas layers, and at least a pair of the electrodes for applying an electric field to the gas layers and the porous light-emitting layer. In particular, the dielectric layer and the first electrode of a pair of the electrodes for applying an electric field are arranged on one surface of the porous light-emitting layer via the gas layer, and the second electrode of a pair of the electrodes is arranged on the other surface of the porous light-emitting layer where the dielectric layer and the first electrode are not arranged, via the gas layer.

In the present embodiment, as shown in FIG. 45B, it is possible that a gap formed of the gas layer 9 is not provided between the porous light-emitting layers 2 and the dielectric layer 10, and that gaps formed of the gas layers 9 are provided between the porous light-emitting layers 2 and the electrodes 6 and 7, respectively.

With this configuration, it is possible to allow the porous light-emitting layers 2 to emit light by applying an electric field from a pair of the electrodes 6 and 7 to the gas layers 9 and the porous light-emitting layers 2 in contact therewith.

In the present embodiment, the points to note in particular during the heat treatment process for forming the porous light-emitting layer include heat treatment temperature and atmosphere. In the present embodiment, since the heat treatment is performed in a nitrogen atmosphere at a temperature in a range of 450° C. to 1200° C., a valence of the doped rare earth element in the phosphor is not changed. When the treatment is performed at temperatures higher than this temperature range, however, the valence of the doped rare earth element may be changed or a solid solution of the insulating layer and the phosphor may be formed, and therefore care should be taken to avoid this. As for the heat treatment atmosphere, it is preferable to perform the heat treatment in a nitrogen atmosphere so as to avoid an effect on the valence of the doped rare earth element in the phosphor particle.

In the present embodiment, the thickness of the insulating layer is set to about 0.1 to 2.0 μm. However, the thickness may be determined in view of an average particle diameter of the phosphor particle and efficiency of surface discharge occurrence. Preferably, the phosphor with an average particle diameter on a submicron order has a relatively thin coating. A large thickness of the insulating layer is not preferable since it may result in a shift in emission spectrum, a deterioration in brightness, and the like. On the contrary, it is assumed that a small thickness of the insulating layer makes it somewhat difficult to cause surface discharge. Therefore, the relationship between the average particle diameter of the phosphor particle and the thickness of the insulating layer is desirably in the proportion of 1 part to 1/10 to 1/500.

Next, the light emitting action of the light-emitting element 1 will be described.

In order to drive the light-emitting element 1 as shown in the figure, an AC electric field is applied between the first electrode 6 and the second electrode 7. The AC electric field to be applied is increased gradually, and when a voltage not less than the dielectric breakdown voltage is applied to the gas layers, discharge occurs. Accordingly, electrons are doubled in the gas layers and collide with the porous light-emitting body to excite the luminescence center thereof, so that the light-emitting layer emits light. In this manner, the gas layers function as an electron supply source, and in the present embodiment, generated electrons are injected from above and below the porous light-emitting layer and pass through the light-emitting layer in an avalanche manner while causing surface discharge throughout the porous light-emitting layer. Surface discharge occurs continuously during the application of an electric field. Electrons generated in an avalanche manner during the application of an electric field collide with the luminescence center of the phosphors, so that the phosphor particles 3 are excited to emit light. As described above, in the present embodiment, electrons are injected from above and below the porous light-emitting layer. Therefore, as compared with the light-emitting element in which electrons are injected from only one side of the light-emitting layer as described in Embodiment 1, the porous light-emitting layer wholly emits light thoroughly, uniformly, and efficiently, resulting in a remarkably increased brightness.

In the present embodiment, the porous light-emitting body having an apparent porosity in a range of not less than 10% to less than 100% is used. In the case of a usual light-emitting layer without a porous structure, light is emitted on its surface but is hardly emitted inside the layer. However, in the case of the porous light-emitting layer of the present embodiment, light is emitted not only on its surface but also inside the light-emitting layer, resulting in considerably favorable luminous efficiency. As described above, in the case of the porous layer, the porous structure allows electrons generated due to discharge to be injected smoothly into the layer, so that surface discharge occurs throughout the layer, and the layer wholly emits light with a high brightness.

It is desirable that the porous light-emitting body used in the present embodiment has a porous structure with an apparent porosity of not less than 10%. On the other hand, when the light-emitting body has an excessively high apparent porosity, the luminous efficiency is decreased, surface discharge is less likely to occur inside the porous light-emitting layer, or the like. On this account, the apparent porosity is desirably in a range of not less than 10% to less than 100%, and most preferably in a range of 50% to less than 100%.

When the AC electric field to be applied has its waveform changed from a sine wave or a sawtooth wave to a rectangular wave or has its frequency increased by several tens to thousands of Hz, electrons are emitted very vigorously by surface discharge, resulting in increased emission brightness. Further, as the voltage of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the light-emitting element in FIGS. 45A and 45B of the present embodiment, an electric field of about 0.79 to 1.7 kV/mm and 0.75 to 1.6 kV/mm, respectively, is applied in a thickness direction of the porous light-emitting layer to allow the phosphor particles 3 to emit light. Thereafter, an alternating electric field of about 0.55 to 1.1 kV/mm and 0.52 to 1.0 kV/mm, respectively, is applied, so that surface discharge occurs continuously to sustain the light emission of the phosphor particles 3. When a higher electric field is applied, the generation of electrons is accelerated, and when a lower electric field is applied, the generation thereof is suppressed. In the case where the gas present in the gas layer is air, at least a voltage of about 0.3 kV/mm, which is a dielectric breakdown voltage of air, is required to be applied.

A current value during discharge is 0.1 nA or less. It was confirmed that light emission once started was sustained even when the voltage was decreased to about 50% to 80% of the voltage applied initially, and that a high brightness, a high contrast, a high recognition capability, and a high reliability were ensured in light emission of the phosphor particles of each of the three colors. In the present embodiment, the light-emitting element is driven in the atmosphere. However, it was confirmed that even in an atmosphere of a rare gas or in a gas atmosphere in which pressure is applied or a negative pressure is formed, the light-emitting element emitted light similarly.

According to the light-emitting element of the present embodiment, the porous light-emitting layer is formed by a thick film process or the like. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, electrons generated due to discharge can collide with the porous light-emitting layer from both sides thereof, and due to the porous structure of the light-emitting body, the colliding electrons are allowed to be injected smoothly into the light-emitting layer while causing surface discharge, resulting in light emission with a very high brightness. In the case of a usual light-emitting body without a porous structure, light is emitted only on its surface. However, as described above, the porous light-emitting layer of the present embodiment wholly emits light thoroughly, resulting in a high brightness. Further, the luminous efficiency is considerably favorable as compared with that achieved by phosphors that emit ultraviolet rays as in plasma display panels. Further, it is possible to provide a light-emitting element that is to be driven with relatively low power consumption when being used in a large-screen display. Since the partition walls are provided as discharge separation means at both ends of the porous light-emitting layer, crosstalk during light emission can be avoided easily.

FIG. 45C shows the same light-emitting element as in FIGS. 45A and 45B except that the dielectric layer 10 interposed between the porous light-emitting layer 2 and the first electrode 6 is not provided.

The light-emitting element in FIG. 45C is manufactured as follows. Initially, on one side of the substrate 5 made of glass or ceramic, an Ag paste is baked to a thickness of 30 μm to form the first electrode 6 into a predetermined shape.

Then, as in Embodiment 1, the phosphor particles 3, each being coated with the insulating layer 4 made of a metal oxide such as MgO, are prepared. As the phosphor particle 3, an inorganic compound, such as BaMgAl₁₀O₁₇:Eu²⁺ (blue), Zn₂SiO₄:Mn²⁺ (green), and YBO₃:Eu³⁺ (red), with an average particle diameter of 2 to 3 μm can be used.

As in Embodiment 3, in the present embodiment, the phosphor particle 3 coated with the insulating layer 4 of MgO is mixed with 5 mass % of polyvinyl alcohol to be granulated, and then the granules are molded in a plate shape under a pressure of about 50 MPa by using a molding die. The thus-obtained molded granules are subjected to heat treatment at 450° C. to 1200° C. for 2 to 5 hours in a nitrogen atmosphere, whereby the plate-shaped porous light-emitting body 2 is manufactured.

Both ends of the plate-shaped porous light-emitting body 2 thus obtained are attached to an electrode side of the substrate 5 by using a glass paste. Specifically, as shown in FIG. 45C, the glass paste is screen-printed, so that the porous light-emitting layer is adhered, followed by heat treatment at 580° C. As a result, the porous light-emitting layer 2 is fixed with a slight gap formed of the gas layer provided between the porous light-emitting layer 2 and the first electrode. The gas layer provided between the porous light-emitting layer 2 and the first electrode 6 preferably has a thickness in a range of 20 to 250 μm, and in particular in a range of 30 to 220 μm. When the thickness is beyond this range, a high voltage is required to be applied for the occurrence of discharge, which is not preferable for the reason of economical efficiency. The thickness of the gas layer may be smaller than the above range, and there is no problem as long as the thickness is larger than a mean free path of gas.

After that, the porous light-emitting layer is covered with the transparent substrate 8 such as a glass plate on which the second electrode 7 made of ITO (indium-tin oxide alloy) is formed beforehand so as to be opposed to the porous light-emitting layer, whereby the light-emitting element 1 of the present embodiment as shown in FIG. 45C is obtained. At this time, the transparent substrate 8 is attached by heat treatment using colloidal silica, water glass, a resin, or the like, so that a slight gap formed of the gas layer is provided between the porous light-emitting layer 2 and the second electrode 7. The width of the gap between the porous light-emitting layer 2 and the second electrode 7 is not necessarily required to be the same as that of the gap between the porous light-emitting layer and the first electrode. They may be set to be substantially the same.

As described above, the present embodiment is characterized in that the slight gaps are provided between the porous light-emitting layer and the first and second electrodes, respectively, provided on both sides of the porous light-emitting layer. This configuration allows the gas layers formed of a rare gas, atmospheric air, oxygen, nitrogen, or a mixed gas thereof to be interposed between the porous light-emitting layer and a pair of the electrodes, respectively. An AC electric field is applied between a pair of the electrodes of the light-emitting element, and when a voltage not less than the dielectric breakdown voltage is applied to the gas layers, discharge occurs. Accordingly, electrons are doubled in the gas layers and collide with the porous light-emitting body to excite the luminescence center thereof, so that the light-emitting layer emits light. In this manner, the gas layers function as an electron supply source, and generated electrons collide with the light-emitting layer, are injected into the layer, and pass through the light-emitting layer in an avalanche manner while causing surface discharge throughout the layer. Surface discharge occurs continuously during the application of an electric field. Electrons generated in an avalanche manner collide with the luminescence center of the phosphors, so that the phosphor particles 3 are excited to emit light. As described above, in the present embodiment, electrons are supplied from both sides of the porous light-emitting layer and injected into the light-emitting layer smoothly and thoroughly. Therefore, as compared with the light-emitting element in which electrons are injected from one side of the porous light-emitting body as described in Embodiment 1, the light-emitting layer wholly emits light uniformly and efficiently with an increased brightness.

In the present embodiment, the phosphor particle 3 coated with the insulating layer 4 of MgO is used. This is because MgO has a high specific resistance (10⁹ Ω·cm or more) and surface discharge can occur efficiently. An insulating layer with a low specific resistance is not preferable since surface discharge is less likely to occur, and a short circuit may occur in some cases. For these reasons, it is desirable to coat the phosphor particle with an insulating metal oxide with a high specific resistance. It should be appreciated that when the phosphor particle itself to be used has a high specific resistance, surface discharge occurs easily without the coating of an insulating metal oxide. As the insulating layer, at least one selected from Y₂O₃, Li₂O, CaO, BaO, SrO, A₂O₃, SiO₂, and ZrO₂ can be used as well as MgO. These oxides are stable substances with an extremely low standard free energy of formation ΔG_{f}⁰ (e.g., −100 kcal/mol or less at room temperature). Further, the insulating layer of these substances is favorable since it has a high specific resistance and is less likely to be reduced. Thus, this layer also serves as an excellent protective coating for suppressing reduction and deterioration of the phosphor particle due to electrons, resulting in increased durability of the phosphor.

Further, instead of the above-mentioned sol-gel method, the insulating layer can be formed by chemisorption or physical adsorption using a CVD method, a sputtering method, a deposition method, a laser method, a shearing stress method, and the like. It is desirable for the insulating layer to be homogeneous and uniform so as not to be peeled off. To this end, it is important, in forming the insulating layer, to immerse the phosphor particle in a weak acid solution of acetic acid, oxalic acid, citric acid, or the like so as to wash impurities attached to a surface of the phosphor particle.

Further, it is desirable that the phosphor particle is subjected to a pretreatment in a nitrogen atmosphere at 200° C. to 500° C. for about 1 to 5 hours before the formation of the insulating layer. The reason for this is as follows. A usual phosphor particle contains a large amount of adsorbed water and water of crystallization, and the formation of the insulating layer on the phosphor particle in such a state exerts an undesirable effect on the lifetime property, such as a deterioration in brightness and a shift in emission spectrum. When the phosphor particle is washed with a weak acid solution, it is rinsed thoroughly in water before performing the pretreatment.

Next, the light emitting action of the light-emitting element 1 will be described with reference to FIG. 45C. In order to drive the light-emitting element 1 as shown in the figure, an AC electric field is applied between the first electrode 6 and the second electrode 7. At this time, the light-emitting element is inserted in a silica tube, and a mixed gas of Ne and Xe is sealed under slight pressure. The AC electric field to be applied is increased gradually, and when a voltage not less than the dielectric breakdown voltage is applied to the gas layers, discharge occurs. Accordingly, electrons are doubled in the gas layers and collide with the porous light-emitting body to excite the luminescence center thereof, so that the porous light-emitting layer emits light. In this manner, the gas layers function as an electron supply source, and generated electrons are injected into the porous light-emitting layer from both sides of the layer and pass through the light-emitting layer in an avalanche manner while causing surface discharge throughout the porous light-emitting layer. Surface discharge occurs continuously during the application of an electric field. Electrons generated in an avalanche manner during the application of an electric field collide with the luminescence center of the phosphors, so that the phosphor particles 3 are excited to emit light. In the present embodiment, electrons are injected from both sides of the porous light-emitting layer, i.e., from above and below the layer. Therefore, as compared with the light-emitting element in which electrons are injected from one side of the layer as described in Embodiment 1, the porous light-emitting layer wholly emits light thoroughly, uniformly, and efficiently, resulting in a remarkably increased brightness.

In the present embodiment, the porous light-emitting body having an apparent porosity in a range of not less than 10% to less than 100% is used. In the case of a usual phosphor layer without a porous structure, light is emitted on its surface but is hardly emitted inside the layer. However, in the case of the porous light-emitting layer, light is emitted not only on its surface but also inside the layer, resulting in considerably favorable luminous efficiency. The reason for this is that the porous light-emitting layer allows electrons due to discharge to go into the layer, so that surface discharge occurs throughout the layer, resulting in light emission with a high brightness.

When the AC electric field to be applied has its waveform changed from a sine wave or a sawtooth wave to a rectangular wave or has its frequency increased by several tens to thousands of Hz, electrons are emitted very vigorously by surface discharge, resulting in increased emission brightness. Further, as the voltage of the AC electric field is increased, a burst wave is generated. A burst wave is generated at a frequency immediately before the peak of the frequency in the case of a sine wave, and is generated at the peak of the frequency in the case of a sawtooth wave or a rectangular wave, and the emission brightness increases with increasing voltage of the burst wave. Once surface discharge is started, ultraviolet rays and visible light also are generated, and it is necessary to suppress deterioration of the phosphor particle 3 due to these rays of light. For this reason, it is preferable to decrease the voltage after light emission is started.

In the present embodiment, as in Embodiment 2, an electric field of about 0.57 to 1.2 kV/mm is applied in a thickness direction of the porous light-emitting layer to allow the phosphor particles 3 to emit light. Thereafter, an alternating electric field of about 0.39 to 0.78 kV/mm is applied, so that surface discharge occurs continuously to sustain the light emission of the phosphor particles 3. As compared with the case where a rare gas is not sealed as in Embodiment 2, light emission is sustained even when the voltage value is decreased to about 60% to 80%. The reason for this is that the sealed rare gas makes an atmosphere in which discharge is more likely to occur. Further, the brightness can be increased remarkably by sealing the rare gas under pressure.

A current value during discharge is 0.1 mA or less. It was confirmed that light emission once started was sustained even when the voltage was decreased to about 50% to 80% of the voltage applied initially, and that a high brightness, a high contrast, a high recognition capability, and a high reliability were ensured in light emission of the phosphor particles of each of the three colors as compared with the light-emitting element of Embodiment 2.

As compared with the above-mentioned case where the rare gas is sealed under pressure, when the light-emitting element without the dielectric layer according to the present embodiment is to be driven to emit light in the atmosphere, it is required that an electric field of about 0.89 to 1.9 kV/mm is applied to allow the phosphor particles 3 to emit light, and that an alternating electric field of about 0.62 to 1.3 kV/mm is applied thereafter, so that surface discharge occurs continuously to sustain the light emission of the phosphor particles 3.

According to the light-emitting element of the present embodiment, the porous light-emitting layer is formed by a thick film process or the like. Thus, unlike a conventional light-emitting element, there is no need to use a thin film formation process for manufacturing the light-emitting element, and neither a vacuum system nor a carrier intensifying layer is necessary. Therefore, the light-emitting element has a simple structure and is manufactured and processed easily. Further, the light-emitting element emits light by surface discharge that occurs due to electrons injected into the porous light-emitting layer, resulting in a high brightness. The present embodiment is characterized in that the porous light-emitting layer wholly emits light thoroughly, unlike a usual phosphor that emits light only on its surface. Further, the luminous efficiency is considerably favorable as compared with that achieved by phosphors that emit ultraviolet rays as in plasma display panels. Further, it is possible to provide a light-emitting element that is to be driven with relatively low power consumption when being used in a large-screen display. Since the partition walls are provided as discharge separation means at both ends of the porous light-emitting layer, crosstalk during light emission can be avoided easily.

### INDUSTRIAL APPLICABILITY

The light-emitting element according to the present invention emits light by surface discharge. Thus, unlike a conventional light-emitting element, there is no need to use a thin film formation process for forming the phosphor layer, and neither a vacuum vessel nor a carrier intensifying layer is necessary. Therefore, the light-emitting element can be manufactured easily. Consequently, the light-emitting element of the present invention is useful as a light-emitting body that constitutes a unit pixel of a large-screen display, and also as a light-emitting body to be applied to lighting, a light source, and the like.

1. A light-emitting element comprising a light-emitting layer including a phosphor, and at least two electrodes,
the light-emitting element comprising at least two kinds of electrically insulating layers with different dielectric constants,
wherein one of the electrically insulating layers is the light-emitting layer, and
one of the two electrodes is formed in contact with one of the insulating layers.

2. The light-emitting element according to claim 1, wherein the at least two electrodes are formed on interfaces of the electrically insulating layers with different dielectric constants.

3. The light-emitting element according to claim 1, wherein the other insulating layer is a gas layer, a ferroelectric layer, or a dielectric layer with a relative dielectric constant of 100 or more.

4. The light-emitting element according to claim 3, wherein the ferroelectric layer or the dielectric layer is formed of at least one layer selected from a sintered layer, a mixed layer of a particle and a binder including a ferroelectric material or a dielectric material, and a molecular deposition thin film including a ferroelectric material or a dielectric material.

5. The light-emitting element according to claim 3, wherein the ferroelectric layer further includes a back electrode.

6. The light-emitting element according to claim 1, wherein the phosphor is a porous light-emitting body.

7. The light-emitting element according to claim 6, wherein the porous light-emitting body includes at least one gas selected from air, nitrogen, and an inert gas.

8. The light-emitting element according to claim 6, wherein the porous light-emitting body is formed of a fine pore connected to a surface of the porous light-emitting body, a gas filled in the fine pore, and a phosphor particle.

9. The light-emitting element according to claim 6, wherein the porous light-emitting body is formed of a phosphor particle or a phosphor particle coated with an insulating layer.

10. The light-emitting element according to claim 6, wherein the porous light-emitting body has an apparent porosity in a range of not less than 10% to less than 100%.

11. The light-emitting element according to claim 6, wherein the porous light-emitting body is formed of at least one particle selected from a phosphor particle and a phosphor particle coated with an insulating layer, and an insulative fiber.

12. The light-emitting element according to claim 1, wherein the light-emitting element is in an atmosphere under pressure, atmospheric pressure, or a reduced pressure, and is sealed entirely.

13. The light-emitting element according to claim 1, wherein a direct or AC electric field is applied between the at least two electrodes so as to cause surface discharge, whereby the light-emitting layer is allowed to emit light.

14. The light-emitting element according to claim 3, wherein the gas layer is provided to have a thickness in a range of not less than 1 μm to not more than 300 μm.

15. The light-emitting element according to claim 1, wherein the light-emitting layer is divided into a plurality of parts by discharge separation means with respect to each pixel.

16. The light-emitting element according to claim 15, wherein the discharge separation means is formed of a partition wall.

17. The light-emitting element according to claim 15, wherein the partition wall is made of an inorganic material.

18. The light-emitting element according to claim 15, wherein the discharge separation means is formed of a space.

19. The light-emitting element according to claim 3, wherein the gas layer is partitioned by a rib in a thickness direction.

20. The light-emitting element according to claim 1, wherein the light-emitting layer emits light of at least red (R), green (G), or blue (B) separately.

21. The light-emitting element according to claim 1, wherein the at least two electrodes are arranged so as to sandwich the at least one dielectric layer and the light-emitting layer therebetween, and an AC electric field is applied so as to cause surface discharge in the light-emitting layer, whereby the light-emitting layer is allowed to emit light.

22. The light-emitting element according to claim 1, wherein the at least two electrodes are an address electrode and a display electrode, respectively.

23. The light-emitting element according to claim 1, wherein the at least one electrode is a transparent electrode arranged on an observation side.

24. The light-emitting element according to claim 3, wherein the gas layer is formed at least one portion selected from a portion between the light-emitting layer and the observation side of the transparent electrode and a portion between the light-emitting layer and the back electrode.

25. The light-emitting element according to claim 1, wherein the light-emitting layer is a porous light-emitting layer, and the porous light-emitting layer is arranged in contact with a ferroelectric layer.

26. The light-emitting element according to claim 25, wherein at least one of the electrodes is arranged on the porous light-emitting layer so that an alternating electric field applied between the at least two electrodes also is applied to a part of the porous light-emitting layer.

27. The light-emitting element according to claim 25, wherein the at least two electrodes are formed so as to sandwich the ferroelectric layer and the porous light-emitting layer therebetween.

28. The light-emitting element according to claim 25, wherein the at least two electrodes both are formed on the ferroelectric layer.

29. The light-emitting element according to claim 25, wherein the at least two electrodes both are formed at a boundary between the ferroelectric layer and the porous light-emitting layer.

30. The light-emitting element according to claim 25, wherein one of the at least two electrodes is formed at a boundary between the ferroelectric layer and the porous light-emitting layer, and the other electrode is formed on the ferroelectric layer.

31. The light-emitting element according to claim 1,
wherein one of the electrically insulating layers is a ferroelectric layer,
the at least two electrodes include a pair of electrodes and another electrode,
a pair of the electrodes are arranged so that an electric field is applied to at least a part of the ferroelectric layer, and
the other electrode is arranged so that an electric field is applied to at least a part of the light-emitting layer provided between the other electrode and at least one of a pair of the electrodes.

32. The light-emitting element according to claim 1, wherein a predetermined electric field or higher is applied to the light-emitting layer, so that electric charge transfer is carried out, whereby the light-emitting layer is allowed to emit light.

33. The light-emitting element according to claim 1, wherein an electron-emitting body further is provided toward the light-emitting layer, and the light-emitting layer is arranged adjacent to the electron-emitting body so as to be irradiated with electrons generated from the electron-emitting body.

34. The light-emitting element according to claim 33, wherein the electron-emitting body includes a cathode electrode, a gate electrode, and a Spindt-type emitter interposed between the two electrodes, and electrons emitted from the Spindt-type emitter by application of a gate voltage between the cathode electrode and the gate electrode are irradiated to the light-emitting layer, whereby the light-emitting layer is allowed to emit light.

35. The light-emitting element according to claim 34, wherein the Spindt-type emitter has a cone shape.

36. The light-emitting element according to claim 34, wherein the Spindt-type emitter is made of at least one metal selected from molybdenum, niobium, zirconium, nickel, and molybdenum steel.

37. The light-emitting element according to claim 33, wherein the electron-emitting body includes a cathode electrode, a gate electrode, and a carbon nanotube interposed between the two electrodes, and electrons emitted from the carbon nanotube by application of a gate voltage between the cathode electrode and the gate electrode are irradiated to the light-emitting layer, whereby the light-emitting layer is allowed to emit light.

38. The light-emitting element according to claim 33, wherein the electron-emitting body is a surface-conduction-type electron-emitting element, a gap is provided in a metal oxide film, and electrons generated from the gap by application of an electric field to an electrode provided on the metal oxide film are irradiated to the porous light-emitting body, whereby the light-emitting layer is allowed to emit light.

39. The light-emitting element according to claim 33, wherein the electron-emitting body is made of a silicon microcrystal with an oxide film sandwiched between polysilicon with an oxide film, and electrons generated by application of a voltage to the silicon microcrystal with an oxide film are irradiated to the light-emitting layer, whereby the light-emitting layer is allowed to emit light.

40. The light-emitting element according to claim 33, wherein the electron-emitting body includes a cathode electrode, a gate electrode, and a whisker emitter interposed between the two electrodes, and electrons emitted from the whisker emitter by application of a gate voltage between the cathode electrode and the gate electrode are irradiated to the light-emitting layer, whereby the light-emitting layer is allowed to emit light.

41. The light-emitting element according to claim 33, wherein the electron-emitting body includes a cathode electrode, a gate electrode, and silicon carbide or a diamond thin film interposed between the two electrodes, and electrons emitted from the electron-emitting body by application of a gate voltage between the cathode electrode and the gate electrode are irradiated to the light-emitting layer, whereby the light-emitting layer is allowed to emit light.
